(19) United States
(12) Patent Application Publication
(10) Pub. No.: US 2015/0107988 A1
(43) Pub. Date: Apr. 23, 2015

(54) METHOD FOR FORMING OXIDE SEMICONDUCTOR FILM

(71) Applicant: Semiconductor Energy Laboratory Co., Ltd., Atsugi-shi (JP)

(72) Inventor: Shunpei YAMAZAKI, Setagaya (JP)

(73) Assignee: Semiconductor Energy Laboratory Co., Ltd., Atsugi-shi (JP)

(21) Appl. No.: 14/280,975

(22) Filed: May 19, 2014

(30) Foreign Application Priority Data
Oct. 22, 2013 (JP) 2013-218823

(51) Int. Cl. H01L 21/02; C30B 29/22; C30B 25/06

(52) U.S. Cl. CPC H01L 21/02631; H01L 21/02565; C30B 25/06; C30B 29/22
USPC 204/192.25

(57) ABSTRACT

A method for forming an oxide semiconductor film using a sputtering apparatus including a target containing a crystalline In—Ga—Zn oxide, a substrate, and a magnet includes the following steps: generating plasma between the target and the substrate; and separating a flat-plate-like In—Ga—Zn oxide in which a first layer including a gallium atom, a zinc atom, and an oxygen atom, a second layer including an indium atom and an oxygen atom, and a third layer including a gallium atom, a zinc atom, and an oxygen atom are stacked in this order. The flat-plate-like In—Ga—Zn oxide passes through the plasma and thus is negatively charged. Then, while keeping crystallinity, the oxide gets close to a top surface of the substrate, moves over the top surface of the substrate due to a magnetic field of the magnet and current flowing from the substrate to the target, and then is deposited.

### TECHNICAL FIELD

The present invention relates to an object, a method, or a manufacturing method. In addition, the present invention relates to a process, a machine, manufacture, or a composition of matter. In particular, the present invention relates to, for example, a semiconductor film, a semiconductor device, a display device, a light-emitting device, a lighting device, a power storage device, a memory device, a processor, a driving method thereof, or a manufacturing method thereof.

Note that in this specification, a semiconductor device refers to any device that can function by utilizing semiconductor characteristics. A display device, a light-emitting device, a lighting device, an electro-optical device, a semiconductor circuit, and an electronic device include a semiconductor device in some cases.

### BACKGROUND ART

A technique for forming a transistor by using a semiconductor film over a substrate having an insulating surface has attracted attention. The transistor is applied to a wide range of semiconductor devices such as an integrated circuit and a display device. A silicon film is known as a semiconductor film applicable to a transistor.

Whether an amorphous silicon film or a polycrystalline silicon film is used as a semiconductor film in a transistor depends on the purpose. For example, in the case of a transistor included in a large display device, an amorphous silicon film, which can be formed using an established technique for forming a film over a large substrate, is preferably used. On the other hand, in the case of a transistor included in a high-performance display device where driver circuits are formed over the same substrate, a polycrystalline silicon film, which can form a transistor having a high field-effect mobility, is preferably used. As a method for forming a polycrystalline silicon film, high-temperature heat treatment or laser light treatment which is performed on an amorphous silicon film has been known.

In recent years, an oxide semiconductor film has attracted attention. For example, a transistor which includes an amorphous In—Ga—Zn oxide film is disclosed (see Patent Document 1). An oxide semiconductor film can be formed by a sputtering method or the like, and thus can be used for a semiconductor film of a transistor in a large display device. Moreover, a transistor including an oxide semiconductor film has high field-effect mobility; therefore, a high-performance display device where driver circuits are formed over the same substrate can be formed. In addition, there is an advantage that capital investment can be reduced because part of production equipment for a transistor including an amorphous silicon film can be improved to be used for a transistor including an oxide semiconductor film.

In 1985, synthesis of a single crystal In—Ga—Zn oxide was reported (see Non-Patent Document 1). Further, in 1995, it was reported that an In—Ga—Zn oxide has a homologous structure and is represented by a composition formula InGaO₃(ZnO)ₘ (m is a natural number) (see Non-Patent Document 2).

In 2012, it was reported that a transistor including a crystalline In—Ga—Zn oxide film has more excellent electrical characteristics and higher reliability than a transistor including an amorphous In—Ga—Zn oxide film (see Non-Patent Document 3). Non-Patent Document 3 reports that a grain boundary is not clearly observed in an In—Ga—Zn oxide film including a c-axis aligned crystal (CAAC).

### REFERENCE

### Patent Document

[Patent Document 1] Japanese Published Patent Application No. 2006-165528

### Non-Patent Document

[Non-Patent Document 1] N. Kimizuka, and T. Mohri, “Spinel, YBFe₂O₄, and YB₂Fe₃O₇ Types of Structures for Compounds in the In₂O₃ and Sc₂O₃-A₂O₃—BO Systems (A; Fe, Ga, or Al; B: Mg, Mn, Fe, Ni, Cu, or Zn) at Temperatures over 1000° C.”, J. Solid State Chem., Vol. 60, 1985, pp. 382-384
[Non-Patent Document 2] N. Kimizuka, M. Isobe, and M. Nakamura, “Syntheses and Single-Crystal Data of Homologous Compounds, In₂O₃(ZnO)ₘ, (m=3, 4, and 5), InGaO₃(ZnO)₃, and Ga₂O₃(ZnO)ₘ, (m=7, 8, 9, and 16) in the In₂O₃—ZnGa₂O₄—ZnO System”, J. Solid State Chem., 1995, Vol. 116, pp. 170-178
[Non-Patent Document 3] S. Yamazaki, J. Koyama, Y. Yamamoto, and K. Okamoto, “Research, Development, and Application of Crystalline Oxide Semiconductor”, SID 2012 DIGEST, pp. 183-186

### DISCLOSURE OF INVENTION

An object of the present invention is to provide a method for forming a crystalline oxide semiconductor film which can be used to form a semiconductor film of a transistor or the like. In particular, an object of the present invention is to provide a method for forming a crystalline oxide semiconductor film having few defects such as grain boundaries.

Another object is to provide a semiconductor device using an oxide semiconductor film. Another object is to provide a transistor having high field-effect mobility. Another object is to provide a transistor having stable electrical characteristics. Another object is to provide a transistor having low off-state current (current in an off state). Another object is to provide a semiconductor device including the transistor. Another object is to provide a novel semiconductor device.

Note that the description of these objects do not disturb the existence of other objects. In one embodiment of the present invention, there is no need to achieve all the objects. Other objects will be apparent from and can be derived from the description of the specification, the drawings, the claims, and the like.

(1) One embodiment of the present invention is a method for forming an oxide semiconductor film using a sputtering apparatus including a target containing a crystalline In—Ga—Zn oxide, a substrate, and a magnet, and the method includes the steps of: generating plasma by applying a potential difference between the target and the substrate; and separating a flat-plate-like In—Ga—Zn oxide in which a first layer including a gallium atom, a zinc atom, and an oxygen atom, a second layer including an indium atom and an oxygen atom, and a third layer including a gallium atom, a zinc atom, and an oxygen atom are stacked in this order, by making an ion generated in the plasma collide with the target. The flat-plate-like In—Ga—Zn oxide is negatively charged by passing through the plasma, gets close to a top surface of the substrate while keeping crystallinity, moves over the top surface of the substrate due to a magnetic field of the magnet and current flowing from the substrate to the target, and then is deposited.

(2) Another embodiment of the present invention is the method for forming an oxide semiconductor film described in (1) in which an oxygen atom bonded to an indium atom on a side surface of the flat-plate-like In—Ga—Zn oxide, or an oxygen atom bonded to the indium atom, a gallium atom, and a zinc atom which is on a side surface of the flat-plate-like In—Ga—Zn oxide is negatively charged.

(3) Another embodiment of the present invention is the method for forming an oxide semiconductor film described in (2) in which the shape of the flat-plate-like In—Ga—Zn oxide is kept by making the negatively charged oxygen atoms repel each other.

(4) Another embodiment of the present invention is the method for forming an oxide semiconductor film described in any one of (1) to (3) in which when the flat-plate-like In—Ga—Zn oxide moves over the top surface of the substrate, the side surface of the flat-plate-like In—Ga—Zn oxide is firmly bonded to the top surface of the substrate after being bonded to a side surface of an In—Ga—Zn oxide which has already been deposited.

(5) Another embodiment of the present invention is the method for forming an oxide semiconductor film described in (4) in which when the bonding is made, the oxygen atom bonded to the side surface of the flat-plate-like In—Ga—Zn oxide is released.

(6) Another embodiment of the present invention is the method for forming an oxide semiconductor film described in (5) in which an oxygen vacancy is filled with the released oxygen atom.

(7) Another embodiment of the present invention is the method for forming an oxide semiconductor film described in any one of (1) to (6) in which when the flat-plate-like In—Ga—Zn oxide is deposited over the top surface of the substrate, the angle between a normal vector of the top surface of the substrate and a c-axis of the flat-plate-like In—Ga—Zn oxide is greater than or equal to −10° and less than or equal to 10°.

(8) Another embodiment of the present invention is the method for forming an oxide semiconductor film described in any one of (1) to (7) in which a composition formula of the crystalline In—Ga—Zn oxide contained in the target is InGaZnO₄.

(9) Another embodiment of the present invention is the method for forming an oxide semiconductor film described in any one of (1) to (8) in which the ion is an oxygen cation.

It is possible to provide a method for forming a crystalline oxide semiconductor film which can be used to form a semiconductor film of a transistor or the like. In particular, it is possible to provide a method for forming a crystalline oxide semiconductor film with less defects such as grain boundaries.

It is possible to provide a semiconductor device using the oxide semiconductor film. It is possible to provide a transistor having high field-effect mobility. It is possible to provide a transistor having stable electrical characteristics. It is possible to provide a transistor with low off-state current (current in an off state). It is possible to provide a semiconductor device including the transistor. It is possible to provide a novel semiconductor device. Note that the description of these effects does not disturb the existence of other effects. One embodiment of the present invention does not necessarily achieve all the objects listed above. Other effects will be apparent from and can be derived from the description of the specification, the drawings, the claims, and the like.

### BRIEF DESCRIPTION OF DRAWINGS

In the accompanying drawings:

FIG. 1 is a schematic diagram of a deposition model of a CAAC-OS film and illustrates a pellet;

FIGS. 2A to 2C illustrate a pellet;

FIG. 3 illustrates force applied to a pellet on a formation surface;

FIGS. 4A and 4B illustrate movement of a pellet on a formation surface;

FIGS. 5A and 5B are cross-sectional views illustrating examples of a CAAC-OS film formed by depositing pellets;

FIGS. 6A and 6B show transmission electron diffraction patterns of a CAAC-OS film;

FIGS. 7A to 7C show analysis results of a CAAC-OS film and a single crystal oxide semiconductor film obtained with an X-ray diffractometer;

FIGS. 8A and 8B are plan-view TEM images of a zinc oxide film and a CAAC-OS film;

FIGS. 9A1, 9A2, 9B1, and 9B2 are high-resolution plan-view TEM images of a CAAC-OS film and show image analysis results thereof;

FIGS. 10A to 10D are a high-resolution plan-view TEM image of a CAAC-OS film and transmission electron diffraction patterns of regions thereof;

FIGS. 11A to 11D are a high-resolution plan-view TEM image of a polycrystalline OS film and transmission electron diffraction patterns of regions thereof;

FIGS. 12A to 12C are a cross-sectional TEM image and a high-resolution cross-sectional TEM image of a CAAC-OS film, and shows image analysis results of the high-resolution cross-sectional TEM image;

FIGS. 13A to 13D are cross-sectional TEM images and a local Fourier transform image of an oxide semiconductor;

FIGS. 14A to 14C are cross-sectional TEM images and a local Fourier transform image of an oxide semiconductor;

FIGS. 15A to 15C are cross-sectional TEM images and a local Fourier transform image of an oxide semiconductor;

FIGS. 16A and 16B illustrate an example of a transmission electron diffraction measurement apparatus, and FIGS. 16C and 16D show nanobeam electron diffraction patterns of oxide semiconductor films;

FIG. 17A shows an example of structural analysis by transmission electron diffraction measurement and FIGS. 17B and 17C show plan-view TEM images;

FIGS. 18A and 18B show an InGaZnO₄ crystal;

FIGS. 19A and 19B show a structure of InGaZnO₄ before collision of an atom, and the like;

FIGS. 20A and 20B show a structure of InGaZnO₄ after collision of an atom, and the like;

FIGS. 21A and 21B show trajectories of atoms after collision of atoms;

FIGS. 22A and 22B are cross-sectional HAADF-STEM images of a CAAC-OS film and a target;

FIG. 23 is a top view illustrating an example of a deposition apparatus;

FIGS. 24A to 24C illustrate a structure example of a deposition apparatus;

FIGS. 25A to 25C are a top view and cross-sectional views illustrating a transistor of one embodiment of the present invention;

FIGS. 26A and 26B are cross-sectional views illustrating a transistor of one embodiment of the present invention;

FIGS. 27A and 27B are a top view and a cross-sectional view illustrating a transistor of one embodiment of the present invention;

FIGS. 28A and 28B are cross-sectional views illustrating transistors of embodiments of the present invention;

FIGS. 29A and 29B are a top view and a cross-sectional view illustrating a transistor of one embodiment of the present invention;

FIGS. 30A and 30B are cross-sectional views illustrating transistors of embodiments of the present invention;

FIGS. 31A and 31B are a top view and a cross-sectional view illustrating a transistor of one embodiment of the present invention;

FIGS. 32A and 32B are a top view and a cross-sectional view illustrating a transistor of one embodiment of the present invention;

FIGS. 33A and 33B are cross-sectional views illustrating transistors of embodiments of the present invention;

FIGS. 34A to 34D are cross-sectional views and circuit diagrams of semiconductor devices of embodiments of the present invention;

FIGS. 35A and 35B are each a circuit diagram of a memory device of one embodiment of the present invention;

FIG. 36 is a block diagram of an RFID tag of one embodiment of the present invention;

FIGS. 37A to 37F show application examples of an RFID tag of one embodiment of the present invention;

FIG. 38 is a block diagram illustrating a CPU of one embodiment of the present invention;

FIG. 39 is a circuit diagram of a memory element of one embodiment of the present invention;

FIGS. 40A to 40C are circuit diagrams of a display device of one embodiment of the present invention;

FIG. 41 illustrates a display module of one embodiment of the present invention; and

FIGS. 42A to 42F each illustrate an electronic device of one embodiment of the present invention.

### BEST MODE FOR CARRYING OUT THE INVENTION

Hereinafter, embodiments of the present invention will be described in detail with reference to the drawings. However, the present invention is not limited to the description below, and it is easily understood by those skilled in the art that modes and details disclosed herein can be modified in various ways. Further, the present invention is not construed as being limited to description of the embodiments. In describing structures of the present invention with reference to the drawings, common reference numerals are used for the same portions in different drawings. Note that the same hatched pattern is applied to similar parts, and the similar parts are not especially denoted by reference numerals in some cases.

Note that the size, the thickness of films (layers), or regions in diagrams is sometimes exaggerated for simplicity.

A voltage usually refers to a potential difference between a given potential and a reference potential (e.g., a source potential or a ground potential (GND)). A voltage can be referred to as a potential and vice versa.

Note that the ordinal numbers such as “first” and “second” in this specification are used for the sake of convenience and do not denote the order of steps or the stacking order of layers. Therefore, for example, the term “first” can be replaced with the term “second”, “third”, or the like as appropriate. In addition, the ordinal numbers in this specification and the like are not necessarily the same as the ordinal numbers used to specify one embodiment of the present invention.

Note that a “semiconductor” includes characteristics of an “insulator” in some cases when the conductivity is sufficiently low, for example. Further, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Further, a “semiconductor” includes characteristics of a “conductor” in some cases when the conductivity is sufficiently high, for example. Further, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of a semiconductor. For example, an element with a concentration of lower than 0.1 atomic % is an impurity. When an impurity is contained, the density of states (DOS) may be formed in a semiconductor, the carrier mobility may be decreased, or the crystallinity may be decreased, for example. When the semiconductor is an oxide semiconductor, examples of an impurity which changes the characteristics of the semiconductor include Group 1 elements, Group 2 elements, Group 14 elements, Group 15 elements, and transition metals other than the main components; specifically, there are hydrogen (including water), lithium, sodium, silicon, boron, phosphorus, carbon, and nitrogen, for example. When the semiconductor is an oxide semiconductor, oxygen vacancies may be formed by entry of impurities such as hydrogen, for example. Further, when the semiconductor is silicon, examples of an impurity which changes the characteristics of the semiconductor include oxygen, Group 1 elements except hydrogen, Group 2 elements, Group 13 elements, and Group 15 elements.

### <Deposition Model of CAAC-OS Film>

A deposition model of a c-axis aligned crystalline oxide semiconductor (CAAC-OS) film, which is a kind of crystalline oxide semiconductor film, is described below.

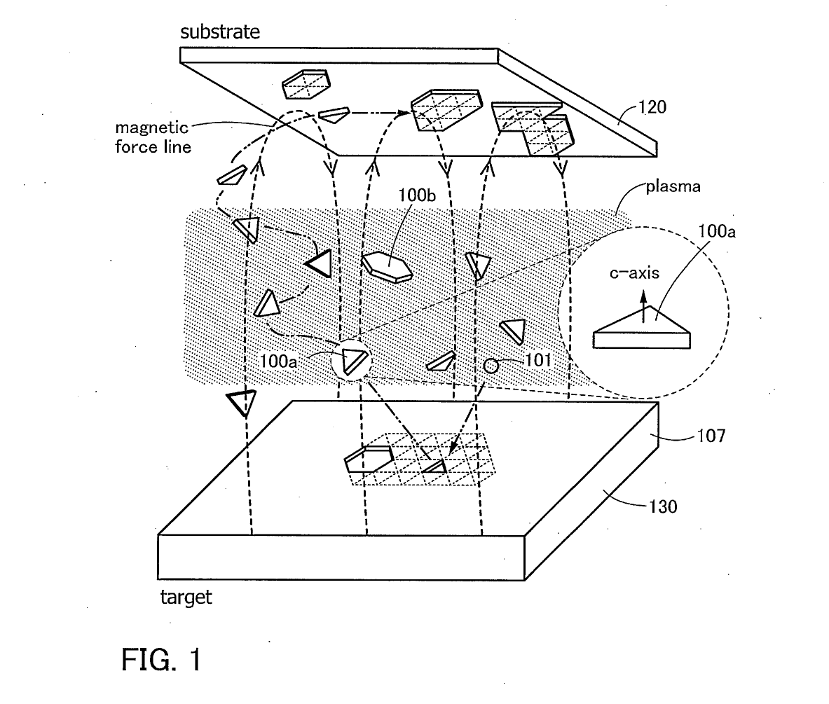

FIG. 1 is a schematic diagram of a deposition chamber illustrating a state where a CAAC-OS film is deposited by a sputtering method.

A target 130 is attached to a backing plate. Under the target 130 and the backing plate, a plurality of magnets are placed. The plurality of magnets generate a magnetic field over the target 130. A sputtering method in which the disposition speed is increased by utilizing a magnetic field of magnets is referred to as a magnetron sputtering method.

The target 130 has a polycrystalline structure in which a cleavage plane exists in at least one crystal grain.

A substrate 120 is placed to face the target 130, and the distance d (also referred to as target-substrate distance (T-S distance)) is greater than or equal to 0.01 m and less than or equal to 1 m, preferably greater than or equal to 0.02 m and less than or equal to 0.5 m. The deposition chamber is mostly filled with a deposition gas (e.g., an oxygen gas, an argon gas, or a mixed gas containing oxygen at 50 vol % or higher) and controlled to higher than or equal to 0.01 Pa and lower than or equal to 100 Pa, preferably higher than or equal to 0.1 Pa and lower than or equal to 10 Pa. Here, discharge starts by application of a voltage at a constant value or higher to the target 130, and plasma is observed. Note that the magnetic field over the target 130 forms a high-density plasma region. In the high-density plasma region, the deposition gas is ionized, so that an ion 101 is generated. Examples of the ion 101 include an oxygen cation (O⁺) and an argon cation (Ar⁺).

The ion 101 is accelerated toward the target 130 side by an electric field, and collides with the target 130 eventually. At this time, a pellet 100a and a pellet 100b which are flat-plate-like (pellet-like) sputtered particles are separated and sputtered from the cleavage plane. Note that structures of the pellet 100a and the pellet 100b may be distorted by an impact of collision of the ion 101.

The pellet 100a is a flat-plate-like (pellet-like) sputtered particle having a triangle plane, e.g., regular triangle plane. The pellet 100b is a flat-plate-like (pellet-like) sputtered particle having a hexagon plane, e.g., regular hexagon plane. Note that a flat-plate-like (pellet-like) sputtered particle such as the pellet 100a and the pellet 100b is collectively called a pellet 100. The shape of a flat plane of the pellet 100 is not limited to a triangle or a hexagon. For example, the flat plane may have a shape formed by combining greater than or equal to 2 and less than or equal to 6 triangles. For example, a square (rhombus) is formed by combining two triangles (regular triangles) in some cases.

The thickness of the pellet 100 is determined depending on the kind of deposition gas and the like. The thicknesses of the pellets 100 are preferably uniform; the reasons thereof are described later. In addition, the sputtered particle preferably has a pellet shape with a small thickness as compared to a dice shape with a large thickness.

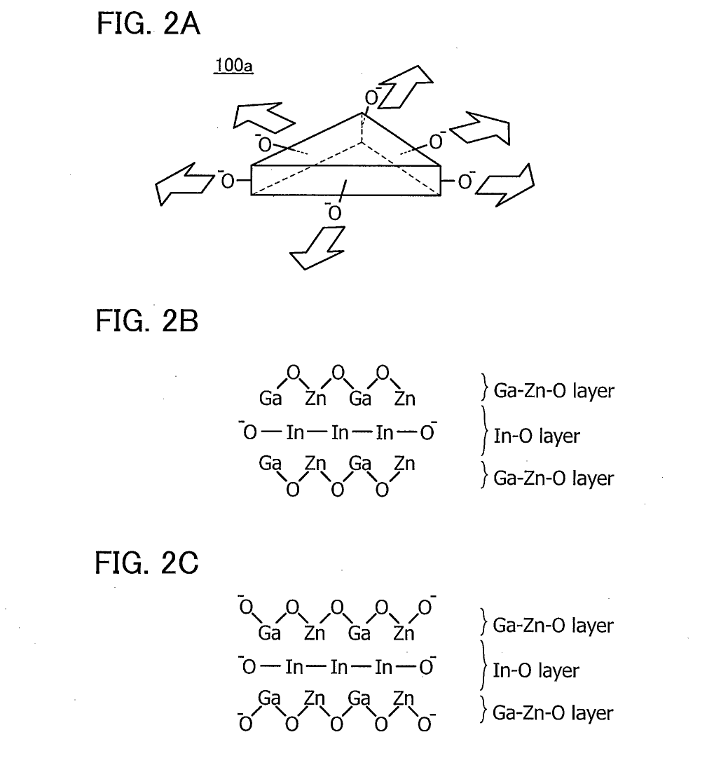

The pellet 100 receives a charge when passing through the plasma, so that side surfaces thereof are negatively or positively charged in some cases. The pellet 100 includes oxygen atoms on its side surfaces, and the oxygen atoms may be negatively charged. For example, a case in which the pellet 100a includes, on side surfaces, oxygen atoms that are negatively charged is illustrated in FIG. 2A. As in this view, when the side surfaces are charged in the same polarity, charges repel each other, and accordingly, the pellet 100a can maintain a flat-plate shape. In the case where a CAAC-OS film is an In—Ga—Zn oxide film, there is a possibility that an oxygen atom bonded to an indium atom is negatively charged as illustrated in FIG. 2B. There is another possibility that an oxygen atom bonded to an indium atom, a gallium atom, or a zinc atom is negatively charged as illustrated in FIG. 2C.

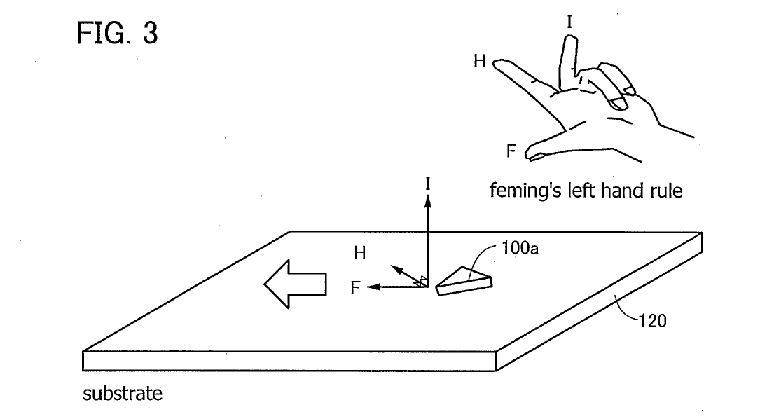

As illustrated in FIG. 1, the pellet 100 flies like a kite in plasma and flutters up to the substrate 120, for example. Since the pellets 100 are charged, when the pellet 100 gets close to a region where another pellet 100 has already been deposited, repulsion is generated. Here, above the substrate 120, a magnetic field is generated in a direction parallel to a top surface of the substrate 120. A potential difference is given between the substrate 120 and the target 130, and accordingly, current flows from the substrate 120 toward the target 130. Thus, the pellet 100 is given a force (Lorentz force) on a surface of the substrate 120 by an effect of the magnetic field and the current (see FIG. 3). This is explainable with Fleming's left-hand rule. In order to increase a force applied to the pellet 100, it is preferable to provide, on the top surface, a region where the magnetic field in a direction parallel to the top surface of the substrate 120 is 10 G or higher, preferably 20 G or higher, further preferably 30 G or higher, still further preferably 50 G or higher. Alternatively, it is preferable to provide, on the top surface, a region where the magnetic field in a direction parallel to the top surface of the substrate is 1.5 times or higher, preferably twice or higher, further preferably 3 times or higher, still further preferably 5 times or higher as high as the magnetic field in a direction perpendicular to the top surface of the substrate 120.

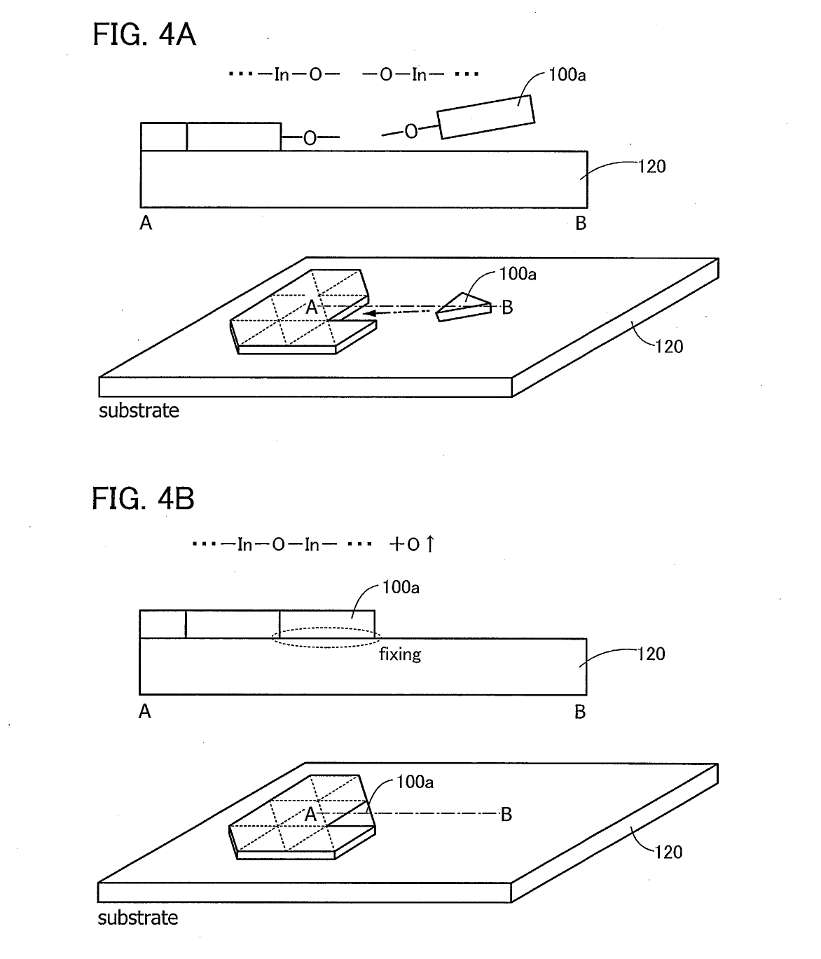

As a result, as illustrated in FIG. 4A, the pellet 100 glides above the surface of the substrate 120. The glide of the pellet 100 is caused in a state where the flat plane faces the substrate 120. Then, as illustrated in FIG. 4B, when the pellet 100 reaches the side surface of another pellet 100 that has been already deposited, the side surfaces of the pellets 100 are bonded. At this time, the oxygen atom on the side surface of the pellet 100 is released. With the released oxygen atom, oxygen vacancies in a CAAC-OS film are filled in some cases; thus, the CAAC-OS film has a low density of defect states.

Further, the pellet 100 is heated over the substrate 120, whereby atoms are rearranged, and the structure distortion caused by the collision of the ion 101 can be reduced. The pellet 100 whose structure distortion is reduced is substantially a single crystal. Even when the pellets 100 are heated after being bonded, expansion and contraction of the pellet 100 itself hardly occur, which is caused by turning the pellet 100 to be substantially a single crystal. Thus, formation of defects such as a grain boundary due to expansion of a space between the pellets 100 can be prevented, and accordingly, generation of crevasses can be prevented. Further, the space is filled with elastic metal atoms and the like, whereby the elastic metal atoms and the like connect the pellets 100 which are not aligned with each other as a highway.

It is considered that as shown in such a model, the pellets 100 are deposited over the substrate 120. Thus, a CAAC-OS film can be deposited even when a surface over which a film is formed (film formation surface) does not have a crystal structure, which is different from film deposition by epitaxial growth. For example, even when a top surface (film formation surface) of the substrate 120 has an amorphous structure, a CAAC-OS film can be formed.

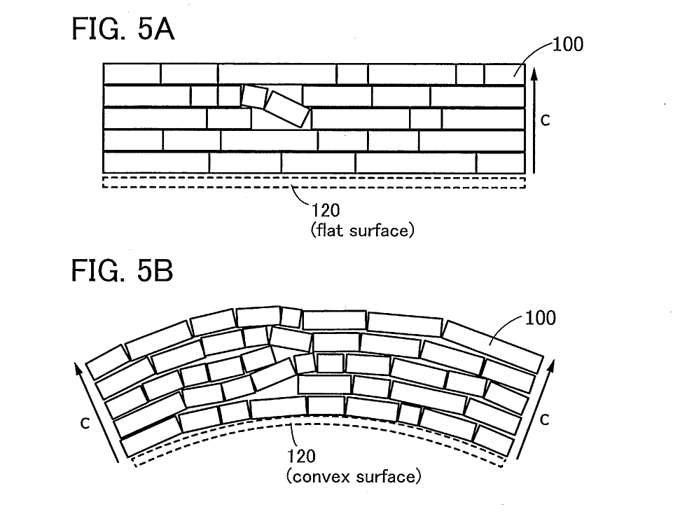

Further, it is found that in formation of the CAAC-OS film, the pellets 100 are arranged in accordance with a shape of the top surface of the substrate 120 that is the film formation surface even when the film formation surface has unevenness. For example, in the case where the top surface of the substrate 120 is flat at the atomic level as illustrated in FIG. 5A, the pellets 100 are arranged so that flat planes parallel to the a-b plane face downwards; thus, a layer with a uniform thickness, flatness, and high crystallinity is formed. By stacking n layers (n is a natural number), the CAAC-OS film can be obtained.

In the case where the top surface of the substrate 120 has unevenness as illustrated in FIG. 5B, a CAAC-OS film in which n layers (n is a natural number) in each of which the pellets 100 are arranged along the convex surface are stacked is formed. Since the substrate 120 has unevenness, as compared to the case in FIG. 5A, a gap is easily generated between the pellets 100 in the CAAC-OS in some cases. Note that owing to intermolecular force, the pellets 100 are arranged so that a gap between the pellets is as small as possible even over the unevenness surface. Therefore, even when the film formation surface has unevenness, a CAAC-OS film with high crystallinity can be formed.

Accordingly, a CAAC-OS film does not need laser crystallization, and deposition can be uniformly performed even in the case of a large-sized glass substrate.

Since the CAAC-OS film is deposited according to such a model, the sputtered particles preferably have a pellet shape with a small thickness. Note that in the case where the sputtered particles have a dice shape with a large thickness, planes of the particles facing the substrate 120 are not the same and thus, the thickness and the orientation of the crystals cannot be uniform in some cases.

Note that an In—Ga—Zn oxide film formed by a sputtering method has a smaller proportion of zinc atoms than a target has. This might be because zinc oxide is more likely to be vaporized than indium oxide or gallium oxide. When an In—Ga—Zn oxide film has a composition ratio which is significantly different from the stoichiometric composition, e.g., InₓGa₂₋ₓO₃(ZnO)ₘ (0<x<2, m is a natural number), the film to be formed has lower crystallinity or is partly polycrystallized in some cases.

For example, the proportion of zinc atoms in the target may be increased in advance to form a CAAC-OS film having high crystallinity. By controlling the atomic ratio of the target, the atomic ratio of the In—Ga—Zn oxide film to be formed can have a value closer to the stoichiometric composition, e.g., InₓGa₂₋ₓO₃(ZnO)ₘ (0<x<2, m is a natural number).

According to the above-described model, a CAAC-OS film having high crystallinity can be formed even over a formation surface having an amorphous structure.

### <Properties of CAAC-OS Film>

A CAAC-OS film, which is a crystalline oxide semiconductor film of this embodiment, will be described below. The CAAC-OS film is an oxide semiconductor film which has c-axis alignment while the directions of a-axes and b-axes are different and in which c-axes are aligned in a direction parallel to a normal vector of a formation surface or a normal vector of a top surface.

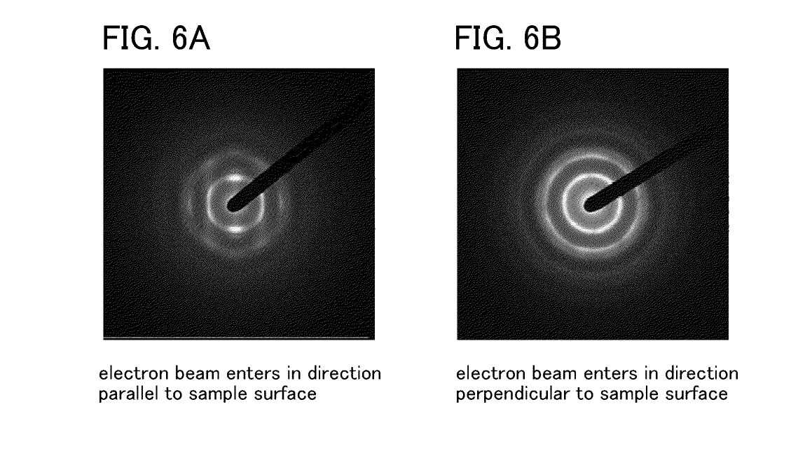

FIG. 6A shows a diffraction pattern (also referred to as a selected-area transmission electron diffraction pattern) when an electron beam having a probe diameter of 300 nm enters an In—Ga—Zn oxide film that is a CAAC-OS film in a direction parallel to a sample surface. As in FIG. 6A, spots due to the (009) plane of an InGaZnO₄ crystal are observed. This indicates that crystals in the CAAC-OS film have c-axis alignment and that the c-axes are aligned in a direction substantially perpendicular to the formation surface or the top surface of the CAAC-OS film. Meanwhile, FIG. 6B shows a diffraction pattern when an electron beam having a probe diameter of 300 nm enters the same sample in a direction perpendicular to the sample surface. As in FIG. 6B, a ring-like diffraction pattern is observed. Thus, it is found that crystals in the CAAC-OS film do not have a-axis alignment and b-axis alignment. It is supposed that the first ring in FIG. 6B is derived from the (010) plane, the (100) plane, and the like of the crystals of InGaZnO₄. Further, it is supposed that the second ring in FIG. 6B is derived from the (110) plane and the like.

In this specification, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

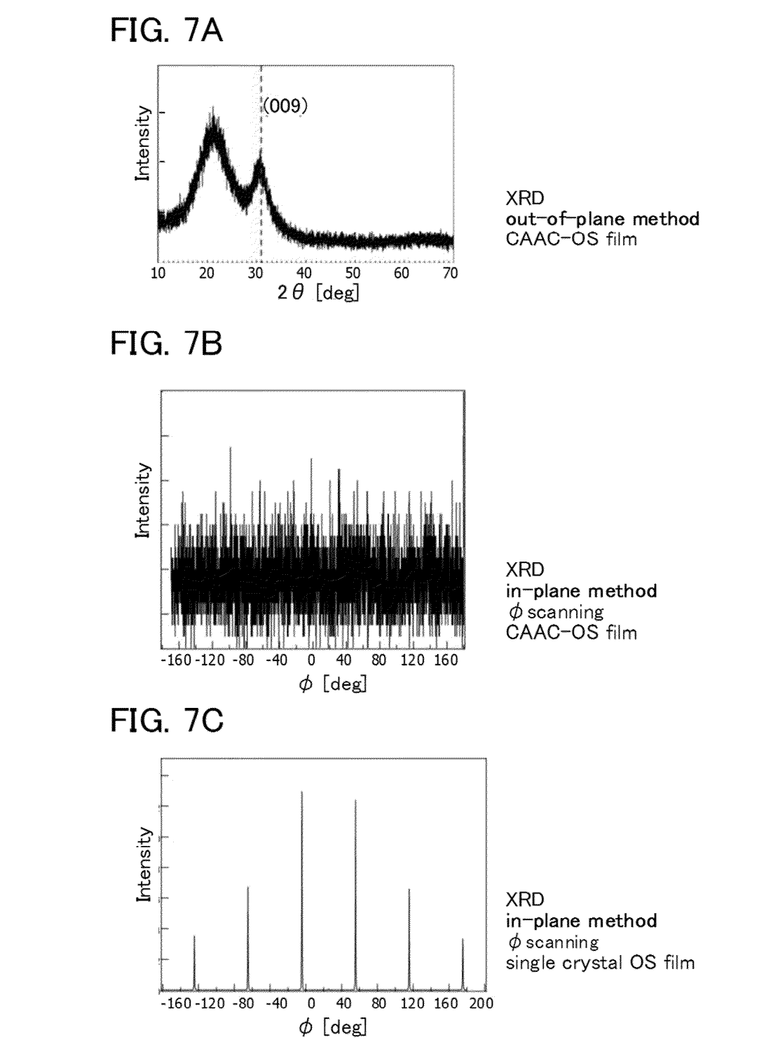

A CAAC-OS film is subjected to structural analysis with an X-ray diffraction (XRD) apparatus. For example, when the CAAC-OS film including an InGaZnO₄ crystal is analyzed by an out-of-plane method, a peak appears when the diffraction angle (2θ) is around 31° (see FIG. 7A). Since this peak is derived from the (009) plane of the InGaZnO₄ crystal, it can also be confirmed from the structural analysis with the XRD apparatus that crystals in the CAAC-OS film have c-axis alignment and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears when 2θ is around 56°. This peak is derived from the (110) plane of the InGaZnO₄ crystal. In the case of the CAAC-OS film, when analysis (φ scan) is performed with 2θ fixed at around 56° and with the sample rotated using a normal vector of the sample surface as an axis (φ axis), a peak is not clearly observed (see FIG. 7B). In contrast, in the case of a single crystal oxide semiconductor film of InGaZnO₄, when φ scan is performed with 2θ fixed at around 56°, six peaks appear (see FIG. 7C). The six peaks are derived from crystal planes equivalent to the (110) plane. Accordingly, from the structural analysis with the XRD apparatus, it can be confirmed that the directions of a-axes and b-axes are different in the CAAC-OS film.

In a transmission electron microscope (TEM) image of the CAAC-OS film, a boundary between crystal regions, that is, a grain boundary is not clearly observed. Thus, in the CAAC-OS film, a reduction in electron mobility due to the grain boundary is less likely to occur.

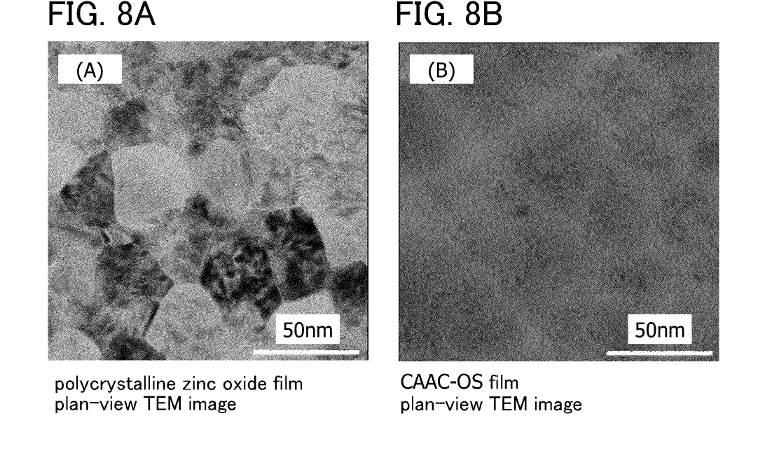

In general, according to the TEM image of a polycrystalline zinc oxide film observed in a direction substantially perpendicular to the sample surface (plan-view TEM image), a clear grain boundary can be seen as shown in FIG. 8A. On the other hand, according to the plan-view TEM image of the same measurement region in the CAAC-OS film, a grain boundary cannot be seen as shown in FIG. 8B.

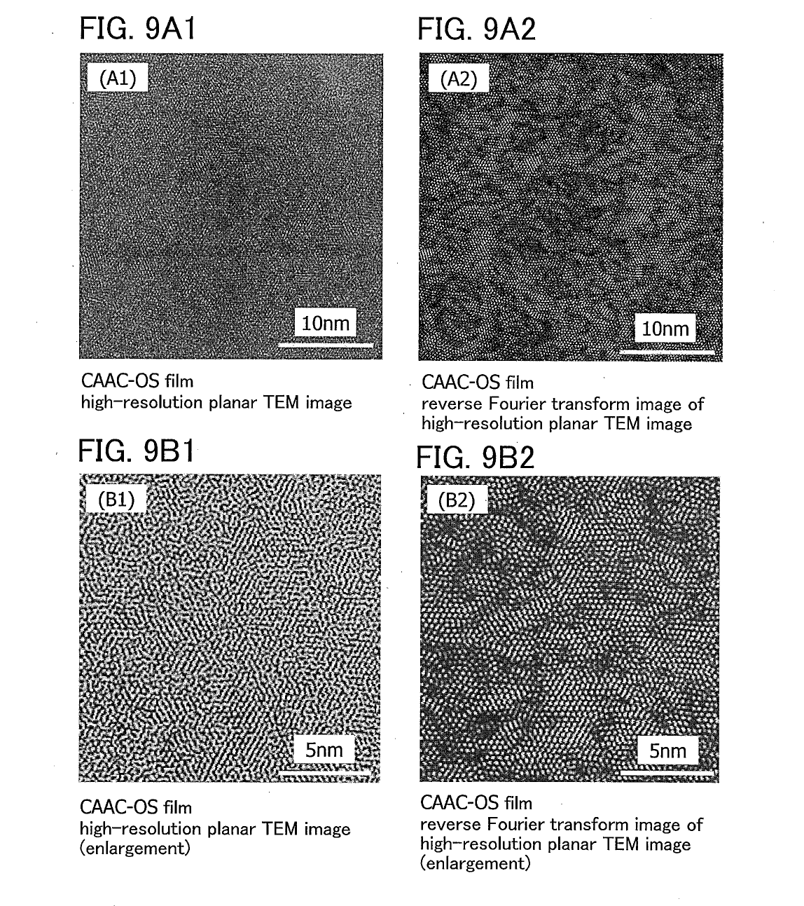

Further, a combined analysis image of a bright-field image which is obtained by plan-view TEM analysis and a diffraction pattern of the CAAC-OS film (also referred to as a high-resolution plan-view TEM image) was obtained (see FIG. 9A1). Even in the high-resolution plan-view TEM image, a clear grain boundary cannot be seen in the CAAC-OS film.

Here, FIG. 9A2 is an image obtained in such a manner that the high-resolution plan-view TEM image in FIG. 9A1 is transferred by the Fourier transform, filtered, and then transferred by the inversely Fourier transform. By such image processing, a real space image can be obtained in which noises are removed from the high-resolution plan-view TEM image so that only periodic components are extracted. By the image processing, a crystal region can be easily observed, and arrangement of metal atoms in a triangular or hexagonal configuration becomes clear. Note that it is found that there is no regularity of arrangement of metal atoms between different crystal regions.

A further enlarged high-resolution plan-view TEM image of the CAAC-OS film is obtained (see FIG. 9B1). Even in the enlarged high-resolution plan-view TEM image, a clear grain boundary cannot be observed in the CAAC-OS film.

Here, FIG. 9B2 is an image obtained in such a manner that the enlarged high-resolution plan-view TEM image in FIG. 9B1 is transferred by the Fourier transform, filtered, and then transferred by the inversely Fourier transform. The enlarged high-resolution plan-view TEM image is subjected to the image processing; thus, arrangement of metal atoms can be observed more clearly. As in FIG. 9B2, metal atoms are arranged in a regular triangular configuration with interior angles of 60° or a regular hexagonal configuration with interior angles of 120°.

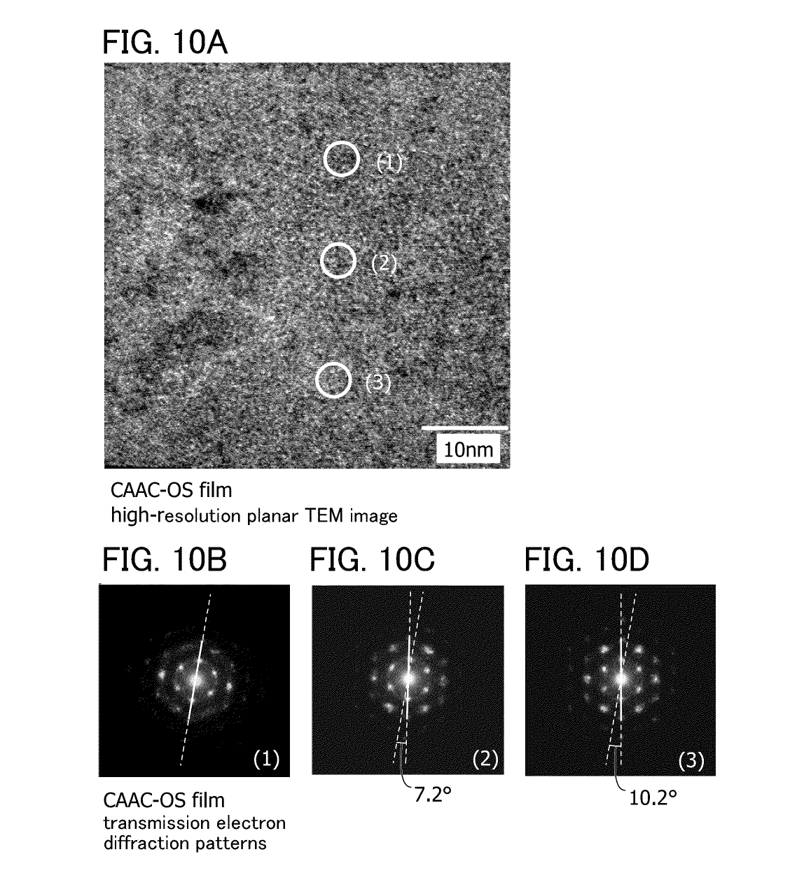

Next, to find how crystal regions are connected in a plane direction in the CAAC-OS film, transmission electron diffraction patterns in regions (1), (2), and (3) of a high-resolution plan-view TEM image in FIG. 10A are obtained and shown in FIGS. 10B, 10C, and 10D, respectively. Note that an electron beam with a probe diameter of 1 nm is used to measure the transmission electron diffraction patterns.

From the transmission electron diffraction patterns, it is found that the CAAC-OS film has a crystal lattice with six-fold symmetry. Thus, it is also confirmed from the transmission electron diffraction patterns in the regions of the high-resolution plan-view TEM image that the CAAC-OS film has c-axis alignment. Further, it is confirmed that the CAAC-OS film has extremely high crystallinity locally.

As in FIGS. 10A to 10D, when attention is focused on the transmission electron diffraction patterns in the regions (1), (2), and (3), the angle of the a-axis (indicated by a white solid line) gradually changes in each of the diffraction patterns. Specifically, when the angle of the a-axis in (1) is 0°, the angle of the a-axis in (2) is changed by 7.2° with respect to the c-axis. Similarly, when the angle of the a-axis in (1) is 0°, the angle of the a-axis in (3) is changed by 10.2° with respect to the c-axis. Thus, the CAAC-OS film has a continuous structure in which different crystal regions are connected while maintaining c-axis alignment.

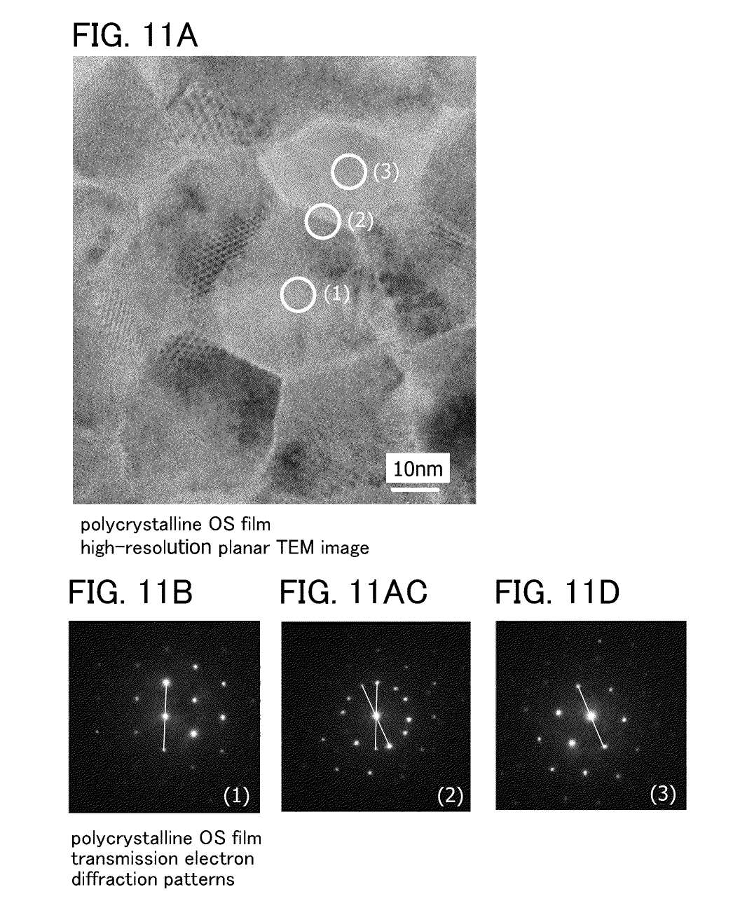

Note that according to a plan-view TEM image of an In—Ga—Zn oxide film crystallized by a laser beam, a clear grain boundary can be seen as shown in FIG. 11A. Thus, the In—Ga—Zn oxide film crystallized by a laser beam is a polycrystalline oxide semiconductor film (polycrystalline OS film).

Next, to find how crystal regions are connected in a plane direction in the polycrystalline OS film, transmission electron diffraction patterns in regions (1), (2), and (3) of the plan-view TEM image in FIG. 11A are obtained and shown in FIGS. 11B, 11C, and 11D, respectively. Note that an electron beam with a probe diameter of 1 nm is used to measure the transmission electron diffraction patterns.

As in FIGS. 11A to 11D, when attention is focused on the transmission electron diffraction patterns in the regions (1), (2), and (3), the region (2) has a diffraction pattern in which the diffraction patterns in the regions (1) and (3) overlap with each other. Accordingly, the grain boundary in the polycrystalline OS film can be confirmed from the electron diffraction patterns.

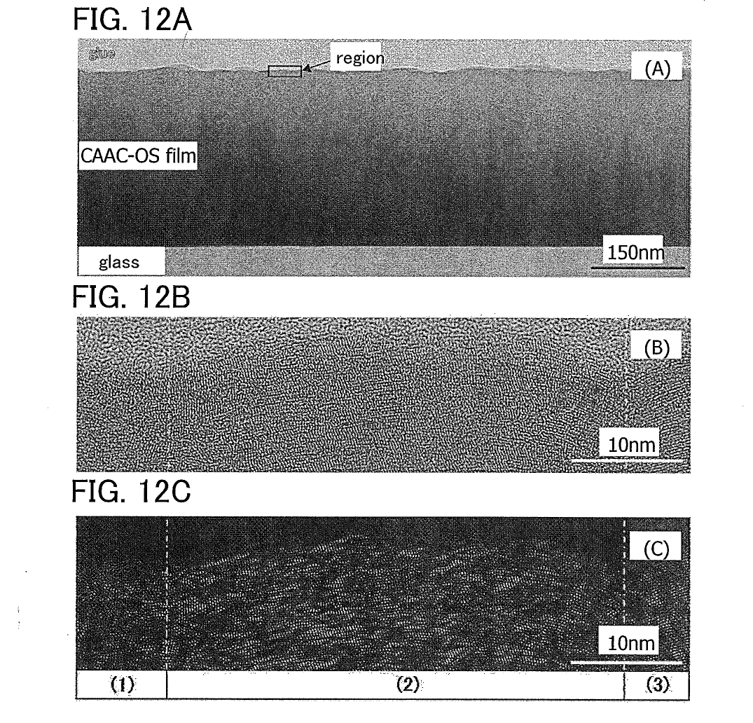

Next, the CAAC-OS film is observed with a TEM in a direction substantially parallel to the sample surface (a cross-sectional TEM image is obtained) (see FIG. 12A). A combined analysis image of a bright-field image which is obtained by cross-sectional TEM analysis and a diffraction pattern of a region surrounded by a frame (also referred to as a high-resolution cross-sectional TEM image) is obtained in the cross-sectional TEM image shown in FIG. 12A (see FIG. 12B).

Here, FIG. 12C is an image obtained in such a manner that the high-resolution cross-sectional TEM image in FIG. 12B is transferred by the Fourier transform, filtered, and then transferred by the inversely Fourier transform. By such image processing, a real space image can be obtained in which noises are removed from the high-resolution cross-sectional TEM image so that only periodic components are extracted. By the image processing, a crystal region can be easily observed, and arrangement of metal atoms in a layered manner can be found. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

FIG. 12B can be divided into regions denoted by (1), (2), and (3) from the left. When each of the regions is regarded as one large crystal region, the size of each of the crystal regions is found to be approximately 50 nm. At this time, between (1) and (2) and between (2) and (3), a clear grain boundary cannot be found. In FIG. 12C, crystal regions are connected between (1) and (2) and between (2) and (3).

It can be confirmed by image analysis that regions in (1) and (2) and regions in (2) and (3) are connected in FIG. 12B.

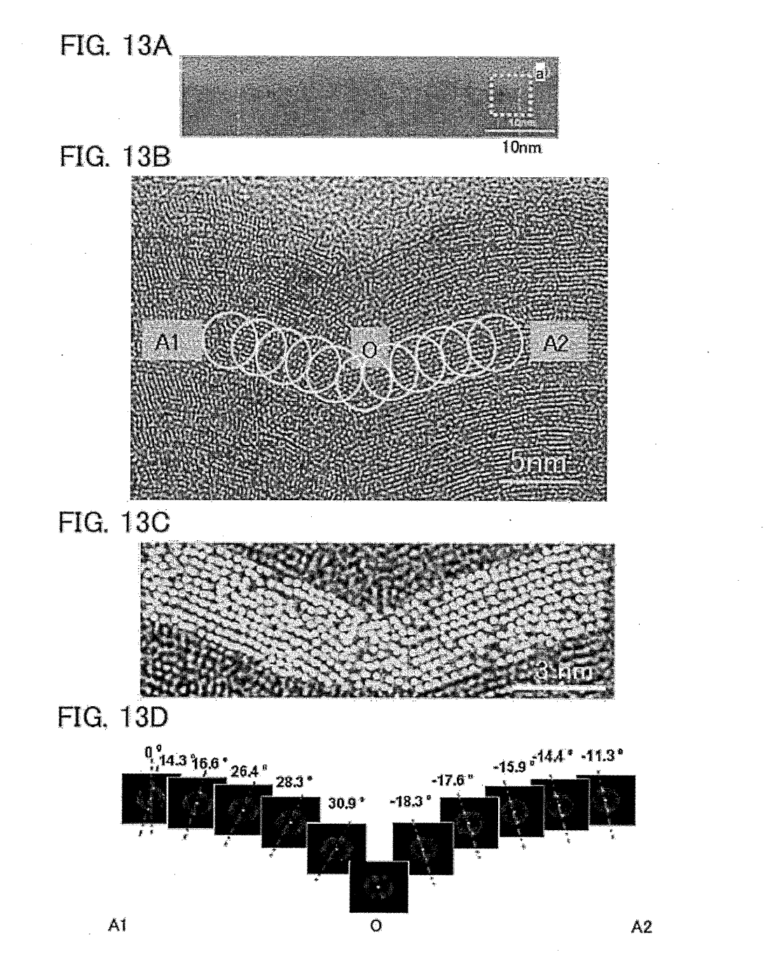

FIG. 13A is the same as FIG. 12B. FIG. 13B is an enlarged cross-sectional TEM image of a region a surrounded by a dotted line in FIG. 13A, and FIG. 13C is a diagram in which atomic arrangement is highlighted for easy understanding of the cross-sectional TEM image of FIG. 13B.

FIG. 13D is Fourier transform images of regions each surrounded by a circle (the diameter is about 4 nm) between A1 and O and between O and A2 in FIG. 13B. C-axis alignment can be observed in each region in FIG. 13D. The c-axis direction between A1 and O is different from that between O and A2, which indicates that a crystal portion in the region between A1 and O is different from that between O and A2. In addition, between A1 and O, the angle of the c-axis continuously and gradually changes, for example 14.3°, 16.6°, and 26.4°, when a direction perpendicular to the sample surface is set to 0°. Similarly, between O and A2, the angle of the c-axis continuously and gradually changes, for example −18.3°, −17.6°, and −15.9°.

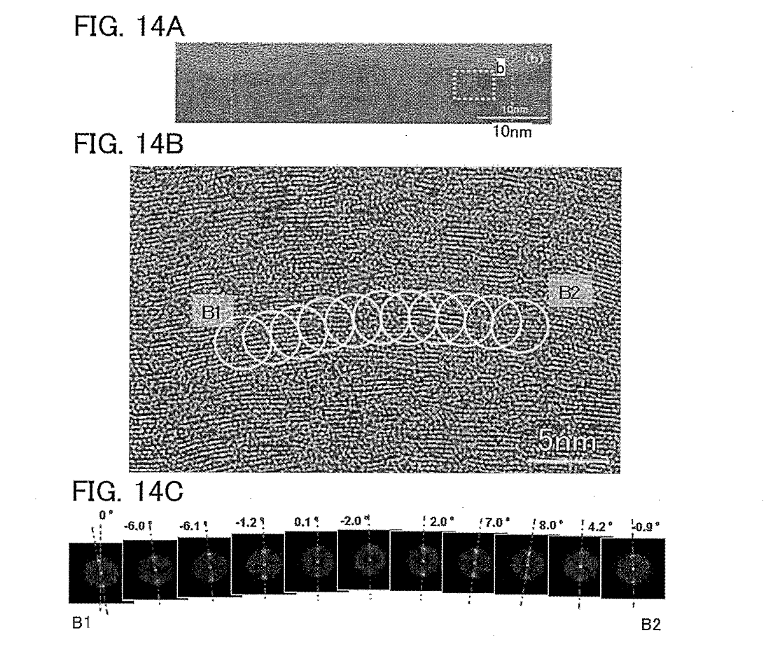

FIG. 14A shows a region b which is shown by a dotted line and whose position is slightly different from that of the region a in FIG. 13A. Further, FIG. 14B is an enlarged cross-sectional TEM image of the region b.

FIG. 14C is Fourier transform images of regions each surrounded by a circle (the diameter is about 4 nm) between B1 and B2 in FIG. 14B. C-axis alignment can be observed in each region in FIG. 14C. Between B1 and B2, the angle of the c-axis continuously and gradually changes, for example −6.0°, −6.1°, and −1.2°.

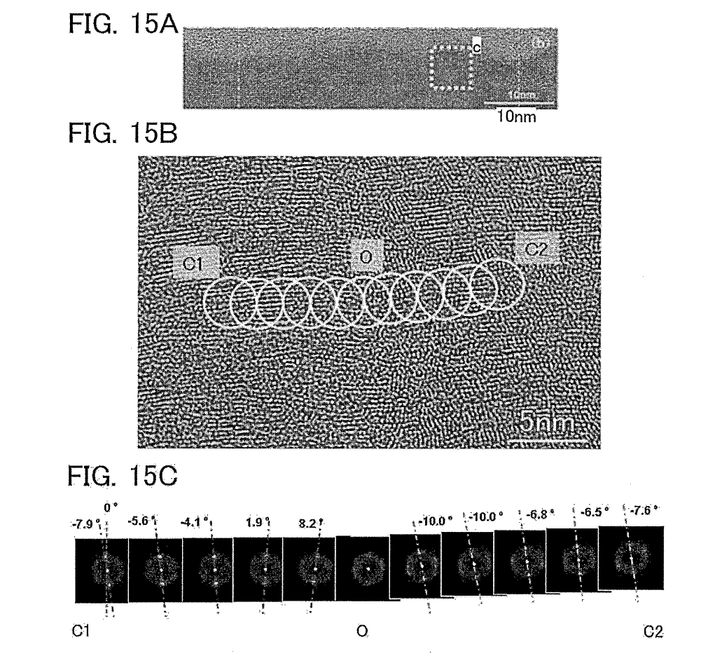

FIG. 15A shows a region c which is shown by a dotted line and whose position is slightly different from that of the region b in FIG. 14A. Further, FIG. 15B is an enlarged cross-sectional TEM image of the region c.

FIG. 15C is Fourier transform images of regions each surrounded by a circle (the diameter is about 4 nm) between C1 and O and between O and C2 in FIG. 15B. C-axis alignment can be observed in each region in FIG. 15C. Between C1 and O, the angle of the c-axis continuously and gradually changes, for example −7.9°, −5.6°, and −4.1°. Similarly, between O and C2, the angle of the c-axis continuously and gradually changes, for example −10.0°, −6.8°, and −6.5°.

Thus, it can be confirmed also by image analysis of the cross-sectional TEM image that crystal regions are connected in the CAAC-OS film.

The CAAC-OS film having such properties is an oxide semiconductor film having a low impurity concentration. The impurity is an element other than the main components of the oxide semiconductor film, such as hydrogen, carbon, silicon, or a transition metal element. In particular, an element (e.g., silicon) which has higher bonding strength with oxygen than a metal element included in the oxide semiconductor film causes disorder of atomic arrangement in the oxide semiconductor film because the element deprives the oxide semiconductor film of oxygen, thereby reducing crystallinity. Further, a heavy metal such as iron or nickel, argon, carbon dioxide, and the like have a large atomic radius (or molecular radius); therefore, when any of such elements is contained in the oxide semiconductor film, the element causes disorder of the atomic arrangement of the oxide semiconductor film, thereby reducing crystallinity. Note that the impurity contained in the oxide semiconductor film might become a carrier trap or a source of carriers.

The CAAC-OS film is an oxide semiconductor film having a low density of defect states. For example, oxygen vacancies in the oxide semiconductor film serve as carrier traps or serve as carrier generation sources when hydrogen is captured therein.

The state in which impurity concentration is low and density of defect states is low (the number of oxygen vacancies is small) is referred to as “highly purified intrinsic” or “substantially highly purified intrinsic”. A highly purified intrinsic or substantially highly purified intrinsic oxide semiconductor film has few carrier generation sources, and thus has a low carrier density. Thus, a transistor including the oxide semiconductor film rarely has a negative threshold voltage (rarely has normally-on characteristics). A highly purified intrinsic or substantially highly purified intrinsic oxide semiconductor film has few carrier traps. Accordingly, the transistor using the oxide semiconductor film has little variation in electrical characteristics and high reliability. Note that charges trapped by the carrier traps in the oxide semiconductor film take a long time to be released and may behave like fixed charges. Thus, the transistor using the oxide semiconductor film with a high impurity concentration and a high density of defect states has unstable electrical characteristics in some cases.

Note that the CAAC-OS film may include a region having an amorphous structure, a region having a microcrystalline structure, or the like.

In the case where the CAAC-OS film has a plurality of structures, the structures can be analyzed using nanobeam electron diffraction in some cases.

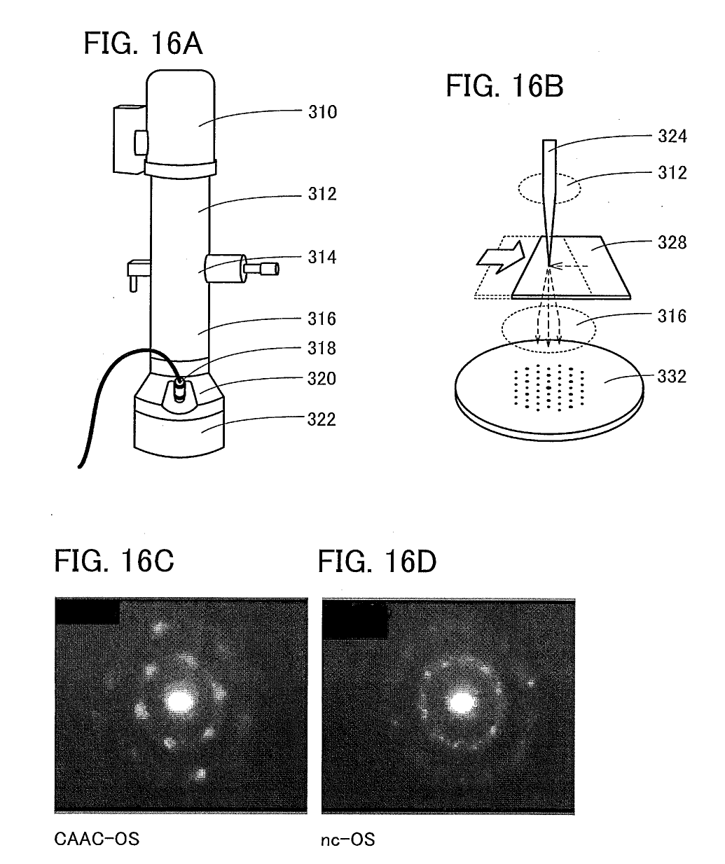

FIG. 16A illustrates a transmission electron diffraction measurement apparatus which includes an electron gun chamber 310, an optical system 312 below the electron gun chamber 310, a sample chamber 314 below the optical system 312, an optical system 316 below the sample chamber 314, an observation chamber 320 below the optical system 316, a camera 318 installed in the observation chamber 320, and a film chamber 322 below the observation chamber 320. The camera 318 is provided to face toward the inside of the observation chamber 320. Note that the film chamber 322 is not necessarily provided.

FIG. 16B illustrates an internal structure of the transmission electron diffraction measurement apparatus illustrated in FIG. 16A. In the transmission electron diffraction measurement apparatus, a substance 328 which is positioned in the sample chamber 314 is irradiated with electrons emitted from an electron gun installed in the electron gun chamber 310 through the optical system 312. Electrons passing through the substance 328 enter a fluorescent screen 332 provided in the observation chamber 320 through the optical system 316. On the fluorescent screen 332, a pattern corresponding to the intensity of the incident electron appears, which allows measurement of a transmission electron diffraction pattern.

The camera 318 is installed so as to face the fluorescent screen 332 and can take a picture of a pattern appearing in the fluorescent screen 332. An angle formed by a straight line which passes through the center of a lens of the camera 318 and the center of the fluorescent screen 332 and a straight line which passes through the center of the lens of the camera 318 and is perpendicular to a floor is, for example, 15° or more and 80° or less, 30° or more and 75° or less, or 45° or more and 70° or less. As the angle is reduced, distortion of the transmission electron diffraction pattern taken by the camera 318 becomes larger. Note that if the angle is obtained in advance, the distortion of an obtained transmission electron diffraction pattern can be corrected. Note that the film chamber 322 may be provided with the camera 318. For example, the camera 318 may be set in the film chamber 322 so as to be opposite to the incident direction of electrons 324. In this case, a transmission electron diffraction pattern with less distortion can be taken from the rear surface of the fluorescent screen 332.

A holder for fixing the substance 328 that is a sample is provided in the sample chamber 314. The holder transmits electrons passing through the substance 328. The holder may have, for example, a function of moving the substance 328 in the direction of the X, Y, and Z axes. The movement function of the holder may have an accuracy of moving the substance in the range of, for example, 1 nm to 10 nm, 5 nm to 50 nm, 10 nm to 100 nm, 50 nm to 500 nm, and 100 nm to 1 μm. The range is preferably determined to be an optimal range for the structure of the substance 328.

Then, a method for measuring a transmission electron diffraction pattern of a substance by the transmission electron diffraction measurement apparatus described above is described.

For example, changes in the structure of a substance can be observed by changing (scanning) the irradiation position of the electrons 324 that are a nanobeam in the substance, as illustrated in FIG. 16B. At this time, when the substance 328 is a CAAC-OS film, a diffraction pattern shown in FIG. 16C is observed. When the substance 328 is an nc-OS film, a diffraction pattern shown in FIG. 16D is observed.

Even when the substance 328 is a CAAC-OS film, a diffraction pattern similar to that of an nc-OS film or the like is partly observed in some cases. Therefore, whether or not a CAAC-OS film is favorable can be determined by the proportion of a region where a diffraction pattern of a CAAC-OS film is observed in a predetermined area (also referred to as proportion of CAAC). In the case of a high quality CAAC-OS film, for example, the proportion of CAAC is higher than or equal to 50%, preferably higher than or equal to 80%, further preferably higher than or equal to 90%, still further preferably higher than or equal to 95%. Note that the proportion of a region where a diffraction pattern different from that of a CAAC-OS film is observed is referred to as the proportion of not-CAAC.

For example, transmission electron diffraction patterns were obtained by scanning a top surface of a sample including a CAAC-OS film obtained just after deposition (represented as “as-sputtered”) and a top surface of a sample including a CAAC-OS film subjected to heat treatment at 450° C. in an atmosphere containing oxygen. Here, the proportion of CAAC was obtained in such a manner that diffraction patterns were observed by scanning for 60 seconds at a rate of 5 nm/second and the obtained diffraction patterns were converted into still images every 0.5 seconds. Note that as an electron beam, a nanobeam with a probe diameter of 1 nm was used. The above measurement was performed on six samples. The proportion of CAAC was calculated using the average value of the six samples.

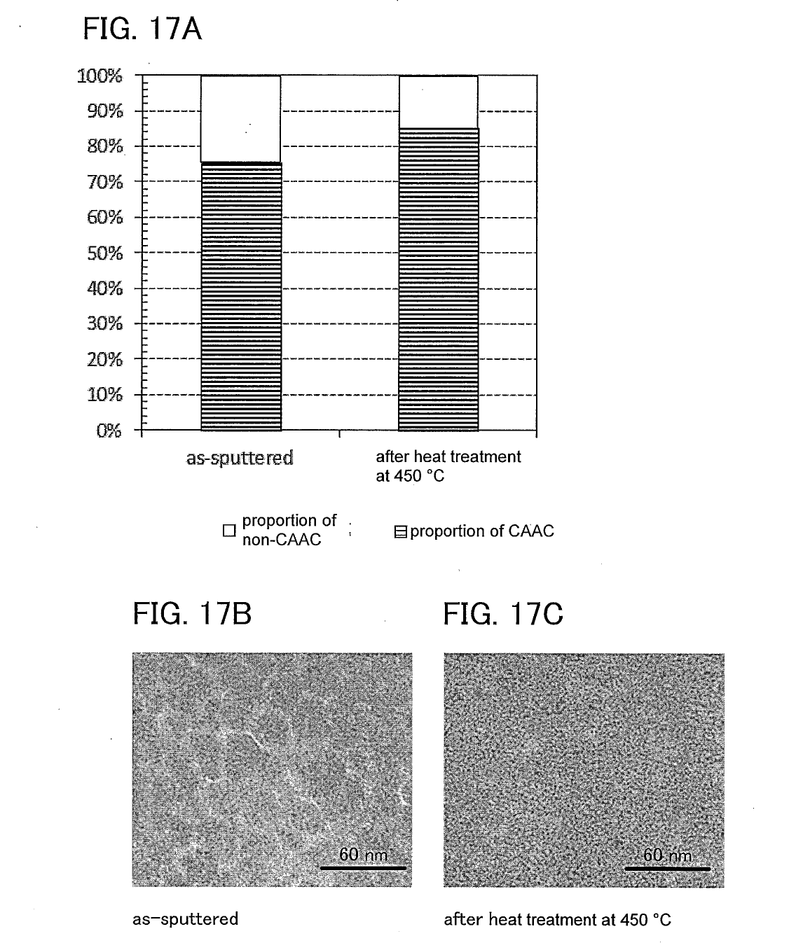

FIG. 17A shows the proportion of CAAC in each sample. The proportion of CAAC of the CAAC-OS film obtained just after the deposition was 75.7% (the proportion of non-CAAC was 24.3%). The proportion of CAAC of the CAAC-OS film subjected to the heat treatment at 450° C. was 85.3% (the proportion of non-CAAC was 14.7%). These results show that the proportion of CAAC obtained after the heat treatment at 450° C. is higher than that obtained just after the deposition. That is, heat treatment at a high temperature (e.g., higher than or equal to 400° C.) reduces the proportion of non-CAAC (increases the proportion of CAAC). Further, the above results also indicate that even when the temperature of the heat treatment is lower than 500° C., the CAAC-OS film can have a high proportion of CAAC.

Here, most of diffraction patterns different from that of a CAAC-OS film are diffraction patterns similar to that of an nc-OS film. Further, an amorphous oxide semiconductor film was not able to be observed in the measurement region. Therefore, the above results suggest that the region having a structure similar to that of an nc-OS film is rearranged by the heat treatment owing to the influence of the structure of the adjacent region, whereby the region becomes CAAC.

FIGS. 17B and 17C are planar TEM images of the CAAC-OS film obtained just after the deposition and the CAAC-OS film subjected to the heat treatment at 450° C., respectively. Comparison between FIGS. 17B and 17C shows that the CAAC-OS film subjected to the heat treatment at 450° C. has more uniform film quality. That is, the heat treatment at a high temperature improves the film quality of the CAAC-OS film.

With such a measurement method, the structure of an oxide semiconductor film having a plurality of structures can be analyzed in some cases.

### <Method for Forming CAAC-OS Film>

A method for forming a CAAC-OS film will be described below.

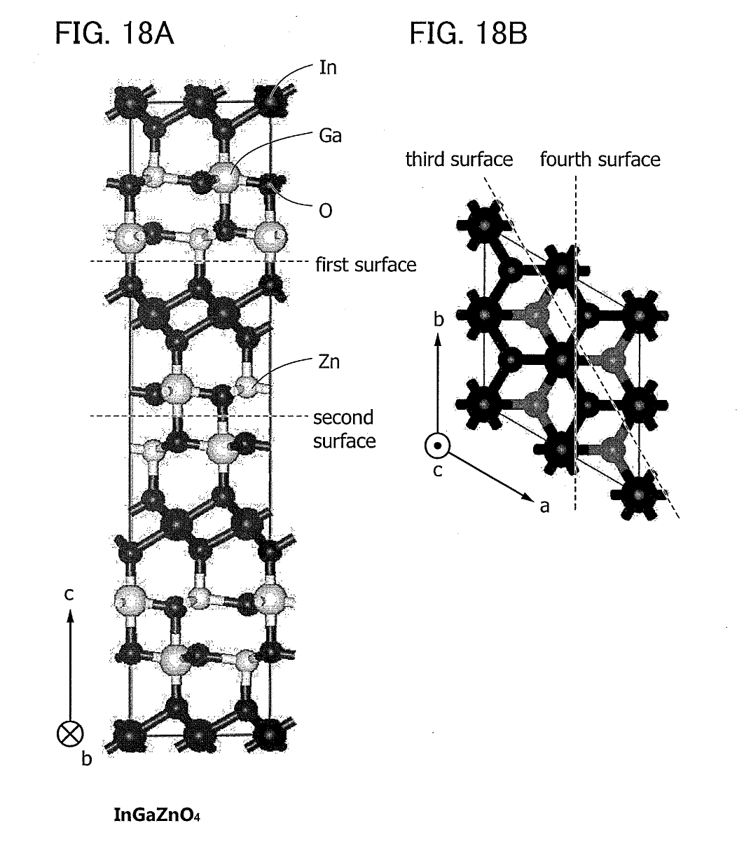

First, a cleavage plane of a target is described with reference to FIGS. 18A and 18B. FIGS. 18A and 18B show a structure of an InGaZnO₄ crystal. Note that FIG. 18A shows a structure in the case where the InGaZnO₄ crystal is observed from a direction parallel to the b-axis when the c-axis is in an upward direction. Further, FIG. 18B shows a structure in the case where the InGaZnO₄ crystal is observed from a direction parallel to the c-axis.

Energy needed for cleavage at each of crystal planes of the InGaZnO₄ crystal was calculated by the first principles calculation. Note that a pseudopotential and density functional theory program (CASTEP) using the plane wave basis were used for the calculation. Note that an ultrasoft type pseudopotential was used as the pseudopotential. GGA/PBE was used as the functional. Cut-off energy was 400 eV.

Energy of a structure in an initial state was obtained after structural optimization including a cell size was performed. Further, energy of a structure after the cleavage at each plane was obtained after structural optimization of atomic arrangement was performed in a state where the cell size was fixed.

On the basis of the structure of the InGaZnO₄ crystal shown in FIGS. 18A and 18B, a structure cleaved at any one of the first plane, the second plane, the third plane, and the fourth plane was formed and subjected to structural optimization calculation in which the cell size was fixed. Here, the first plane is a crystal plane between a Ga—Zn—O layer and an In—O layer and is parallel to the (001) plane (or the a-b plane) (see FIG. 18A). The second plane is a crystal plane between a Ga—Zn—O layer and a Ga—Zn—O layer and is parallel to the (001) plane (or the a-b plane) (see FIG. 18A). The third plane is a crystal plane parallel to the (110) plane (see FIG. 18B). The fourth plane is a crystal plane parallel to the (100) plane (or the b-c plane) (see FIG. 18B).

Under the above conditions, the energy of the structure after the cleavage at each plane was calculated. Next, a difference between the energy of the structure after the cleavage and the energy of the structure in the initial state was divided by the area of the cleavage plane; thus, cleavage energy which served as a measure of easiness of cleavage at each plane was calculated. Note that the energy of a structure is calculated based on atoms and electrons included in the structure. That is, kinetic energy of the electrons and interactions between the atoms, between the atom and the electron, and between the electrons are considered in the calculation.

As calculation results, the cleavage energy of the first plane was 2.60 J/m², that of the second plane was 0.68 J/m², that of the third plane was 2.18 J/m², and that of the fourth plane was 2.12 J/m² (see Table 1).

TABLE 1

| | Cleavage Energy [J/m²] |
|---|---|
| First Plane | 2.60 |
| Second Plane | 0.68 |
| Third Plane | 2.18 |
| Fourth Plane | 2.12 |

From the calculations, in the structure of the InGaZnO₄ crystal shown in FIGS. 18A and 18B, the cleavage energy at the second plane is the lowest. In other words, a plane between a Ga—Zn—O layer and a Ga—Zn—O layer is cleaved most easily (cleavage plane). Therefore, in this specification, the cleavage plane indicates the second plane, which is a plane where cleavage is performed most easily.

Since the second plane between a Ga—Zn—O layer and a Ga—Zn—O layer is the cleavage plane, the InGaZnO₄ crystals shown in FIG. 18A can be separated at two planes equivalent to the second plane. Therefore, in the case where an ion or the like is made to collide with a target, a wafer-like unit (we call this a pellet) which is cleaved at a plane with the lowest cleavage energy is thought to be blasted off as the minimum unit. In that case, a pellet of InGaZnO₄ includes three layers: a Ga—Zn—O layer, an In—O layer, and a Ga—Zn—O layer.

Further, the third plane (a crystal plane parallel to the (110) plane) and the fourth plane (a crystal plane parallel to the (100) plane (or the b-c plane)) have lower cleavage energy than the first plane (a crystal plane which is between a Ga—Zn—O layer and an In—O layer and is parallel to the (001) plane (or the a-b plane)); thus, the flat-plane shape of the pellet is thought to be likely a triangle or a hexagon.

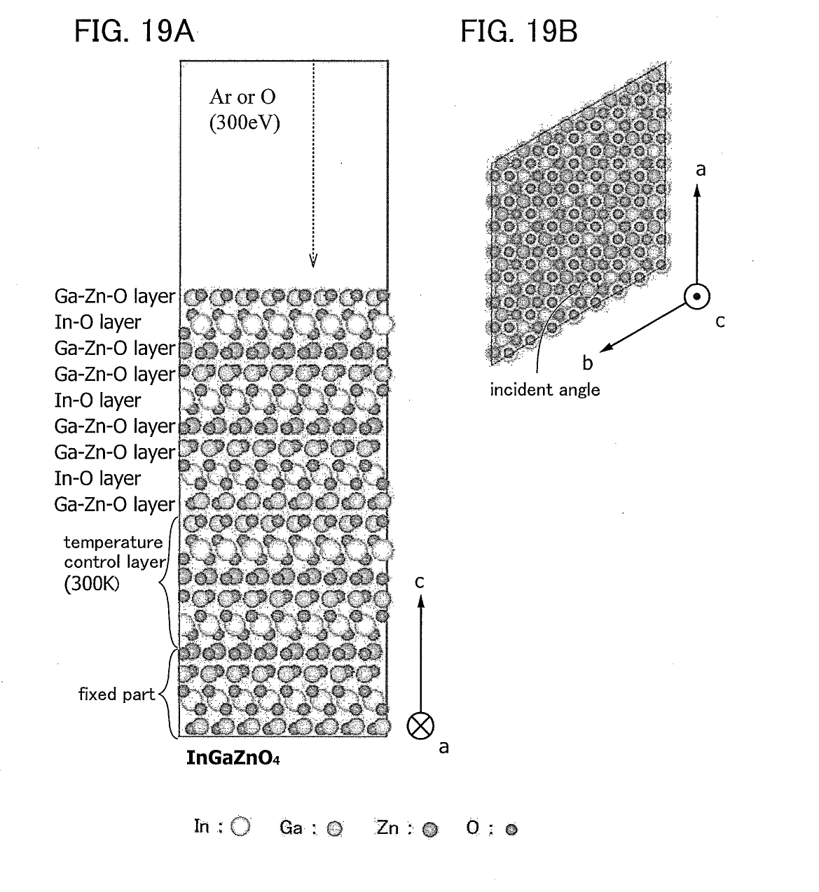

Next, through classical molecular dynamics calculation, on the assumption of an InGaZnO₄ crystal having a homologous structure as a target, a cleavage plane in the case where sputtering is performed on the target by using argon (Ar) or oxygen (O) was evaluated. FIG. 19A shows a cross-sectional structure of an InGaZnO₄ crystal (2688 atoms) used for the calculation, and FIG. 19B shows a top structure thereof. Note that a fixed layer in FIG. 19A is a layer which prevents the positions of the atoms from moving. A temperature control layer in FIG. 19A is a layer whose temperature is constantly set to a fixed temperature (300 K).

For the classical molecular dynamics calculation, Materials Explorer 5.0 manufactured by Fujitsu Limited. was used. Note that the initial temperature, the cell size, the time step size, and the number of steps were set to be 300 K, a certain size, 0.01 fs, and ten million, respectively. In calculation, an atom to which an energy of 300 eV was applied was made to enter a cell from a direction perpendicular to the a-b plane of the InGaZnO₄ crystal under the conditions.

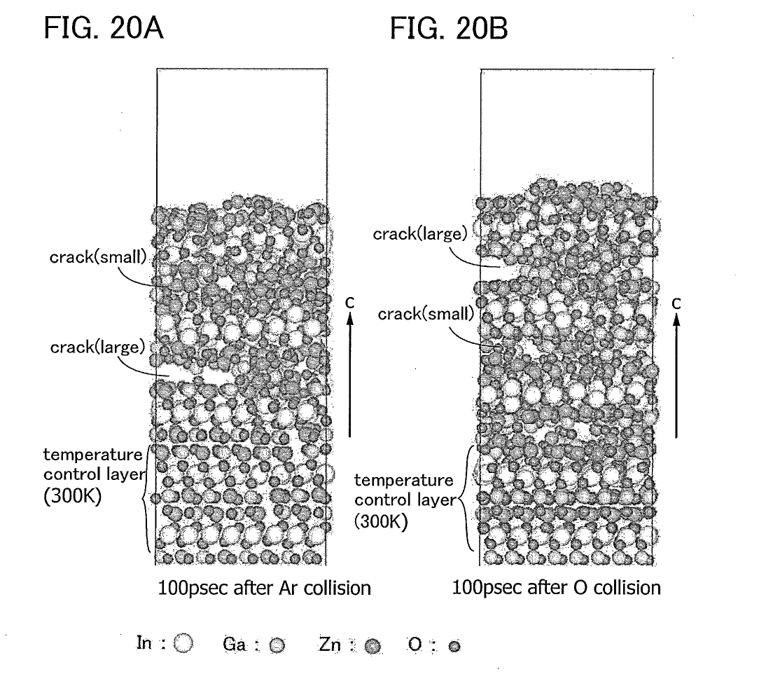

FIG. 20A shows an atomic arrangement when 99.9 picoseconds have passed after argon enters the cell including the InGaZnO₄ crystal shown in FIGS. 19A and 19B. FIG. 20B shows an atomic arrangement when 99.9 picoseconds have passed after oxygen enters the cell. Note that in FIGS. 20A and 20B, part of the fixed layer in FIG. 19A is omitted.

According to FIG. 20A, in a period from entry of argon into the cell to when 99.9 picoseconds have passed, a crack was formed from the cleavage plane corresponding to the second plane shown in FIG. 18A. Thus, in the case where argon collides with the InGaZnO₄ crystal and the uppermost surface is the second plane (the zero-th), a large crack was found to be formed in the second plane (the second).

On the other hand, according to FIG. 20B, in a period from entry of oxygen into the cell to when 99.9 picoseconds have passed, a crack was found to be formed from the cleavage plane corresponding to the second plane shown in FIG. 18A. Note that in the case where oxygen collides with the cell, a large crack was found to be formed in the second plane (the first) of the InGaZnO₄ crystal.

Accordingly, it is found that an atom (ion) collides with a target including an InGaZnO₄ crystal having a homologous structure from the upper surface of the target, the InGaZnO₄ crystal is cleaved along the second plane, and a flat-plate-like particle (hereinafter referred to as a pellet) is separated. It is also found that the pellet formed in the case where oxygen collides with the cell is smaller than that formed in the case where argon collides with the cell.

The above calculation suggests that the separated pellet includes a damaged region. In some cases, the damaged region included in the pellet can be repaired in such a manner that a defect caused by the damage reacts with oxygen. Repairing the damaged portion included in the pellet is described later.

Here, difference in size of the pellet depending on atoms which are made to collide was studied.

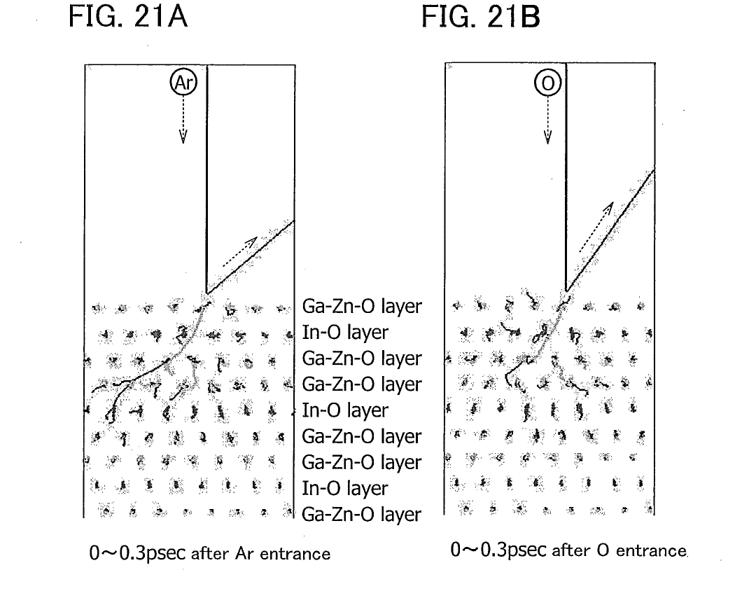

FIG. 21A shows trajectories of the atoms from 0 picosecond to 0.3 picoseconds after argon enters the cell including the InGaZnO₄ crystal shown in FIGS. 19A and 19B. Accordingly, FIG. 21A corresponds to a period from FIGS. 19A and 19B to FIG. 20A.

From FIG. 21A, when argon collides with gallium (Ga) of the first layer (Ga—Zn—O layer) counted from the top, the gallium collides with zinc (Zn) of the third layer (Ga—Zn—O layer) counted from the top and then, the zinc reaches the vicinity of the sixth layer (Ga—Zn—O layer) counted from the top. Note that the argon which collides with the gallium is sputtered to the outside. Accordingly, in the case where argon collides with the target including the InGaZnO₄ crystal, a crack is thought to be formed in the second plane (the second) in FIG. 19A.

FIG. 21B shows trajectories of the atoms from 0 picosecond to 0.3 picoseconds after oxygen enters the cell including the InGaZnO₄ crystal shown in FIGS. 19A and 19B. Accordingly, FIG. 21B corresponds to a period from FIGS. 19A and 19B to FIG. 20A.

On the other hand, from FIG. 21B, when oxygen collides with gallium (Ga) of the first layer (Ga—Zn—O layer), the gallium collides with zinc (Zn) of the third layer (Ga—Zn—O layer) counted from the top and then, the zinc does not reach the fifth layer (In—O layer) counted from the top. Note that the oxygen which collides with the gallium is sputtered to the outside. Accordingly, in the case where oxygen collides with the target including the InGaZnO₄ crystal, a crack is thought to be formed in the second plane (the first) in FIG. 19A.

This calculation also shows that the InGaZnO₄ crystal with which an atom (ion) collides is separated from the cleavage plane.

In addition, difference in depth of a crack is examined in view of conservation laws. The energy conservation law and the law of conservation of momentum can be represented by the following formula (1) and the following formula (2). Here, E represents energy of argon or oxygen before collision (300 eV), m_{A} represents mass of argon or oxygen, v_{A} represents the speed of argon or oxygen before collision, v′_{A} represents the speed of argon or oxygen after collision, m_{Ga} represents mass of gallium, v_{Ga} represents the speed of gallium before collision, and v′_{Ga} represents the speed of gallium after collision.

$$\begin{matrix}[ Formula 1 ] & \\ E = \frac{1}{2} {m}_{A} {v}_{A}^{2} + \frac{1}{2} {m}_{Ga} {v}_{Ga}^{2} & ( 1 ) \\ [ Formula 2 ] & \\ {m}_{A} {v}_{A} + {m}_{Ga} {v}_{Ga} = {m}_{A} {v}_{A}^{′} + {m}_{Ga} {v}_{Ga}^{′} & ( 2 )\end{matrix}$$

On the assumption that collision of argon or oxygen is elastic collision, the relationship among v_{A}, v′_{A}, v_{Ga}, and v′_{Ga} can be represented by the following formula (3).

[Formula 3]

v′_{A}−v′_{Ga}=−(v_{A}−v_{Ga}) (3)

From the formulae (1), (2), and (3), the speed of gallium v′_{Ga} after collision of argon or oxygen can be represented by the following formula (4).

$$\begin{matrix}[ Formula 4 ] & \\ {v}_{Ga}^{′} = \frac{\sqrt{{m}_{A}}}{{m}_{A} + {m}_{Ga}} \cdot 2 \sqrt{2 E} & ( 4 )\end{matrix}$$

In the formula (4), mass of argon or oxygen is substituted into m_{A}, whereby the speeds after collision of the atoms are compared. In the case where the argon and the oxygen have the same energy before collision, the speed of gallium in the case where argon collides with the gallium was found to be 1.24 times as high as that in the case where oxygen collides with the gallium. Thus, the energy of the gallium in the case where argon collides with the gallium is higher than that in the case where oxygen collides with the gallium by the square of the speed.

The speed (energy) of gallium after collision in the case where argon collides with the gallium was found to be higher than that in the case where oxygen collides with the gallium. Accordingly, a crack is thought to be formed at a deeper position in the case where argon collides with the gallium than in the case where oxygen collides with the gallium.

The above calculation shows that when sputtering is performed using a target including the InGaZnO₄ crystal having a homologous structure, separation occurs from the cleavage plane to form a pellet. On the other hand, even when sputtering is performed on a region having another structure of a target without the cleavage plane, a pellet is not formed, and a sputtered particle with an atomic-level size which is minuter than a pellet is formed. Because the sputtered particle is smaller than the pellet, the sputtered particle is thought to be removed through a vacuum pump connected to a sputtering apparatus. Therefore, a model in which particles with a variety of sizes and shapes fly to a substrate and are deposited hardly applies to the case where sputtering is performed using a target including the InGaZnO₄ crystal having a homologous structure. A model in FIG. 1 in which sputtered pellets are deposited to form a CAAC-OS film makes sense.

The CAAC-OS film formed in this manner has substantially the same density as a single crystal OS film. For example, the density of the single crystal OS film of InGaZnO₄ having a homologous structure is 6.36 g/cm³, and the density of the CAAC-OS film having substantially the same atomic ratio is approximately 6.3 g/cm³.

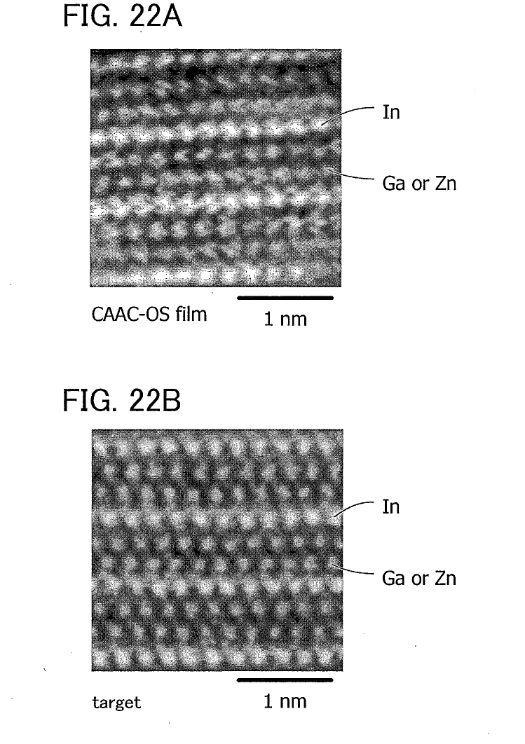

FIGS. 22A and 22B show atomic arrangements of cross sections of an In—Ga—Zn oxide film (see FIG. 22A) that is a CAAC-OS film deposited by a sputtering method and a target thereof (see FIG. 22B). For observation of atomic arrangement, a high-angle annular dark field scanning transmission electron microscopy (HAADF-STEM) was used. The contrast of the image of each of the atoms in the HAADF-STEM is proportional to the square of its atomic number. Therefore, Zn (atomic number: 30) and Ga (atomic number: 31), which have close atomic numbers, are difficult to distinguish. A Hitachi scanning transmission electron microscope HD-2700 was used for the HAADF-STEM.

When FIG. 22A and FIG. 22B are compared, it is found that the CAAC-OS film and the target each have a homologous structure and arrangements of atoms in the CAAC-OS film correspond to those in the target.

### <Deposition Apparatus>

A deposition apparatus with which the above-described CAAC-OS film can be deposited is described below.

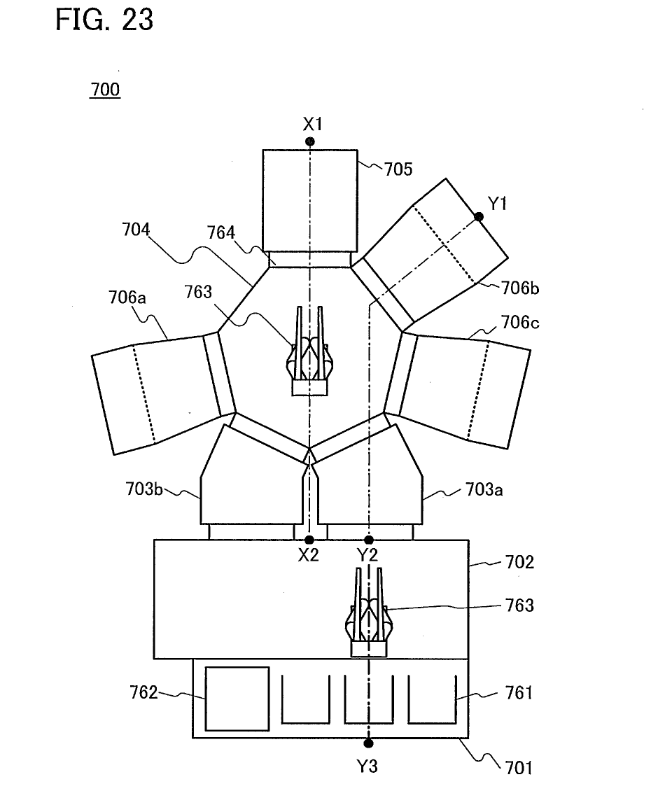

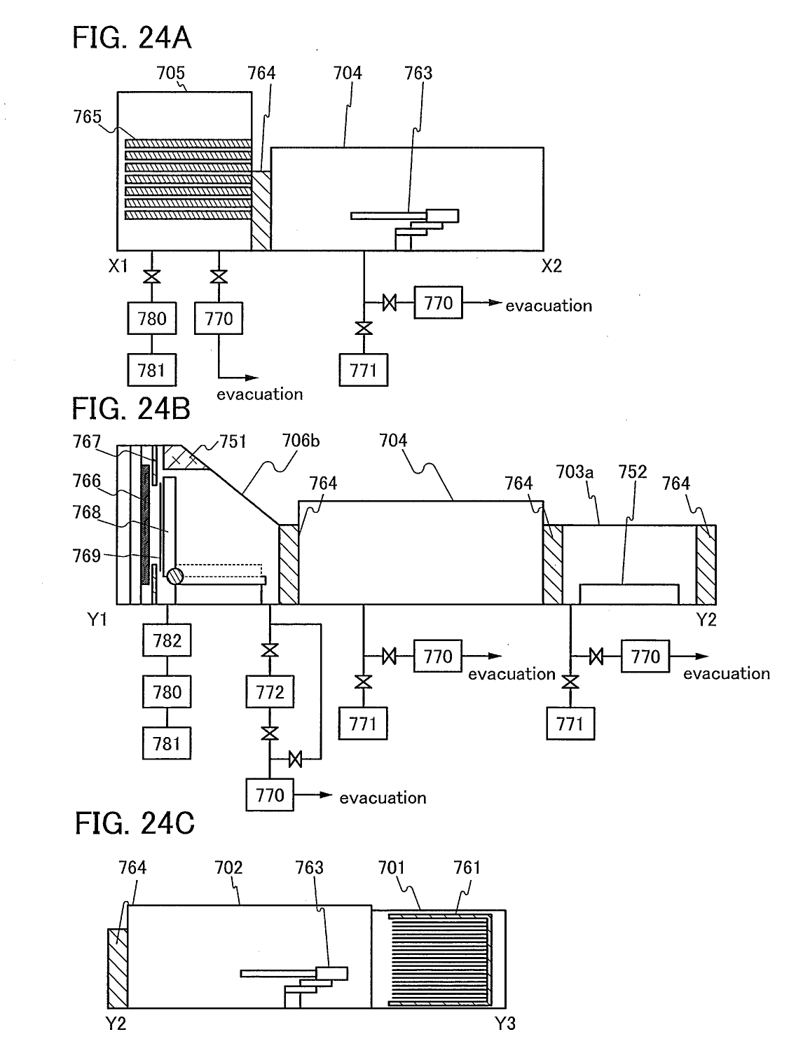

First, a structure of a deposition apparatus which allows the entry of few impurities into a film at the time of the deposition is described with reference to FIG. 23 and FIGS. 24A to 24C.

FIG. 23 is a top view schematically illustrating a single wafer multi-chamber deposition apparatus 700. The deposition apparatus 700 includes an atmosphere-side substrate supply chamber 701 including a cassette port 761 for holding a substrate and an alignment port 762 for performing alignment of a substrate, an atmosphere-side substrate transfer chamber 702 through which a substrate is transferred from the atmosphere-side substrate supply chamber 701, a load lock chamber 703a where a substrate is carried and the pressure inside the chamber is switched from atmospheric pressure to reduced pressure or from reduced pressure to atmospheric pressure, an unload lock chamber 703b where a substrate is carried out and the pressure inside the chamber is switched from reduced pressure to atmospheric pressure or from atmospheric pressure to reduced pressure, a transfer chamber 704 through which a substrate is transferred in a vacuum, a substrate heating chamber 705 where a substrate is heated, and deposition chambers 706a, 706b, and 706c in each of which a target is placed for deposition.

Note that a plurality of cassette ports 761 may be provided as illustrated in FIG. 23 (in FIG. 23, three cassette ports 761 are provided).

The atmosphere-side substrate transfer chamber 702 is connected to the load lock chamber 703a and the unload lock chamber 703b, the load lock chamber 703a and the unload lock chamber 703b are connected to the transfer chamber 704, and the transfer chamber 704 is connected to the substrate heating chamber 705 and the deposition chambers 706a, 706b, and 706c.

Gate valves 764 are provided for connecting portions between chambers so that each chamber except the atmosphere-side substrate supply chamber 701 and the atmosphere-side substrate transfer chamber 702 can be independently kept under vacuum. Moreover, the atmosphere-side substrate transfer chamber 702 and the transfer chamber 704 each include a transfer robot 763, with which a glass substrate can be transferred.

Further, it is preferable that the substrate heating chamber 705 also serve as a plasma treatment chamber. In the deposition apparatus 700, it is possible to transfer a substrate without exposure to the air between treatment and treatment; therefore, adsorption of impurities on a substrate can be suppressed. In addition, the order of deposition, heat treatment, or the like can be freely determined. Note that the number of the transfer chambers, the number of the deposition chambers, the number of the load lock chambers, the number of the unload lock chambers, and the number of the substrate heating chambers are not limited to the above, and the numbers thereof can be set as appropriate depending on the space for placement or the process conditions.

Next, FIG. 24A, FIG. 24B, and FIG. 24C are a cross-sectional view taken along dashed-dotted line X1-X2, a cross-sectional view taken along dashed-dotted line Y1-Y2, and a cross-sectional view taken along dashed-dotted line Y2-Y3, respectively, in the deposition apparatus 700 illustrated in FIG. 23.

FIG. 24A is a cross section of the substrate heating chamber 705 and the transfer chamber 704, and the substrate heating chamber 705 includes a plurality of heating stages 765 which can hold a substrate. Note that although the number of heating stages 765 illustrated in FIG. 24A is seven, it is not limited thereto and may be greater than or equal to one and less than seven, or greater than or equal to eight. It is preferable to increase the number of the heating stages 765 because a plurality of substrates can be subjected to heat treatment at the same time, which leads to an increase in productivity. Further, the substrate heating chamber 705 is connected to a vacuum pump 770 through a valve. As the vacuum pump 770, a dry pump and a mechanical booster pump can be used, for example.

As heating mechanism which can be used for the substrate heating chamber 705, a resistance heater may be used for heating, for example. Alternatively, heat conduction or heat radiation from a medium such as a heated gas may be used as the heating mechanism. For example, rapid thermal annealing (RTA) such as gas rapid thermal annealing (GRTA) or lamp rapid thermal annealing (LRTA) can be used. The LRTA is a method for heating an object by radiation of light (an electromagnetic wave) emitted from a lamp such as a halogen lamp, a metal halide lamp, a xenon arc lamp, a carbon arc lamp, a high-pressure sodium lamp, or a high-pressure mercury lamp. In the GRTA, heat treatment is performed using a high-temperature gas. An inert gas is used as the gas.

Moreover, the substrate heating chamber 705 is connected to a refiner 781 through a mass flow controller 780. Note that although the mass flow controller 780 and the refiner 781 can be provided for each of a plurality of kinds of gases, only one mass flow controller 780 and one refiner 781 are provided for easy understanding. As the gas introduced to the substrate heating chamber 705, a gas whose dew point is −80° C. or lower, preferably −100° C. or lower can be used; for example, an oxygen gas, a nitrogen gas, and a rare gas (e.g., an argon gas) are used.

The transfer chamber 704 includes the transfer robot 763. The transfer robot 763 includes a plurality of movable portions and an arm for holding a substrate and can transfer a substrate to each chamber. Further, the transfer chamber 704 is connected to the vacuum pump 770 and a cryopump 771 through valves. With such a structure, evacuation can be performed using the vacuum pump 770 when the pressure inside the transfer chamber 704 is in the range of atmospheric pressure to low or medium vacuum (about 0.1 Pa to several hundred Pa) and then, by switching the valves, evacuation can be performed using the cryopump 771 when the pressure inside the transfer chamber 704 is in the range of middle vacuum to high or ultra-high vacuum (0.1 Pa to 1×10⁻⁷ Pa).

Alternatively, two or more cryopumps 771 may be connected in parallel to the transfer chamber 704. With such a structure, even when one of the cryopumps is in regeneration, evacuation can be performed using any of the other cryopumps. Note that the above regeneration refers to treatment for discharging molecules (or atoms) entrapped in the cryopump. When molecules (or atoms) are entrapped too much in a cryopump, the evacuation capability of the cryopump is lowered; therefore, regeneration is performed regularly.

FIG. 24B is a cross section of the deposition chamber 706b, the transfer chamber 704, and the load lock chamber 703a.

Here, the details of the deposition chamber (sputtering chamber) are described with reference to FIG. 24B. The deposition chamber 706b illustrated in FIG. 24B includes a target 766, an attachment protection plate 767, and a substrate stage 768. Note that here, a substrate 769 is provided on the substrate stage 768. Although not illustrated, the substrate stage 768 may include a substrate holding mechanism which holds the substrate 769, a rear heater which heats the substrate 769 from the back surface, or the like.

Note that the substrate stage 768 is held substantially vertically to a floor during deposition and is held substantially parallel to the floor when the substrate is delivered. In FIG. 24B, the position where the substrate stage 768 is held when the substrate is delivered is denoted by a dashed line. With such a structure, the probability that dust or a particle which might be mixed into a film during the deposition is attached to the substrate 769 can be suppressed as compared with the case where the substrate stage 768 is held parallel to the floor. However, there is a possibility that the substrate 769 falls when the substrate stage 768 is held vertically) (90° to the floor; therefore, the angle of the substrate stage 768 to the floor is preferably wider than or equal to 80° and narrower than 90°.

The attachment protection plate 767 can suppress deposition of a particle which is sputtered from the target 766 on a region where deposition is not needed. Moreover, the attachment protection plate 767 is preferably processed to prevent accumulated sputtered particles from being separated. For example, blasting treatment which increases surface roughness may be performed, or roughness may be formed on the surface of the attachment protection plate 767.

The deposition chamber 706b is connected to the mass flow controller 780 through a gas heating system 782, and the gas heating system 782 is connected to the refiner 781 through the mass flow controller 780. With the gas heating system 782, a gas which is introduced to the deposition chamber 706b can be heated to a temperature higher than or equal to 40° C. and lower than or equal to 400° C., preferably higher than or equal to 50° C. and lower than or equal to 200° C. Note that although the gas heating system 782, the mass flow controller 780, and the refiner 781 can be provided for each of a plurality of kinds of gases, only one gas heating system 782, one mass flow controller 780, and one refiner 781 are provided for easy understanding. As the gas introduced to the deposition chamber 706b, a gas whose dew point is −80° C. or lower, preferably −100° C. or lower can be used; for example, an oxygen gas, a nitrogen gas, and a rare gas (e.g., an argon gas) are used.

A facing-target-type sputtering apparatus may be provided in the deposition chamber 706b. In a facing-target-type sputtering apparatus, plasma is confined between targets; therefore, plasma damage to a substrate can be reduced. Further, step coverage can be improved because an incident angle of a sputtered particle to the substrate can be made smaller depending on the inclination of the target.

Note that a parallel-plate-type sputtering apparatus or an ion beam sputtering apparatus may be provided in the deposition chamber 706b.

In the case where the refiner is provided just before the gas is introduced, the length of a pipe between the refiner and the deposition chamber 706b is less than or equal to 10 m, preferably less than or equal to 5 m, more preferably less than or equal to 1 m. When the length of the pipe is less than or equal to 10 m, less than or equal to 5 m, or less than or equal to 1 m, the effect of the release of gas from the pipe can be reduced accordingly. As the pipe for the gas, a metal pipe the inside of which is covered with iron fluoride, aluminum oxide, chromium oxide, or the like can be used. With the above pipe, the amount of released gas containing impurities is made small and the entry of impurities into the gas can be reduced as compared with a SUS316L-EP pipe, for example. Further, a high-performance ultra-compact metal gasket joint (UPG joint) may be used as a joint of the pipe. A structure where all the materials of the pipe are metals is preferable because the effect of the generated released gas or the external leakage can be reduced as compared with a structure where resin or the like is used.

The deposition chamber 706b is connected to a turbo molecular pump 772 and the vacuum pump 770 through valves.

In addition, the deposition chamber 706b is provided with a cryotrap 751.

The cryotrap 751 is a mechanism which can adsorb a molecule (or an atom) having a relatively high melting point, such as water. The turbo molecular pump 772 is capable of stably removing a large-sized molecule (or atom), needs low frequency of maintenance, and thus enables high productivity, whereas it has a low capability in removing hydrogen and water. Hence, the cryotrap 751 is connected to the deposition chamber 706b so as to have a high capability in removing water or the like. The temperature of a refrigerator of the cryotrap 751 is set to be lower than or equal to 100 K, preferably lower than or equal to 80 K. In the case where the cryotrap 751 includes a plurality of refrigerators, it is preferable to set the temperature of each refrigerator at a different temperature because efficient evacuation is possible. For example, the temperature of a first-stage refrigerator may be set to be lower than or equal to 100 K and the temperature of a second-stage refrigerator may be set to be lower than or equal to 20 K.

Note that the evacuation method of the deposition chamber 706b is not limited to the above, and a structure similar to that in the evacuation method described in the transfer chamber 704 (the evacuation method using the cryopump and the vacuum pump) may be employed. Needless to say, the evacuation method of the transfer chamber 704 may have a structure similar to that of the deposition chamber 706b (the evacuation method using the turbo molecular pump and the vacuum pump).

Note that in each of the transfer chamber 704, the substrate heating chamber 705, and the deposition chamber 706b which are described above, the back pressure (total pressure) and the partial pressure of each gas molecule (atom) are preferably set as follows. In particular, the back pressure and the partial pressure of each gas molecule (atom) in the deposition chamber 706b need to be noted because impurities might enter a film to be formed.

In each of the above chambers, the back pressure (total pressure) is less than or equal to 1×10⁻⁴ Pa, preferably less than or equal to 3×10⁻⁵ Pa, more preferably less than or equal to 1×10⁻⁵ Pa. In each of the above chambers, the partial pressure of a gas molecule (atom) having a mass-to-charge ratio (m/z) of 18 is less than or equal to 3×10⁻⁵ Pa, preferably less than or equal to 1×10⁻⁵ Pa, more preferably less than or equal to 3×10⁻⁶ Pa. Moreover, in each of the above chambers, the partial pressure of a gas molecule (atom) having a mass-to-charge ratio (m/z) of 28 is less than or equal to 3×10⁻⁵ Pa, preferably less than or equal to 1×10⁻⁵ Pa, more preferably less than or equal to 3×10⁻⁶ Pa. Further, in each of the above chambers, the partial pressure of a gas molecule (atom) having a mass-to-charge ratio (m/z) of 44 is less than or equal to 3×10⁻⁵ Pa, preferably less than or equal to 1×10⁻⁵ Pa, more preferably less than or equal to 3×10⁻⁶ Pa.

Note that a total pressure and a partial pressure in a vacuum chamber can be measured using a mass analyzer. For example, Qulee CGM-051, a quadrupole mass analyzer (also referred to as Q-mass) manufactured by ULVAC, Inc. may be used.

Moreover, the transfer chamber 704, the substrate heating chamber 705, and the deposition chamber 706b which are described above preferably have a small amount of external leakage or internal leakage.

For example, in each of the transfer chamber 704, the substrate heating chamber 705, and the deposition chamber 706b which are described above, the leakage rate is less than or equal to 3×10⁻⁶ Pa·m³/s, preferably less than or equal to 1×10⁻⁶ Pa·m³/s. The leakage rate of a gas molecule (atom) having a mass-to-charge ratio (m/z) of 18 is less than or equal to 1×10⁻⁷ Pa·m³/s, preferably less than or equal to 3×10⁻⁸ Pa·m³/s. The leakage rate of a gas molecule (atom) having a mass-to-charge ratio (m/z) of 28 is less than or equal to 1×10⁻⁵ Pa·m³/s, preferably less than or equal to 1×10⁻⁶ Pa·m³/s. The leakage rate of a gas molecule (atom) having a mass-to-charge ratio (m/z) of 44 is less than or equal to 3×10⁻⁶ Pa·m³/s, preferably less than or equal to 1×10⁻⁶ Pa·m³/S.

Note that a leakage rate can be derived from the total pressure and partial pressure measured using the mass analyzer.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or due to released gas from an internal member. Measures need to be taken from both aspects of external leakage and internal leakage in order that the leakage rate is set to be less than or equal to the above value.

For example, an open/close portion of the deposition chamber 706b can be sealed with a metal gasket. For the metal gasket, metal covered with iron fluoride, aluminum oxide, or chromium oxide is preferably used. The metal gasket realizes higher adhesion than an O-ring, and can reduce the external leakage. Further, with the use of the metal covered with iron fluoride, aluminum oxide, chromium oxide, or the like, which is in the passive state, the release of gas containing impurities released from the metal gasket is suppressed, so that the internal leakage can be reduced.

For a member of the deposition apparatus 700, aluminum, chromium, titanium, zirconium, nickel, or vanadium, which releases a smaller amount of gas containing impurities, is used. Alternatively, for the above member, an alloy containing iron, chromium, nickel, and the like covered with the above material may be used. The alloy containing iron, chromium, nickel, and the like is rigid, resistant to heat, and suitable for processing. Here, when surface unevenness of the member is decreased by polishing or the like to reduce the surface area, the release of gas can be reduced.

Alternatively, the above member of the deposition apparatus 700 may be covered with iron fluoride, aluminum oxide, chromium oxide, or the like.

The member of the deposition apparatus 700 is preferably formed with only metal as much as possible. For example, in the case where a viewing window formed with quartz or the like is provided, it is preferable that the surface of the viewing window be thinly covered with iron fluoride, aluminum oxide, chromium oxide, or the like so as to suppress release of gas.

When an adsorbed substance is present in the deposition chamber, the adsorbed substance does not affect the pressure in the deposition chamber because it is adsorbed onto an inner wall or the like; however, the adsorbed substance causes gas to be released when the inside of the deposition chamber is evacuated. Therefore, although there is no correlation between the leakage rate and the evacuation rate, it is important that the adsorbed substance present in the deposition chamber be desorbed as much as possible and evacuation be performed in advance with the use of a pump with high evacuation capability. Note that the deposition chamber may be subjected to baking to promote desorption of the adsorbed substance. By the baking, the desorption rate of the adsorbed substance can be increased about tenfold. The baking can be performed at a temperature in the range of 100° C. to 450° C. At this time, when the adsorbed substance is removed while an inert gas is introduced to the deposition chamber, the desorption rate of water or the like, which is difficult to be desorbed simply by evacuation, can be further increased. Note that when the inert gas which is introduced is heated to substantially the same temperature as the baking temperature of the deposition chamber, the desorption rate of the adsorbed substance can be further increased. Here, a rare gas is preferably used as an inert gas. Depending on the kind of a film to be deposited, oxygen or the like may be used instead of an inert gas. For example, in the case of depositing an oxide, the use of oxygen which is the main component of the oxide is preferable in some cases.

Alternatively, treatment for evacuating the inside of the deposition chamber is preferably performed a certain period of time after heated oxygen, a heated inert gas such as a heated rare gas, or the like is introduced to increase a pressure in the deposition chamber. The introduction of the heated gas can desorb the adsorbed substance in the deposition chamber, and the impurities present in the deposition chamber can be reduced. Note that an advantageous effect can be achieved when this treatment is repeated more than or equal to 2 times and less than or equal to 30 times, preferably more than or equal to 5 times and less than or equal to 15 times. Specifically, an inert gas, oxygen, or the like with a temperature higher than or equal to 40° C. and lower than or equal to 400° C., preferably higher than or equal to 50° C. and lower than or equal to 200° C. is introduced to the deposition chamber, so that the pressure therein can be kept to be greater than or equal to 0.1 Pa and less than or equal to 10 kPa, preferably greater than or equal to 1 Pa and less than or equal to 1 kPa, more preferably greater than or equal to 5 Pa and less than or equal to 100 Pa in the time range of 1 minute to 300 minutes, preferably 5 minutes to 120 minutes. After that, the inside of the deposition chamber is evacuated in the time range of 5 minutes to 300 minutes, preferably 10 minutes to 120 minutes.

The desorption rate of the adsorbed substance can be further increased also by dummy deposition. Here, the dummy deposition refers to deposition on a dummy substrate by a sputtering method or the like, in which a film is deposited on the dummy substrate and the inner wall of the deposition chamber so that impurities in the deposition chamber and an adsorbed substance on the inner wall of the deposition chamber are confined in the film. For a dummy substrate, a substrate which releases a smaller amount of gas is preferably used. By performing dummy deposition, the concentration of impurities in a film which will be deposited later can be reduced. Note that the dummy deposition may be performed at the same time as the baking of the deposition chamber.

Next, the details of the transfer chamber 704 and the load lock chamber 703a illustrated in FIG. 24B and the atmosphere-side substrate transfer chamber 702 and the atmosphere-side substrate supply chamber 701 illustrated in FIG. 24C are described. Note that FIG. 24C is a cross section of the atmosphere-side substrate transfer chamber 702 and the atmosphere-side substrate supply chamber 701.

For the transfer chamber 704 illustrated in FIG. 24B, the description of the transfer chamber 704 illustrated in FIG. 24A can be referred to.

The load lock chamber 703a includes a substrate delivery stage 752. When a pressure in the load lock chamber 703a becomes atmospheric pressure by being increased from reduced pressure, the substrate delivery stage 752 receives a substrate from the transfer robot 763 provided in the atmosphere-side substrate transfer chamber 702. After that, the load lock chamber 703a is evacuated into vacuum so that the pressure therein becomes reduced pressure and then the transfer robot 763 provided in the transfer chamber 704 receives the substrate from the substrate delivery stage 752.

Further, the load lock chamber 703a is connected to the vacuum pump 770 and the cryopump 771 through valves. For a method for connecting evacuation systems such as the vacuum pump 770 and the cryopump 771, the description of the method for connecting the transfer chamber 704 can be referred to, and the description thereof is omitted here. Note that the unload lock chamber 703b illustrated in FIG. 23 can have a structure similar to that in the load lock chamber 703a.

The atmosphere-side substrate transfer chamber 702 includes the transfer robot 763. The transfer robot 763 can deliver a substrate from the cassette port 761 to the load lock chamber 703a or deliver a substrate from the load lock chamber 703a to the cassette port 761. Further, a mechanism for suppressing entry of dust or a particle, such as high efficiency particulate air (HEPA) filter, may be provided above the atmosphere-side substrate transfer chamber 702 and the atmosphere-side substrate supply chamber 701.

The atmosphere-side substrate supply chamber 701 includes a plurality of cassette ports 761. The cassette port 761 can hold a plurality of substrates.

The surface temperature of the target is set to be lower than or equal to 100° C., preferably lower than or equal to 50° C., more preferably about room temperature (typically, 25° C.). In a sputtering apparatus for a large substrate, a large target is often used. However, it is difficult to form a target for a large substrate without a juncture. In fact, a plurality of targets are arranged so that there is as little space as possible therebetween to obtain a large shape; however, a slight space is inevitably generated. When the surface temperature of the target increases, in some cases, zinc or the like is volatilized from such a slight space and the space might be expanded gradually. When the space expands, a metal of a backing plate or a metal used for adhesion might be sputtered and might cause an increase in impurity concentration. Thus, it is preferable that the target be cooled sufficiently.

Specifically, for the backing plate, a metal having high conductivity and a high heat dissipation property (specifically copper) is used. The target can be cooled efficiently by making a sufficient amount of cooling water flow through a water channel which is formed in the backing plate.

Note that in the case where the target includes zinc, plasma damage is alleviated by the deposition in an oxygen gas atmosphere; thus, an oxide film in which zinc is unlikely to be volatilized can be obtained.

Specifically, the concentration of hydrogen in the CAAC-OS film, which is measured by secondary ion mass spectrometry (SIMS), can be set to be lower than or equal to 2×10²⁰ atoms/cm³, preferably lower than or equal to 5×10¹⁹ atoms/cm³, more preferably lower than or equal to 1×10¹⁹ atoms/cm³, still more preferably lower than or equal to 5×10¹⁸ atoms/cm³.

The concentration of nitrogen in the CAAC-OS film, which is measured by SIMS, can be set to be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The concentration of carbon in the CAAC-OS film, which is measured by SIMS, can be set to be lower than 5×10¹⁹ atoms/cm³, preferably lower than or equal to 5×10¹⁸ atoms/cm³, more preferably lower than or equal to 1×10¹⁸ atoms/cm³, still more preferably lower than or equal to 5×10¹⁷ atoms/cm³.

The amount of each of the following gas molecules (atoms) released from the CAAC-OS film can be less than or equal to 1×10¹⁹/cm³, preferably less than or equal to 1×10¹⁸/cm³, which is measured by thermal desorption spectroscopy (TDS) analysis: a gas molecule (atom) having a mass-to-charge ratio (m/z) of 2 (e.g., hydrogen molecule), a gas molecule (atom) having a mass-to-charge ratio (m/z) of 18, a gas molecule (atom) having a mass-to-charge ratio (m/z) of 28, and a gas molecule (atom) having a mass-to-charge ratio (m/z) of 44.

With the above deposition apparatus, entry of impurities into the CAAC-OS film can be suppressed. Further, when a film in contact with the CAAC-OS film is formed with the use of the above deposition apparatus, the entry of impurities into the CAAC-OS film from the film in contact therewith can be suppressed.

### <Transistor Structure>

The structures of transistors of embodiments of the present invention will be described below.

### <Transistor Structure 1>

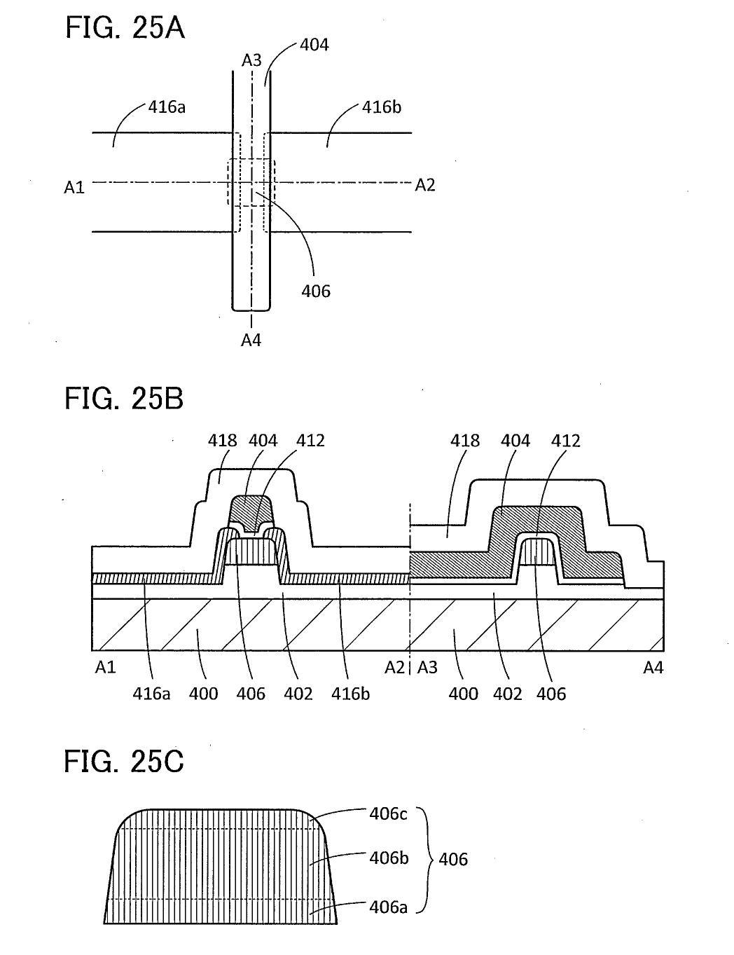

FIGS. 25A and 25B are a top view and a cross-sectional view which illustrate a transistor of one embodiment of the present invention. FIG. 25A is a top view and FIG. 25B is a cross-sectional view taken along dashed-dotted line A1-A2 and dashed-dotted line A3-A4 in FIG. 25A. Note that for simplification of the drawing, some components are not illustrated in the top view in FIG. 25A.

The transistor in FIGS. 25A and 25B includes an insulating film 402 having a projection over a substrate 400, a semiconductor film 406 over the projection of the insulating film 402, a conductive film 416a and a conductive film 416b in contact with a top surface and side surfaces of the semiconductor film 406, an insulating film 412 over the semiconductor film 406, the conductive film 416a, and the conductive film 416b, a conductive film 404 which is in contact with a top surface of the insulating film 412 and faces the top surface and the side surfaces of the semiconductor film 406, and an insulating film 418 over the conductive film 416a, the conductive film 416b, and the conductive film 404. Note that the insulating film 402 does not necessarily include a projection. The conductive film 404 serves as a gate electrode of the transistor. Further, the conductive film 416a and the conductive film 416b serve as a source electrode and a drain electrode of the transistor.

As illustrated in FIG. 25B, a side surface of the conductive film 416a and a side surface of the conductive film 416b are in contact with the side surfaces of the semiconductor film 406. The semiconductor film 406 can be electrically surrounded by an electric field of the conductive film 404 (a structure in which a semiconductor film is electrically surrounded by an electric field of a conductive film is referred to as a surrounded channel (s-channel) structure). Therefore, a channel is formed in the entire semiconductor film 406 (bulk) in some cases. In the s-channel structure, a large amount of current can flow between a source and a drain of a transistor, so that a high on-state current can be obtained.

The s-channel structure is suitable for a miniaturized transistor because a high on-state current can be obtained. A semiconductor device including the miniaturized transistor can have a high integration degree and high density. For example, the channel length of the transistor is preferably less than or equal to 40 nm, more preferably less than or equal to 30 nm, still more preferably less than or equal to 20 nm and the channel width of the transistor is preferably less than or equal to 40 nm, more preferably less than or equal to 30 nm, still more preferably less than or equal to 20 nm.

Note that the channel length refers to, for example, a distance between a source (a source region or a source electrode) and a drain (a drain region or a drain electrode) in a region where a semiconductor (or a portion where a current flows in a semiconductor when a transistor is on) and a gate electrode overlap with each other or a region where a channel is formed in a top view of the transistor. In one transistor, channel lengths in all regions are not necessarily the same. In other words, the channel length of one transistor is not limited to one value in some cases. Therefore, in this specification, the channel length is any one of values, the maximum value, the minimum value, or the average value in a region where a channel is formed.

A channel width refers to, for example, the length of a portion where a source and a drain face each other in a region where a semiconductor (or a portion where a current flows in a semiconductor when a transistor is on) and a gate electrode overlap with each other, or a region where a channel is formed. In one transistor, channel widths in all regions do not necessarily have the same value. In other words, a channel width of one transistor is not fixed to one value in some cases. Therefore, in this specification, a channel width is any one of values, the maximum value, the minimum value, or the average value in a region where a channel is formed.

Note that depending on transistor structures, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a top surface of a semiconductor is higher than the proportion of a channel region formed in a side surface of a semiconductor in some cases. In that case, an effective channel width obtained when a channel is actually formed is greater than an apparent channel width shown in the top view.

In a transistor having a three-dimensional structure, an effective channel width is difficult to measure in some cases. For example, to estimate an effective channel width from a design value, it is necessary to assume that the shape of a semiconductor is known as an assumption condition. Therefore, in the case where the shape of a semiconductor is not known accurately, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Further, in this specification, in the case where the term “channel width” is simply used, it may denote a surrounded channel width and an apparent channel width. Alternatively, in this specification, in the case where the term “channel width” is simply used, it may denote an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where electric field mobility, a current value per channel width, and the like of a transistor are obtained by calculation, a surrounded channel width may be used for the calculation. In that case, a value different from one in the case where an effective channel width is used for the calculation is obtained in some cases.

The above-described CAAC-OS film is preferably used as the semiconductor film 406.

The semiconductor film 406 is an oxide containing indium, for example. An oxide can have high carrier mobility (electron mobility) by containing indium, for example. The semiconductor film 406 preferably contains an element M The element M is preferably aluminum, gallium, yttrium, tin, or the like. Other elements which can be used as the element M are boron, silicon, titanium, iron, nickel, germanium, yttrium, zirconium, molybdenum, lanthanum, cerium, neodymium, hafnium, tantalum, tungsten, and the like. Note that two or more of the above elements may be used in combination as the element M The element M is an element having high bonding energy with oxygen, for example. The element M is an element that can increase the energy gap of the oxide, for example. Further, the semiconductor film 406 preferably contains zinc. When the oxide contains zinc, the oxide is easily to be crystallized, for example.

Note that the semiconductor film 406 is not limited to the oxide containing indium. The semiconductor film 406 may be, for example, zinc tin oxide or gallium tin oxide.

For the semiconductor film 406, an oxide with a wide energy gap is used. For example, the energy gap of the semiconductor film 406 is greater than or equal to 2.5 eV and less than or equal to 4.2 eV, preferably greater than or equal to 2.8 eV and less than or equal to 3.8 eV, more preferably greater than or equal to 3 eV and less than or equal to 3.5 eV.

For example, the case where the semiconductor film 406 has a three-layer structure is described with reference to FIG. 25C.

For an oxide semiconductor layer 406b (middle layer), the description of the above-described CAAC-OS film and the like can be referred to. The oxide semiconductor layer 406a (bottom layer) and an oxide semiconductor layer 406c (top layer) include one or more elements other than oxygen included in the oxide semiconductor layer 406b. Since the oxide semiconductor layer 406a and the oxide semiconductor layer 406c each include one or more elements other than oxygen included in the oxide semiconductor layer 406b, an interface state is less likely to be formed at the interface between the oxide semiconductor layer 406a and the oxide semiconductor layer 406b and the interface between the oxide semiconductor layer 406b and the oxide semiconductor layer 406c.

In the case of using an In—M—Zn oxide as the oxide semiconductor layer 406a, when summation of In and M is assumed to be 100 atomic %, the proportions of In and Mare preferably set to be less than 50 atomic % and greater than or equal to 50 atomic %, respectively, further preferably less than 25 atomic % and greater than or equal to 75 atomic %, respectively. In the case of using an In—M—Zn oxide as the oxide semiconductor layer 406b, when summation of In and M is assumed to be 100 atomic %, the proportions of In and M are preferably set to be greater than or equal to 25 atomic % and less than 75 atomic %, respectively, further preferably greater than or equal to 34 atomic % and less than 66 atomic %, respectively. In the case of using an In—M—Zn oxide as the oxide semiconductor layer 406c, when summation of In and M is assumed to be 100 atomic %, the proportions of In and M are preferably set to be less than 50 atomic % and greater than or equal to 50 atomic %, respectively, further preferably less than 25 atomic % and greater than or equal to 75 atomic %, respectively. Note that the oxide semiconductor layer 406c may be an oxide that is a type the same as that of the oxide semiconductor layer 406a.

Here, in some cases, there is a mixed region of the oxide semiconductor layer 406a and the oxide semiconductor layer 406b between the oxide semiconductor layer 406a and the oxide semiconductor layer 406b. Further, in some cases, there is a mixed region of the oxide semiconductor layer 406b and the oxide semiconductor layer 406c between the oxide semiconductor layer 406b and the oxide semiconductor layer 406c. The mixed region has a low interface state density. For that reason, the stack of the oxide semiconductor layer 406a, the oxide semiconductor layer 406b, and the oxide semiconductor layer 406c has a band structure where energy at each interface and in the vicinity of the interface is changed continuously (continuous junction).

As the oxide semiconductor layer 406b, an oxide having an electron affinity higher than those of the oxide semiconductor layers 406a and 406c is used. For example, as the oxide semiconductor layer 406b, an oxide having an electron affinity higher than those of the oxide semiconductor layers 406a and 406c by 0.07 eV or higher and 1.3 eV or lower, preferably 0.1 eV or higher and 0.7 eV or lower, more preferably 0.15 eV or higher and 0.4 eV or lower is used. Note that the electron affinity refers to an energy difference between the vacuum level and the bottom of the conduction band.

At this time, when an electric field is applied to a gate electrode, a channel is formed in the oxide semiconductor layer 406b having the highest electron affinity in the oxide semiconductor layer 406a, the oxide semiconductor layer 406b, and the oxide semiconductor layer 406c.

Moreover, the thickness of the oxide semiconductor layer 406c is preferably as small as possible to increase the on-state current of the transistor. The thickness of the oxide semiconductor layer 406c is set to be less than 10 nm, preferably less than or equal to 5 nm, further preferably less than or equal to 3 nm, for example. Meanwhile, the oxide semiconductor layer 406c has a function of blocking elements other than oxygen (such as silicon) included in the adjacent insulating film from entering the oxide semiconductor layer 406b where a channel is formed. For this reason, it is preferable that the oxide semiconductor layer 406c have a certain thickness. The thickness of the oxide semiconductor layer 406c is set to be greater than or equal to 0.3 nm, preferably greater than or equal to 1 nm, further preferably greater than or equal to 2 nm, for example.

To improve reliability, preferably, the thickness of the oxide semiconductor layer 406a is large and the thickness of the oxide semiconductor layer 406c is small. Specifically, the thickness of the oxide semiconductor layer 406a is set to be greater than or equal to 20 nm, preferably greater than or equal to 30 nm, further preferably greater than or equal to 40 nm, still further preferably greater than or equal to 60 nm. With the oxide semiconductor layer 406a having a thickness greater than or equal to 20 nm, preferably greater than or equal to 30 nm, further preferably greater than or equal to 40 nm, still further preferably greater than or equal to 60 nm, the distance from the interface between the adjacent insulating film and the oxide semiconductor layer 406a to the oxide semiconductor layer 406b where the channel is formed can be greater than or equal to 20 nm, preferably greater than or equal to 30 nm, further preferably greater than or equal to 40 nm, still further preferably greater than or equal to 60 nm. Note that since the productivity of a semiconductor device might be reduced, the thickness of the oxide semiconductor layer 406a is set to be less than or equal to 200 nm, preferably less than or equal to 120 nm, further preferably less than or equal to 80 nm.

For example, the concentration of silicon in a region between the oxide semiconductor layer 406b and the oxide semiconductor layer 406a measured by SIMS is set to be lower than 1×10¹⁹ atoms/cm³, preferably lower than 5×10¹⁸ atoms/cm³, further preferably lower than 2×10¹⁸ atoms/cm³. The concentration of silicon in a region between the oxide semiconductor layer 406b and the oxide semiconductor layer 406c measured by SIMS is set to be lower than 1×10¹⁹ atoms/cm³, preferably lower than 5×10¹⁸ atoms/cm³, further preferably lower than 2×10¹⁸ atoms/cm³.

It is preferable to reduce the concentration of hydrogen in the oxide semiconductor layer 406a and the oxide semiconductor layer 406c in order to reduce the concentration of hydrogen in the oxide semiconductor layer 406b. The concentration of hydrogen in the oxide semiconductor layer 406a and the oxide semiconductor layer 406c measured by SIMS is set to be lower than or equal to 2×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³. It is preferable to reduce the concentration of nitrogen in the oxide semiconductor layer 406a and the oxide semiconductor layer 406c in order to reduce the concentration of nitrogen in the oxide semiconductor layer 406b. The concentration of nitrogen in the oxide semiconductor layer 406a and the oxide semiconductor layer 406c measured by SIMS is set to be lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

The above three-layer structure is an example of the semiconductor film 406. For example, a two-layer structure without the oxide semiconductor layer 406a or the oxide semiconductor layer 406c may be employed.

At least part (or all) of the conductive film 416a (and/or the conductive film 416b) is provided on at least part (or all) of a surface, a side surface, a top surface, and/or a bottom surface of a semiconductor film, e.g., the semiconductor film 406.

Alternatively, at least part (or all) of the conductive film 416a (and/or the conductive film 416b) is in contact with at least part (or all) of a surface, a side surface, a top surface, and/or a bottom surface of a semiconductor film, e.g., the semiconductor film 406. Further alternatively, at least part (or all) of the conductive film 416a (and/or the conductive film 416b) is in contact with at least part (or all) of a semiconductor film, e.g., the semiconductor film 406.

Alternatively, at least part (or all) of the conductive film 416a (and/or the conductive film 416b) is electrically connected to at least part (or all) of a surface, a side surface, a top surface, and/or a bottom surface of a semiconductor film, e.g., the semiconductor film 406. Alternatively, at least part (or all) of the conductive film 416a (and/or the conductive film 416b) is electrically connected to at least part (or all) of a semiconductor film, e.g., the semiconductor film 406.

Alternatively, at least part (or all) of the conductive film 416a (and/or the conductive film 416b) is provided near at least part (or all) of a surface, a side surface, a top surface, and/or a bottom surface of a semiconductor film, e.g., the semiconductor film 406. Alternatively, at least part (or all) of the conductive film 416a (and/or the conductive film 416b) is provided near at least part (or all) of a semiconductor film, e.g., the semiconductor film 406.

Alternatively, at least part (or all) of the conductive film 416a (and/or the conductive film 416b) is provided on a side of at least part (or all) of a surface, a side surface, a top surface, and/or a bottom surface of a semiconductor film, e.g., the semiconductor film 406. Alternatively, at least part (or all) of the conductive film 416a (and/or the conductive film 416b) is provided on a side of at least part (or all) of a semiconductor film, e.g., the semiconductor film 406.

Alternatively, at least part (or all) of the conductive film 416a (and/or the conductive film 416b) is provided obliquely above at least part (or all) of a surface, a side surface, a top surface, and/or a bottom surface of a semiconductor film, e.g., the semiconductor film 406. Alternatively, at least part (or all) of the conductive film 416a (and/or the conductive film 416b) is provided obliquely above at least part (or all) of a semiconductor film, e.g., the semiconductor film 406.

Alternatively, at least part (or all) of the conductive film 416a (and/or the conductive film 416b) is provided above at least part (or all) of a surface, a side surface, a top surface, and/or a bottom surface of a semiconductor film, e.g., the semiconductor film 406. Alternatively, at least part (or all) of the conductive film 416a (and/or the conductive film 416b) is provided above at least part (or all) of a semiconductor film, e.g., the semiconductor film 406.

There is no large limitation on the substrate 400. For example, a glass substrate, a ceramic substrate, a quartz substrate, a sapphire substrate, or a stabilized zirconia substrate (e.g., an yttria-stabilized zirconia substrate) may be used. Alternatively, a single crystal semiconductor substrate or a polycrystalline semiconductor substrate made of silicon, silicon carbide, or the like, a compound semiconductor substrate made of silicon germanium or the like, a silicon-on-insulator (SOI) substrate, or the like may be used. Still alternatively, any of these substrates provided with a semiconductor element may be used.

Still alternatively, a flexible substrate may be used as the substrate 400. As a method for providing the transistor over a flexible substrate, there is a method in which the transistor is formed over a non-flexible substrate and then the transistor is separated and transferred to the substrate 400 which is a flexible substrate. In that case, a separation layer is preferably provided between the non-flexible substrate and the transistor.

The insulating film 402 may be formed of, for example, a single layer or a stack of an insulating film containing aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulating film 402 can have a function of preventing diffusion of impurities from the substrate 400. Here, in the case where the semiconductor film 406 is an oxide semiconductor film, the insulating film 402 can have a function of supplying oxygen to the semiconductor film 406. Therefore, the insulating film 402 is preferably an insulating film containing oxygen. For example, an insulating film containing oxygen more than that in the stoichiometric composition is preferable.

The insulating film 402 may be formed by a sputtering method, a chemical vapor deposition (CVD) method, a molecular beam epitaxy (MBE) method, a pulsed laser deposition (PLD) method, or an atomic layer deposition (ALD) method.

Note that in the case where the insulating film 402 is a stacked-layer film, films in the stacked-layer film may be formed using by different formation methods such as the above formation methods. For example, the first layer may be formed by a CVD method and the second layer may be formed by an ALD method. Alternatively, the first layer may be formed by a sputtering method and the second layer may be formed by an ALD method. When films are formed by different formation methods as described above, the films can have different functions or different properties. Further, by stacking the films, a more appropriate film can be formed as a stacked-layer film.

In other words, an n-th film is formed by at least one of a sputtering method, a CVD method, an MBE method, a PLD method, an ALD method, and the like, and an n+1 film is formed by at least one of a sputtering method, a CVD method, an MBE method, a PLD method, an ALD method, and the like (n is a natural number). Note that the n-th film and the n+1 film may be formed by the same formation method or different formation methods. Note that the n-th film and the n+2 film may be formed by the same formation method. Alternatively, all the films may be formed by the same formation method.

Alternatively, when a silicon substrate is used as the substrate 400, the insulating film to be the insulating film 402 can be formed by a thermal oxidation method.

Then, in order to planarize the surface of the insulating film to be the insulating film 402, chemical mechanical polishing (CMP) may be performed. By CMP treatment, the average surface roughness (Ra) of the insulating film to be the insulating film 402 is less than or equal to 1 nm, preferably less than or equal to 0.3 nm, more preferably less than or equal to 0.1 nm. In some cases, Ra that is less than or equal to the above value can increase the crystallinity of the semiconductor film 406. Ra can be measured using an atomic force microscope (AFM).

The conductive film 416a and the conductive film 416b each may be formed to have a single-layer structure or a stacked-layer structure using a conductive film containing one or more kinds of aluminum, titanium, chromium, cobalt, nickel, copper, yttrium, zirconium, molybdenum, ruthenium, silver, tantalum, and tungsten, for example.

A conductive film to be the conductive film 416a and the conductive film 416b may be formed by a sputtering method, a CVD method, an MBE method, a PLD method, an ALD method, or the like.

The conductive film 416a and the conductive film 416b are formed in such a manner that the conductive film to be the conductive film 416a and the conductive film 416b is formed and then partly etched. Therefore, it is preferable to employ a formation method by which the semiconductor film 406 is not damaged when the conductive film is formed. In other words, the conductive film is preferably formed by an MCVD method or the like.

Note that in the case where the conductive film 416a and the conductive film 416b are each formed to have a stacked-layer structure, films in the stacked-layer film may be formed by different formation methods such as a CVD method (a plasma CVD method, a thermal CVD method, an MCVD method, an MOCVD method, or the like), an MBE method, a PLD method, and an ALD method. For example, the first layer may be formed by an MOCVD method and the second layer may be formed by a sputtering method. Alternatively, the first layer may be formed by an ALD method and the second layer may be formed by an MOCVD method. Alternatively, the first layer may be formed by an ALD method and the second layer may be formed by a sputtering method. Alternatively, the first layer may be formed by an ALD method, the second layer may be formed by a sputtering method, and the third layer may be formed by an ALD method. Thus, when films are formed by different formation methods, the films can have different functions or different properties. Further, by stacking the films, a more appropriate film can be formed as a stacked-layer film.

In other words, in the case where the conductive film 416a and the conductive film 416b are each a stacked-layer film, for example, an n-th film is formed by at least one of a CVD method (a plasma CVD method, a thermal CVD method, an MCVD method, an MOCVD method, or the like), an MBE method, a PLD method, an ALD method, and the like and an n+1 film is formed by at least one of a CVD method (a plasma CVD method, a thermal CVD method, an MCVD method, an MOCVD method, or the like), an MBE method, a PLD method, an ALD method, and the like (n is a natural number). Note that the n-th film and the n+1 film may be formed by different formation methods. Note that the n-th film and the n+2 film may be formed by the same formation method. Alternatively, all the films may be formed by the same formation method.

Note that the conductive film 416a (conductive film 416b) or at least one film in the stacked conductive film 416a (conductive film 416b), and the semiconductor film 406 or at least one film in the stacked semiconductor film 406 may be formed by the same formation method. For example, both of them may be formed by an ALD method. Thus, they can be formed without exposure to the air. As a result, entry of impurities can be prevented. Alternatively, for example, the conductive film 416a (conductive film 416b) and the semiconductor film 406 in contact with each other may be formed by the same formation method. Thus, the formation can be performed in the same chamber. As a result, entry of impurities can be prevented. As described above, the same formation method may be employed in not only the case of the semiconductor film 406 and the conductive film 416a (conductive film 416b) but also the case of other films which are adjacent to each other. Note that a method for manufacturing a semiconductor device of one embodiment of the present invention is not limited thereto.

Note that the conductive film 416a (conductive film 416b) or at least one film in the stacked conductive film 416a (conductive film 416b), the semiconductor film 406 or at least one film in the stacked semiconductor film 406, and the insulating film 402 or at least one film in the stacked insulating film 402 may be formed by the same formation method. For example, all of them may be formed by a sputtering method. Thus, they can be formed without exposure to the air. As a result, entry of impurities can be prevented. Note that a method for manufacturing a semiconductor device of one embodiment of the present invention is not limited thereto.

The insulating film 412 may be formed of, for example, a single layer or a stack of an insulating film containing aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

Note that in the case where the insulating film 412 is formed to have a stacked-layer structure, films in the insulating film 412 may be formed by different formation methods such as a CVD method (a plasma CVD method, a thermal CVD method, an MCVD method, an MOCVD method, or the like), an MBE method, a PLD method, and an ALD method. For example, the first layer may be formed by an MOCVD method and the second layer may be formed by a sputtering method. Alternatively, the first layer may be formed by an ALD method and the second layer may be formed by an MOCVD method. Alternatively, the first layer may be formed by an ALD method and the second layer may be formed by a sputtering method. Alternatively, the first layer may be formed by an ALD method, the second layer may be formed by a sputtering method, and the third layer may be formed by an ALD method. Thus, when films are formed by different formation methods, the films can have different functions or different properties. Further, by stacking the films, a more appropriate film can be formed as a stacked-layer film.

In other words, in the case where the insulating film 412 is a stacked-layer film, for example, an n-th film is formed by at least one of a CVD method (a plasma CVD method, a thermal CVD method, an MCVD method, an MOCVD method, or the like), an MBE method, a PLD method, an ALD method, and the like and an n+1-th film is formed by at least one of a CVD method (a plasma CVD method, a thermal CVD method, an MCVD method, an MOCVD method, or the like), an MBE method, a PLD method, an ALD method, and the like (n is a natural number). Note that the n-th film and the n+1-th film may be formed by different formation methods. Note that the n-th film and the n+2-th film may be formed by the same formation method. Alternatively, all the films may be formed by the same formation method.

Note that the insulating film 412 or at least one film in the stacked insulating film 412, and the conductive film 416a (conductive film 416b) or at least one film in the stacked conductive film 416a (conductive film 416b) may be formed by the same formation method. For example, both of them may be formed by an ALD method. Thus, they can be formed without exposure to the air. As a result, entry of impurities can be prevented. Alternatively, for example, the conductive film 416a (conductive film 416b) and the insulating film 412 in contact with each other may be formed by the same formation method. Thus, the formation can be performed in the same chamber. As a result, entry of impurities can be prevented.

Note that the insulating film 412 or at least one film in the stacked insulating film 412, the conductive film 416a (conductive film 416b) or at least one film in the stacked conductive film 416a (conductive film 416b), the semiconductor film 406 or at least one film in the stacked semiconductor film 406, and the insulating film 402 or at least one film in the stacked insulating film 402 may be formed by the same formation method. For example, all of them may be formed by a sputtering method. Thus, they can be formed without exposure to the air. As a result, entry of impurities can be prevented. Note that a method for manufacturing a semiconductor device of one embodiment of the present invention is not limited thereto.

The conductive film 404 may be formed to have a single-layer structure or a stacked-layer structure using a conductive film containing one or more kinds of aluminum, titanium, chromium, cobalt, nickel, copper, yttrium, zirconium, molybdenum, ruthenium, silver, tantalum, and tungsten, for example.

A conductive film to be the conductive film 404 may be formed by a sputtering method, a CVD method, an MBE method, a PLD method, an ALD method, or the like.

The insulating film 412 functions as a gate insulating film of a transistor. Therefore, the conductive film 404 is preferably formed by a formation method by which the insulating film 412 is not damaged when the conductive film to be the conductive film 404 is formed. In other words, the conductive film is preferably formed by an MCVD method or the like.

Note that in the case where the conductive film 404 is formed to have a stacked-layer structure, films in the conductive film 404 may be formed by different formation methods such as a CVD method (a plasma CVD method, a thermal CVD method, an MCVD method, an MOCVD method, or the like), an MBE method, a PLD method, and an ALD method. For example, the first layer may be formed by an MOCVD method and the second layer may be formed by a sputtering method. Alternatively, the first layer may be formed by an ALD method and the second layer may be formed by an MOCVD method. Alternatively, the first layer may be formed by an ALD method and the second layer may be formed by a sputtering method. Alternatively, the first layer may be formed by an ALD method, the second layer may be formed by a sputtering method, and the third layer may be formed by an ALD method. Thus, when films are formed by different formation methods, the films can have different functions or different properties. Further, by stacking the films, a more appropriate film can be formed as a stacked-layer film.

In other words, in the case where the conductive film 404 is a stacked-layer film, for example, an n-th film is formed by at least one of a CVD method (a plasma CVD method, a thermal CVD method, an MCVD method, an MOCVD method, or the like), an MBE method, a PLD method, an ALD method, and the like and an n+1-th film is formed by at least one of a CVD method (a plasma CVD method, a thermal CVD method, an MCVD method, an MOCVD method, or the like), an MBE method, a PLD method, an ALD method, and the like (n is a natural number). Note that the n-th film and the n+1-th film may be formed by different formation methods. Note that the n-th film and the n+2-th film may be formed by the same formation method. Alternatively, all the films may be formed by the same formation method.

Note that the conductive film 404 or at least one film in the stacked conductive film 404, and the insulating film 412 or at least one film in the stacked insulating film 412 may be formed by the same formation method. For example, both of them may be formed by an ALD method. Thus, they can be formed without exposure to the air. As a result, entry of impurities can be prevented. Alternatively, for example, the conductive film 404 and the insulating film 412 in contact with each other may be formed by the same formation method. Thus, the formation can be performed in the same chamber. As a result, entry of impurities can be prevented.

Note that the conductive film 404 or at least one film in the stacked conductive film 404, the insulating film 412 or at least one film in the stacked insulating film 412, the conductive film 416a (conductive film 416b) or at least one film in the stacked conductive film 416a (conductive film 416b), the semiconductor film 406 or at least one film in the stacked semiconductor film 406, and the insulating film 402 or at least one film in the stacked insulating film 402 may be formed by the same formation method. For example, all of them may be formed by a sputtering method. Thus, they can be formed without exposure to the air. As a result, entry of impurities can be prevented. Note that a method for manufacturing a semiconductor device of one embodiment of the present invention is not limited thereto.

The insulating film 418 may be formed of, for example, a single layer or a stack of an insulating film containing aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide.

The insulating film 402 can have a function of preventing diffusion of impurities from the substrate 400. Here, in the case where the semiconductor film 406 is an oxide semiconductor film, the insulating film 402 can have a function of supplying oxygen to the semiconductor film 406. Therefore, the insulating film 402 is preferably an insulating film containing oxygen. For example, an insulating film containing oxygen more than that in the stoichiometric composition is preferable.

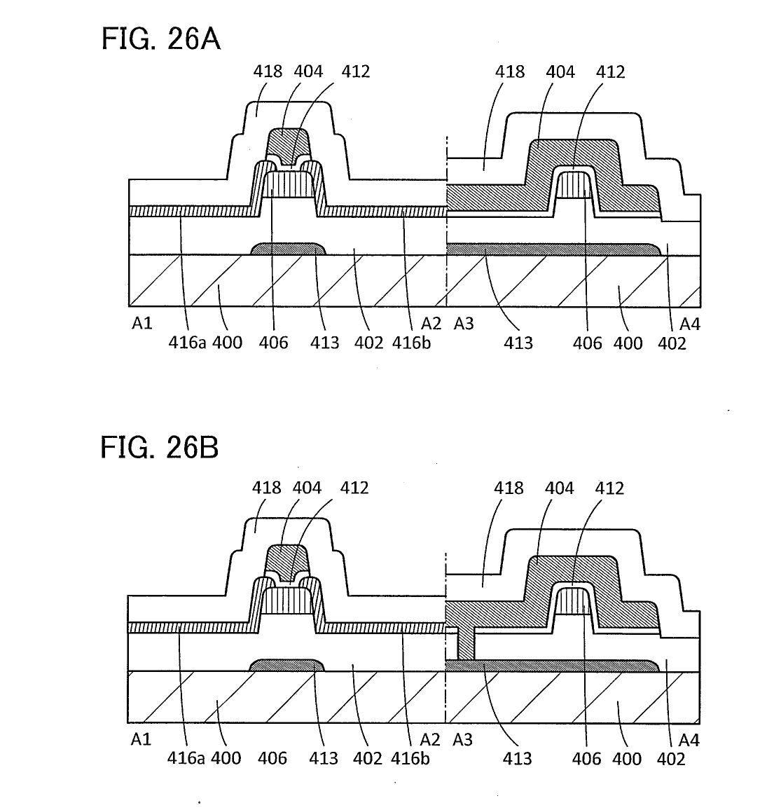

Although FIGS. 25A to 25C show an example in which the gate electrode of the transistor is provided above the semiconductor film 406, a semiconductor device of one embodiment of the present invention is not limited thereto. As illustrated in FIG. 26A, a conductive film 413 that can function as a gate electrode may be provided below the semiconductor film 406. For the conductive film 413, the description of the conductive film 404 is referred to. Note that a potential or signal which is the same as that supplied to the conductive film 404 or a potential or signal which is different from that supplied to the conductive film 404 may be supplied to the conductive film 413. For example, by supplying a constant potential to the conductive film 413, the threshold voltage of a transistor may be controlled. FIG. 26B shows an example in which the conductive film 413 and the conductive film 404 are connected to each other through an opening. Even in the case other than the case illustrated in FIGS. 25A to 25C, the conductive film 413 capable of functioning as a gate electrode can be similarly provided.

### <Modification Example of Transistor Structure 1>

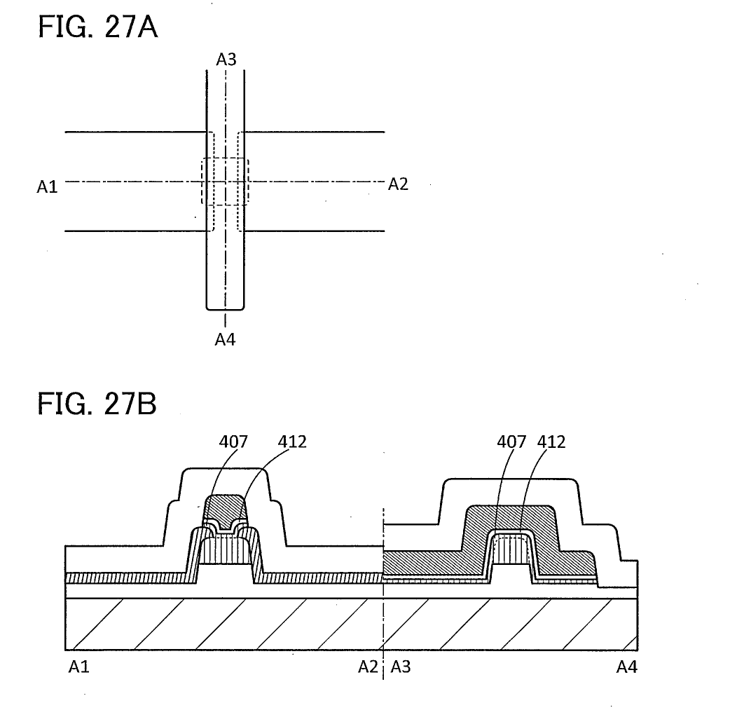

As in a transistor illustrated in FIGS. 27A and 27B, a semiconductor film 407 may be provided under the insulating film 412. As the semiconductor film 407, the semiconductor film shown as the oxide semiconductor layer 406c may be used. Note that description of the transistor in FIGS. 25A to 25C is referred to for the structures of the other components.

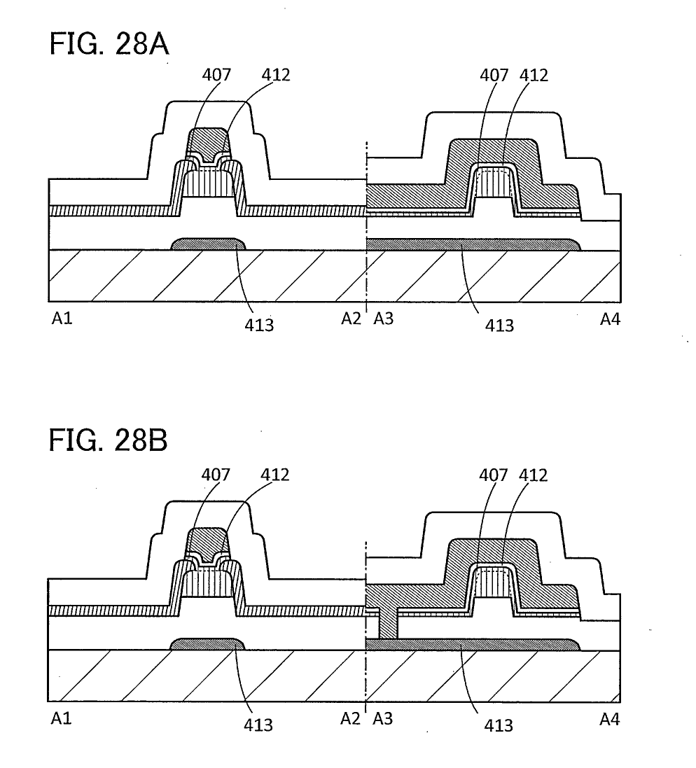

Although FIGS. 27A and 27B show an example in which the gate electrode of the transistor is provided above the semiconductor film 406, a semiconductor device of one embodiment of the present invention is not limited thereto. As illustrated in FIG. 28A, the conductive film 413 that can function as a gate electrode may be provided below the semiconductor film 406. For the conductive film 413, description of the conductive film 404 is referred to. Note that a potential or signal which is the same as that supplied to the conductive film 404 or a potential or signal which is different from that supplied to the conductive film 404 may be supplied to the conductive film 413. For example, by supplying a constant potential to the conductive film 413, the threshold voltage of a transistor may be controlled. FIG. 28B shows an example in which the conductive film 413 and the conductive film 404 are connected to each other through an opening. Even in the case other than the cases illustrated in FIGS. 25A to 25C and FIGS. 27A and 27B, the conductive film 413 capable of functioning as a gate electrode can be similarly provided.

### <Transistor Structure 2>

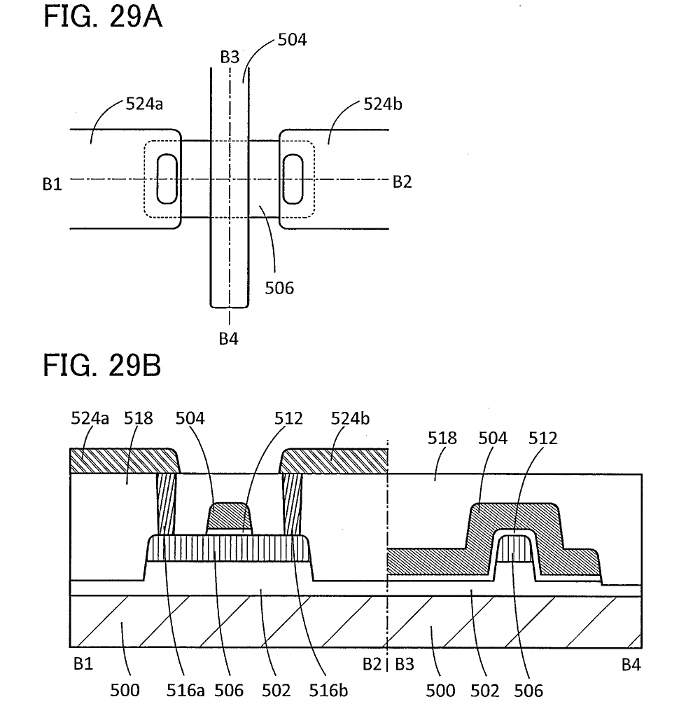

FIGS. 29A and 29B are a top view and a cross-sectional view which illustrate a transistor of one embodiment of the present invention. FIG. 29A is a top view and FIG. 29B is a cross-sectional view taken along dashed-dotted line B1-B2 and dashed-dotted line B3-B4 in FIG. 29A. Note that for simplification of the drawing, some components are not illustrated in the top view in FIG. 29A.

The transistor in FIGS. 29A and 29B includes an insulating film 502 having a projection over a substrate 500, a semiconductor film 506 over the projection of the insulating film 502, an insulating film 512 over the semiconductor film 506, a conductive film 504 which is in contact with a top surface of the insulating film 512 and faces a top surface and side surfaces of the semiconductor film 506, an insulating film 518 which is over the semiconductor film 506 and the conductive film 504 and includes openings reaching the semiconductor film 506, a conductive film 516a and a conductive film 516b with which the openings are filled, and a conductive film 524a and a conductive film 524b which are in contact with the conductive film 516a and the conductive film 516b, respectively. Note that the insulating film 502 does not necessarily include a projection. The conductive film 504 serves as a gate electrode of the transistor. Further, the conductive film 516a and the conductive film 516b serve as a source electrode and a drain electrode of the transistor.

In the transistor in FIGS. 29A and 29B, the conductive film 516a and the conductive film 516b are provided so as not to overlap with the conductive film 504. Thus, parasitic capacitance between the conductive film 516a and the conductive film 504 and parasitic capacitance between the conductive film 516b and the conductive film 504 can be reduced. For this reason, the transistor in FIGS. 29A and 29B can have excellent switching characteristics.

Further, since the level of the top surface of the insulating film 518, that of the conductive film 516a, and that of the conductive film 516b are the same, shape defects do not easily occur. Therefore, a semiconductor device including the transistor can be manufactured with high yield.

The conductive film 524a and the conductive film 524b each may be formed to have a single-layer structure or a stacked-layer structure using a conductive film containing one or more kinds of aluminum, titanium, chromium, cobalt, nickel, copper, yttrium, zirconium, molybdenum, ruthenium, silver, tantalum, and tungsten, for example.

For the substrate 500, the description of the substrate 400 is referred to. For the insulating film 502, the description of the insulating film 402 is referred to. For the semiconductor film 506, the description of the semiconductor film 406 is referred to. For the conductive film 516a and the conductive film 516b, the description of the conductive film 416a and the conductive film 416b is referred to. For the insulating film 512, the description of the insulating film 412 is referred to. For the conductive film 504, the description of the conductive film 404 is referred to. For the insulating film 518, the description of the insulating film 418 is referred to.

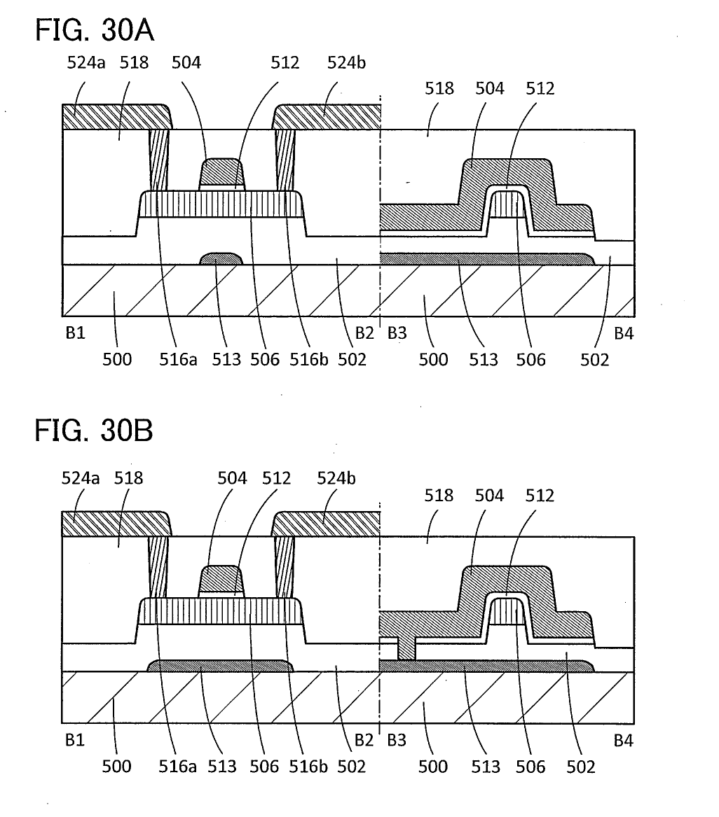

Although FIGS. 29A and 29B show an example in which the gate electrode of the transistor is provided above the semiconductor film 506, a semiconductor device of one embodiment of the present invention is not limited thereto. As illustrated in FIG. 30A, a conductive film 513 that can function as a gate electrode may be provided below the semiconductor film 506. For the conductive film 513, the description of the conductive film 504 is referred to. Note that a potential or signal which is the same as that supplied to the conductive film 504 or a potential or signal which is different from that supplied to the conductive film 504 may be supplied to the conductive film 513. For example, by supplying a constant potential to the conductive film 513, the threshold voltage of a transistor may be controlled. FIG. 30B shows an example in which the conductive film 513 and the conductive film 504 are connected to each other through an opening. The conductive film 513 may be provided so as to overlap with the conductive film 524a and the conductive film 524b. An example in that case is shown in FIG. 30B. Even in the case other than the cases illustrated in FIGS. 25A to 25C, FIGS. 27A and 27B, and FIGS. 29A and 29B, the conductive film 513 capable of functioning as the gate electrode can be similarly provided.

### <Modification Example of Transistor Structure 2>

In the transistor illustrated in FIGS. 29A and 29B, a semiconductor film may be provided under the insulating film 512. For the semiconductor film, the description of the semiconductor film 407 is referred to. Note that the description of the transistor in FIGS. 29A and 29B is referred to for the structures of the other components.

### <Transistor Structure 3>

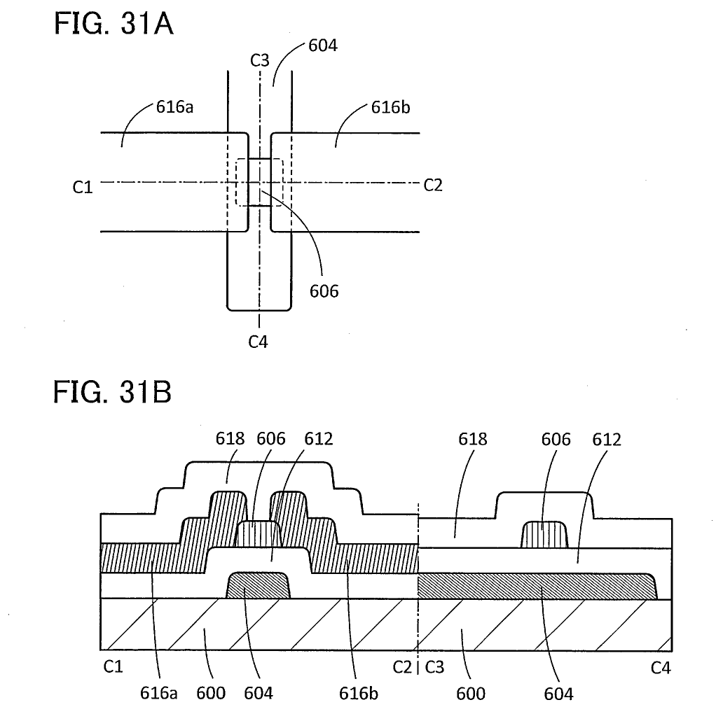

FIGS. 31A and 31B are a top view and a cross-sectional view which illustrate a transistor of one embodiment of the present invention. FIG. 31A is a top view and FIG. 31B is a cross-sectional view taken along dashed-dotted line C1-C2 and dashed-dotted line C3-C4 in FIG. 31A. Note that for simplification of the drawing, some components are not illustrated in the top view in FIG. 31A.

The transistor illustrated in FIGS. 31A and 31B includes a conductive film 604 over a substrate 600, an insulating film 612 over the conductive film 604, a semiconductor film 606 over the insulating film 612, a conductive film 616a and a conductive film 616b in contact with a top surface and side surfaces of the semiconductor film 606, and an insulating film 618 over the semiconductor film 606, the conductive film 616a, and the conductive film 616b. Note that an insulating film may be provided between the substrate 600 and the conductive film 604. The conductive film 604 functions as a gate electrode of the transistor. Further, the conductive film 616a and the conductive film 616b serve as a source electrode and a drain electrode of the transistor.

The transistor may include a conductive film which overlaps with the semiconductor film 606 with the insulating film 618 provided therebetween. The conductive film functions as a second gate electrode of the transistor. Further, an s-channel structure may be formed using the second gate electrode.

For the substrate 600, the description of the substrate 400 is referred to. For the conductive film 604, the description of the conductive film 404 is referred to. For the insulating film 612, the description of the insulating film 412 is referred to. For the semiconductor film 606, the description of the semiconductor film 406 is referred to. For the conductive film 616a and the conductive film 616b, the description of the conductive film 416a and the conductive film 416b is referred to. For the insulating film 618, the description of the insulating film 418 is referred to.

Over the insulating film 618, a display element may be provided. For example, a pixel electrode, a liquid crystal layer, a common electrode, a light-emitting layer, an organic EL layer, an anode electrode, a cathode electrode, or the like may be provided. The display element is connected to the conductive film 616a or the like, for example.

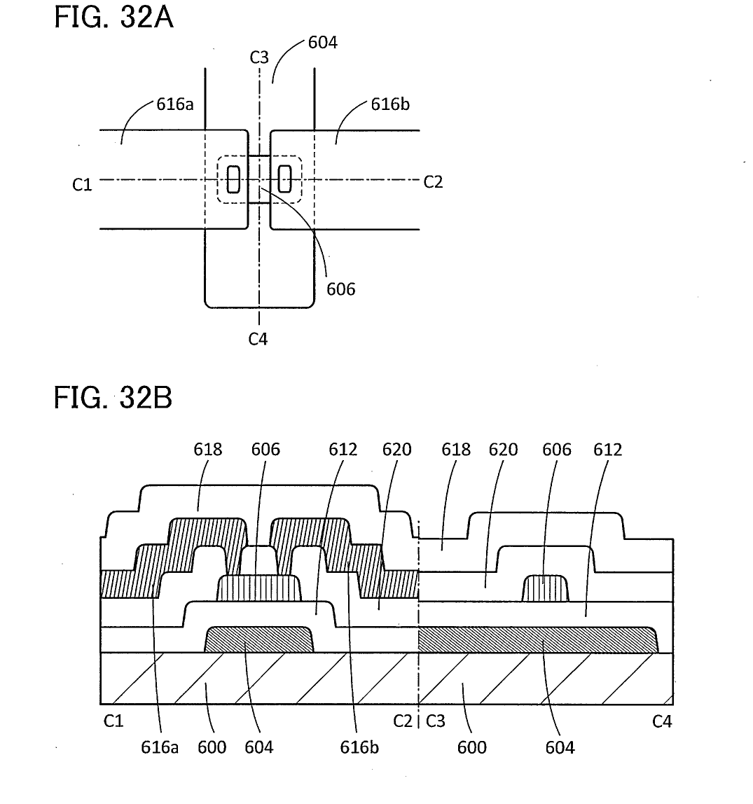

Over the semiconductor film 606, an insulating film that can function as a channel protective film may be provided. Alternatively, as illustrated in FIGS. 32A and 32B, an insulating film 620 may be provided between the semiconductor film 606 and the conductive films 616a and 616b. In that case, the conductive film 616a (conductive film 616b) and the semiconductor film 606 are connected to each other through an opening in the insulating film 620. For the insulating film 620, the description of the insulating film 412 may be referred to.

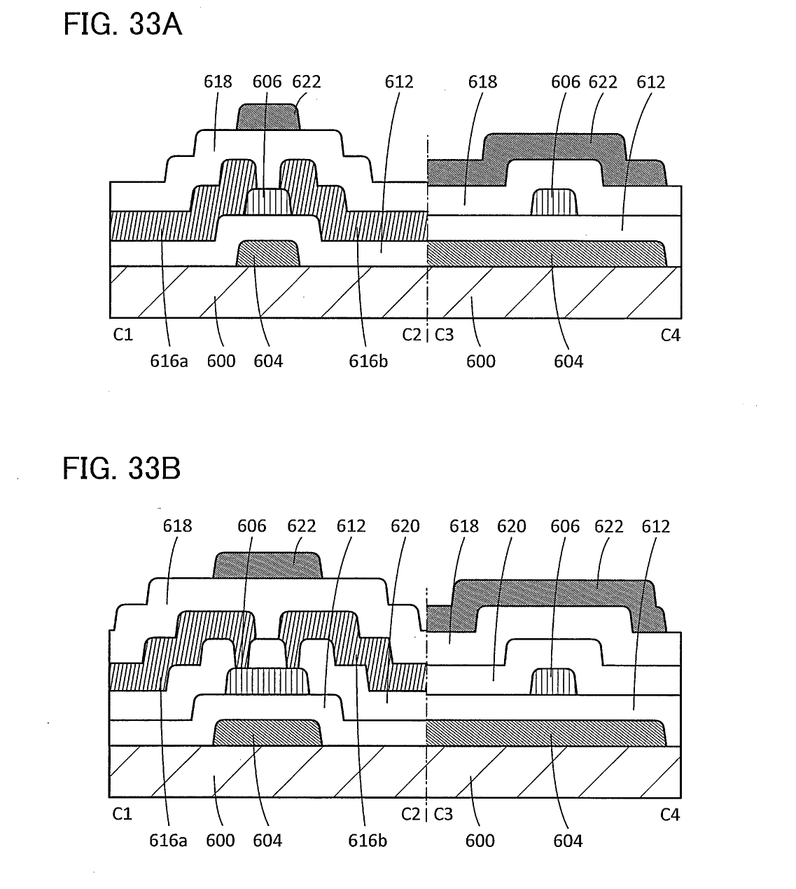

In FIG. 31B and FIG. 32B, a conductive film 622 may be provided over the insulating film 618. Examples in that case are shown in FIGS. 33A and 33B. For the conductive film 622, the description of the conductive film 604 is referred to. A potential or signal which is the same as that supplied to the conductive film 604 or a potential or signal which is different from that supplied to the conductive film 604 may be supplied to the conductive film 622. For example, by supplying a constant potential to the conductive film 622, the threshold voltage of a transistor may be controlled. In other words, the conductive film 622 can function as a gate electrode.

### <Semiconductor Device>

An example of a semiconductor device of one embodiment of the present invention is shown below.

### <Circuit>

An example of a circuit including a transistor of one embodiment of the present invention is shown below.

### [Cross-Sectional Structure]

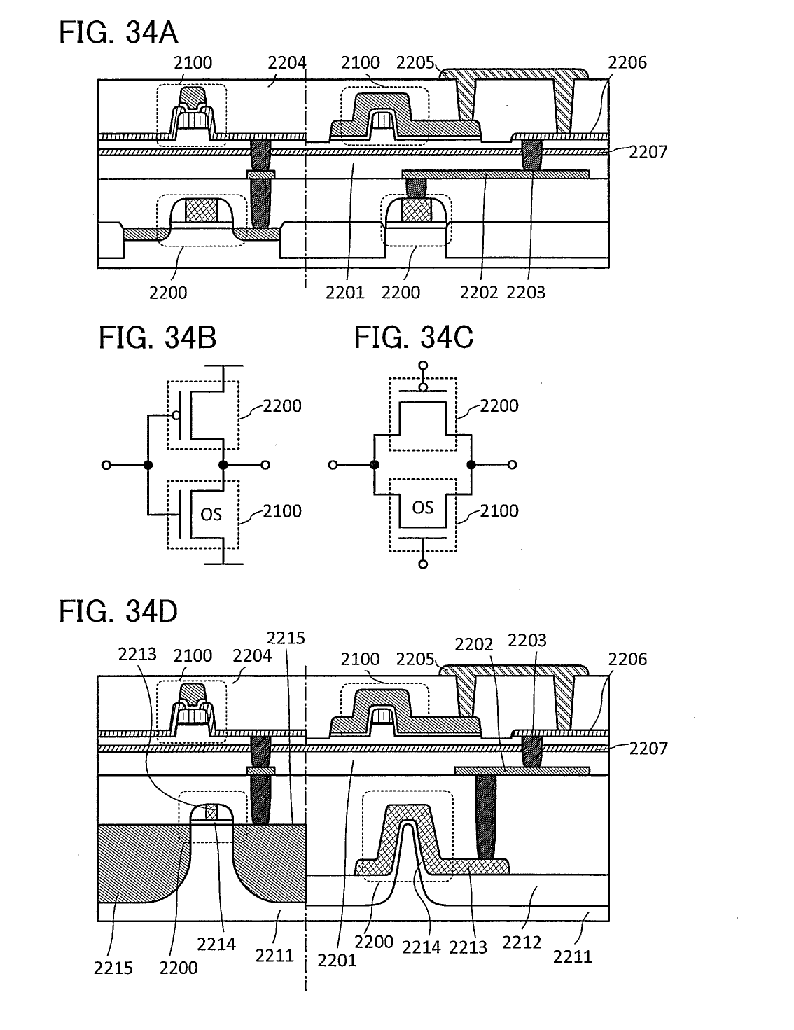

FIG. 34A is a cross-sectional view of a semiconductor device of one embodiment of the present invention. The semiconductor device illustrated in FIG. 34A includes a transistor 2200 using a first semiconductor in a lower portion and a transistor 2100 using a second semiconductor in an upper portion. FIG. 34A shows an example in which the transistor illustrated in FIGS. 25A to 25C is used as the transistor 2100 using the second semiconductor.

As the first semiconductor, a semiconductor having an energy gap different from that of the second semiconductor may be used. For example, the first semiconductor may be a semiconductor other than an oxide semiconductor and the second semiconductor may be an oxide semiconductor. As the first semiconductor, silicon, germanium, or the like which has a polycrystalline structure, a single crystal structure, or the like may be used. Alternatively, a semiconductor having distortion such as distorted silicon may be used. Alternatively, as the first semiconductor, gallium arsenide, aluminum gallium arsenide, indium gallium arsenide, gallium nitride, indium phosphide, silicon germanium, or the like which can be used for a high-electron-mobility transistor (HEMT) may be used. By using any of these semiconductors as the first semiconductor, the transistor 2100 capable of high speed operation can be obtained. By using an oxide semiconductor as the second semiconductor, the transistor 2200 with low off-state current can be obtained.

Note that the transistor 2200 may be either an n-channel transistor or a p-channel transistor, and an appropriate transistor is used in accordance with a circuit. As the transistor 2100 and/or the transistor 2200, the above-described transistor or the transistor illustrated in FIG. 34A is not necessarily used in some cases.

The semiconductor device illustrated in FIG. 34A includes the transistor 2100 above the transistor 2200 with an insulating film 2201 and an insulating film 2207 provided therebetween. Between the transistor 2200 and the transistor 2100, a plurality of conductive films 2202 which function as wirings are provided. Wirings or electrodes provided in an upper layer and a lower layer are electrically connected to each other by a plurality of conductive films 2203 embedded in insulating films. Further, the semiconductor device illustrated in FIG. 34A includes an insulating film 2204 over the transistor 2100, a conductive film 2205 over the insulating film 2204, and a conductive film 2206 formed in the same layer (through the same steps) as a source electrode and a drain electrode of the transistor 2100.

By stacking a plurality of transistors, a plurality of circuits can be arranged with high density.

Here, in the case where single crystal silicon is used as the first semiconductor of the transistor 2200, the hydrogen concentration in an insulating film near the first semiconductor of the transistor 2200 is preferably high. The hydrogen terminates dangling bonds of silicon, so that the reliability of the transistor 2200 can be increased. On the other hand, in the case where an oxide semiconductor is used as the second semiconductor of the transistor 2100, the hydrogen concentration in an insulating film near the second semiconductor of the transistor 2100 is preferably low. Since the hydrogen causes generation of carriers in the oxide semiconductor, which might lead to a decrease in the reliability of the transistor 2100. Therefore, in the case where the transistor 2200 using single crystal silicon and the transistor 2100 using an oxide semiconductor are stacked, providing the insulating film 2207 having a function of blocking hydrogen between the transistors is effective because the reliability of the transistors can be increased.

The insulating film 2207 may be, for example, formed to have a single-layer structure or a stacked-layer structure using an insulating film containing aluminum oxide, aluminum oxynitride, gallium oxide, gallium oxynitride, yttrium oxide, yttrium oxynitride, hafnium oxide, hafnium oxynitride, yttria-stabilized zirconia (YSZ), or the like.

Further, an insulating film having a function of blocking hydrogen is preferably formed over the transistor 2100 to cover the transistor 2100 using an oxide semiconductor. As the insulating film, an insulating film that is similar to the insulating film 2207 can be used, and in particular, an aluminum oxide film is preferably used. The aluminum oxide film has a high blocking effect of preventing penetration of both oxygen and impurities such as hydrogen and moisture. Thus, by using the aluminum oxide film as the insulating film covering the transistor 2100, release of oxygen from the oxide semiconductor included in the transistor 2100 can be prevented and entry of water and hydrogen into the oxide semiconductor can be prevented.

Note that the transistor 2200 can be a transistor of various types without being limited to a planar type transistor. For example, a FIN-type transistor can be used. An example of a cross-sectional view in this case is shown in FIG. 34D. An insulating layer 2212 is provided over a semiconductor substrate 2211. The semiconductor substrate 2211 includes a projection portion with a thin tip (also referred to a fin). Alternatively, the projection portion may not have the thin tip; a projection portion with a cuboid-like projection portion and a projection portion with a thick tip are permitted, for example. A gate insulating film 2214 is provided over the projection portion of the semiconductor substrate 2211, and a gate electrode 2213 is provided over the gate insulating film 2214. Source and drain regions 2215 are formed in the semiconductor substrate 2211. Note that here is shown an example in which the semiconductor substrate 2211 includes the projection portion; however, a semiconductor device of one embodiment of the present invention is not limited thereto. For example, a semiconductor region having a projection portion may be formed by processing an SOI substrate.

### [Circuit Configuration Example]

In the above circuit, electrodes of the transistor 2100 and the transistor 2200 can be connected in a variety of ways; thus, a variety of circuits can be formed. Examples of circuit configurations which can be achieved by using a semiconductor device of one embodiment of the present invention are shown below.

### [CMOS Circuit]

A circuit diagram in FIG. 34B shows a configuration of a so-called CMOS circuit in which the p-channel transistor 2200 and the n-channel transistor 2100 are connected to each other in series and in which gates of them are connected to each other.

### [Analog Switch]

A circuit diagram in FIG. 34C shows a configuration in which sources of the transistors 2100 and 2200 are connected to each other and drains of the transistors 2100 and 2200 are connected to each other. With such a configuration, the transistors can function as a so-called analog switch.

### [Memory Device Example]

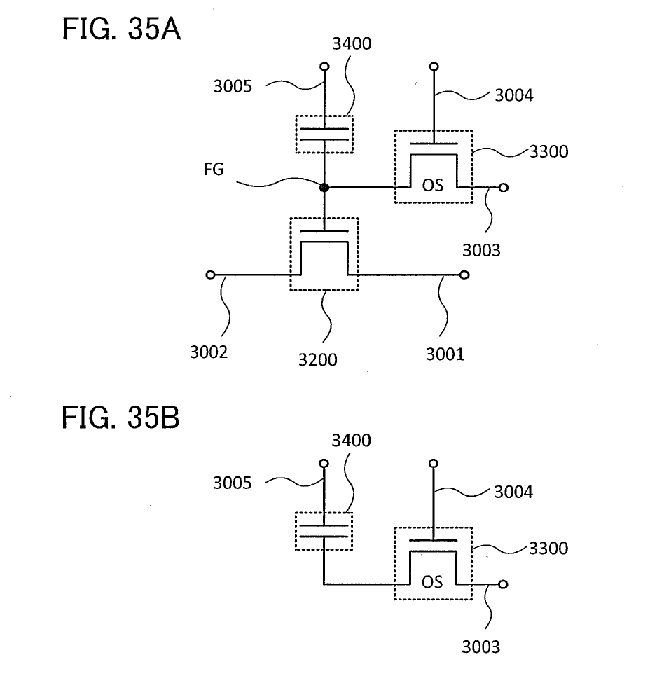

An example of a semiconductor device (memory device) which includes the transistor of one embodiment of the present invention, which can retain stored data even when not powered, and which has an unlimited number of write cycles is shown in FIGS. 35A and 35B.

The semiconductor device illustrated in FIG. 35A includes a transistor 3200 using a first semiconductor, a transistor 3300 using a second semiconductor, and a capacitor 3400. Note that any of the above-described transistors can be used as the transistor 3300.

The transistor 3300 is a transistor using an oxide semiconductor. Since the off-state current of the transistor 3300 is low, stored data can be retained for a long period at a predetermined node of the semiconductor device. In other words, power consumption of the semiconductor device can be reduced because refresh operation becomes unnecessary or the frequency of refresh operation can be extremely low.

In FIG. 35A, a first wiring 3001 is electrically connected to a source of the transistor 3200. A second wiring 3002 is electrically connected to a drain of the transistor 3200. A third wiring 3003 is electrically connected to one of the source and the drain of the transistor 3300. A fourth wiring 3004 is electrically connected to the gate of the transistor 3300. The gate of the transistor 3200 and the other of the source and the drain of the transistor 3300 are electrically connected to the one electrode of the capacitor 3400. A fifth wiring 3005 is electrically connected to the other electrode of the capacitor 3400.

The semiconductor device in FIG. 35A has a feature that the potential of the gate of the transistor 3200 can be retained, and thus enables writing, retaining, and reading of data as follows.

Writing and retaining of data are described. First, the potential of the fourth wiring 3004 is set to a potential at which the transistor 3300 is turned on, so that the transistor 3300 is turned on. Accordingly, the potential of the third wiring 3003 is supplied to a node FG where the gate of the transistor 3200 and the one electrode of the capacitor 3400 are electrically connected to each other. That is, a predetermined charge is supplied to the gate of the transistor 3200 (writing). Here, one of two kinds of charges providing different potential levels (hereinafter referred to as a low-level charge and a high-level charge) is supplied. After that, the potential of the fourth wiring 3004 is set to a potential at which the transistor 3300 is turned off, so that the transistor 3300 is turned off. Thus, the charge is held at the node FG (retaining).

Since the off-state current of the transistor 3300 is extremely low, the charge of the node FG is retained for a long time.

Next, reading of data is described. An appropriate potential (a reading potential) is supplied to the fifth wiring 3005 while a predetermined potential (a constant potential) is supplied to the first wiring 3001, whereby the potential of the second wiring 3002 varies depending on the amount of charge retained in the node FG. This is because in the case of using an n-channel transistor as the transistor 3200, an apparent threshold voltage Vₜₕ_{_{—}}_{H} at the time when the high-level charge is given to the gate of the transistor 3200 is lower than an apparent threshold voltage Vₜₕ_{_{—}}_{L} at the time when the low-level charge is given to the gate of the transistor 3200. Here, an apparent threshold voltage refers to the potential of the fifth wiring 3005 which is needed to turn on the transistor 3200. Thus, the potential of the fifth wiring 3005 is set to a potential V₀ which is between Vₜₕ_{_{—}}_{H} and Vₜₕ_{_{—}}_{L}, whereby charge supplied to the node FG can be determined. For example, in the case where the high-level charge is supplied to the node FG in writing and the potential of the fifth wiring 3005 is V₀ (>Vₜₕ_{_{—}}_{H}), the transistor 3200 is turned on. On the other hand, in the case where the low-level charge is supplied to the node FG in writing, even when the potential of the fifth wiring 3005 is V₀ (<Vₜₕ_{_{—}}_{L}), the transistor 3200 remains off. Thus, the data retained in the node FG can be read by determining the potential of the second wiring 3002.

Note that in the case where memory cells are arrayed, it is necessary that data of a desired memory cell is read in read operation. In the case where data of the other memory cells is not read, the fifth wiring 3005 may be supplied with a potential at which the transistor 3200 is turned off regardless of the charge supplied to the node FG, that is, a potential lower than Vₜₕ_{_{—}}_{H}. Alternatively, the fifth wiring 3005 may be supplied with a potential at which the transistor 3200 is turned on regardless of the charge supplied to the node FG, that is, a potential higher than Vₜₕ_{_{—}}_{L}.

The semiconductor device in FIG. 35B is different form the semiconductor device in FIG. 35A in that the transistor 3200 is not provided. Also in this case, writing and retaining operation of data can be performed in a manner similar to the semiconductor device in FIG. 35A.

Reading of data in the semiconductor device in FIG. 35B is described. When the transistor 3300 is turned on, the third wiring 3003 which is in a floating state and the capacitor 3400 are electrically connected to each other, and the charge is redistributed between the third wiring 3003 and the capacitor 3400. As a result, the potential of the third wiring 3003 is changed. The amount of change in potential of the third wiring 3003 varies depending on the potential of the one electrode of the capacitor 3400 (or the charge accumulated in the capacitor 3400).

For example, the potential of the third wiring 3003 after the charge redistribution is (C_{B}×V_{B0}+C×V)/(C_{B}+C), where V is the potential of the one electrode of the capacitor 3400, C is the capacitance of the capacitor 3400, C_{B} is the capacitance component of the third wiring 3003, and V_{B0} is the potential of the third wiring 3003 before the charge redistribution. Thus, it can be found that, assuming that the memory cell is in either of two states in which the potential of the one electrode of the capacitor 3400 is V₁ and V₀ (V₁>V₀), the potential of the third wiring 3003 in the case of retaining the potential V₁ (=(C_{B}×V_{B0}+C×V₁)/(C_{B}+C)) is higher than the potential of the third wiring 3003 in the case of retaining the potential V₀ (=(C_{B}×V_{B0}+C×V₀)/(C_{B}+C)).

Then, by comparing the potential of the third wiring 3003 with a predetermined potential, data can be read.

In this case, a transistor including the first semiconductor may be used for a driver circuit for driving a memory cell, and a transistor including the second semiconductor may be stacked over the driver circuit as the transistor 3300.

When including a transistor using an oxide semiconductor and having an extremely low off-state current, the semiconductor device described above can retain stored data for a long time. In other words, refresh operation becomes unnecessary or the frequency of the refresh operation can be extremely low, which leads to a sufficient reduction in power consumption. Moreover, stored data can be retained for a long time even when power is not supplied (note that a potential is preferably fixed).

Further, in the semiconductor device, high voltage is not needed for writing data and deterioration of elements is less likely to occur. Unlike in a conventional nonvolatile memory, for example, it is not necessary to inject and extract electrons into and from a floating gate; thus, a problem such as deterioration of an insulating film is not caused. That is, the semiconductor device of one embodiment of the present invention does not have a limit on the number of times data can be rewritten, which is a problem of a conventional nonvolatile memory, and the reliability thereof is drastically improved. Furthermore, data is written depending on the state of the transistor (on or off), whereby high-speed operation can be easily achieved.

### <RFID Tag>

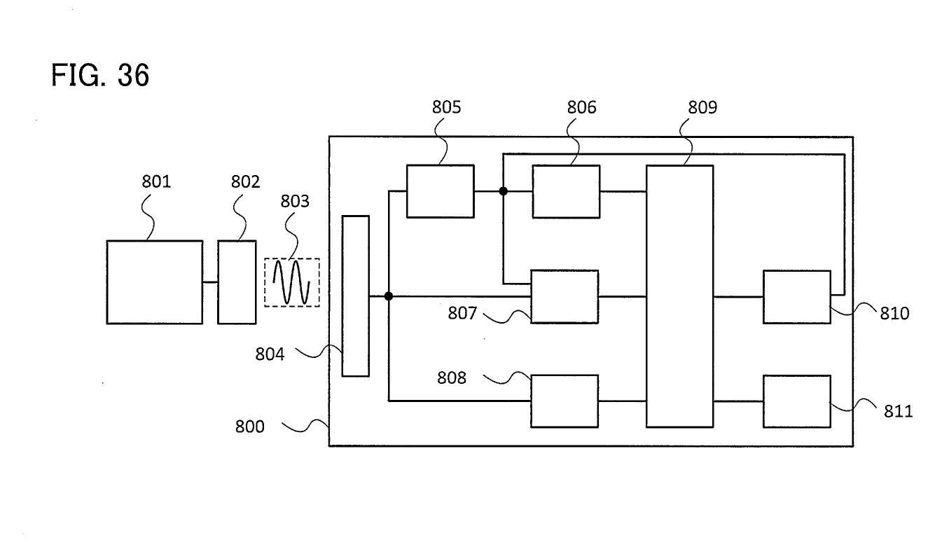

An RFID tag including the transistor or the memory device is described below with reference to FIG. 36.

The RFID tag of one embodiment of the present invention includes a memory circuit, stores data in the memory circuit, and transmits and receives data to/from the outside by using contactless means, for example, wireless communication. With these features, the RFID tag can be used for an individual authentication system in which an object or the like is recognized by reading the individual information, for example. Note that the RFID tag is required to have high reliability in order to be used for this purpose.

A configuration of the RFID tag will be described with reference to FIG. 36. FIG. 36 is a block diagram illustrating a configuration example of an RFID tag.

As shown in FIG. 36, an RFID tag 800 includes an antenna 804 which receives a radio signal 803 that is transmitted from an antenna 802 connected to a communication device 801 (also referred to as an interrogator, a reader/writer, or the like). The RFID tag 800 includes a rectifier circuit 805, a constant voltage circuit 806, a demodulation circuit 807, a modulation circuit 808, a logic circuit 809, a memory circuit 810, and a ROM 811. A semiconductor of a transistor having a rectifying function included in the demodulation circuit 807 may be a material which enables a reverse current to be low enough, for example, an oxide semiconductor. This can suppress the phenomenon of a rectifying function becoming weaker due to generation of a reverse current and prevent saturation of the output from the demodulation circuit. In other words, the input to the demodulation circuit and the output from the demodulation circuit can have a relation closer to a linear relation. Note that data transmission methods are roughly classified into the following three methods: an electromagnetic coupling method in which a pair of coils is provided so as to face each other and communicates with each other by mutual induction, an electromagnetic induction method in which communication is performed using an induction field, and a radio wave method in which communication is performed using a radio wave. Any of these methods can be used in the RFID tag 800.

Next, the structure of each circuit will be described. The antenna 804 exchanges the radio signal 803 with the antenna 802 which is connected to the communication device 801. The rectifier circuit 805 generates an input potential by rectification, for example, half-wave voltage doubler rectification of an input alternating signal generated by reception of a radio signal at the antenna 804 and smoothing of the rectified signal with a capacitor provided in a later stage in the rectifier circuit 805. Note that a limiter circuit may be provided on an input side or an output side of the rectifier circuit 805. The limiter circuit controls electric power so that electric power which is higher than or equal to certain electric power is not input to a circuit in a later stage if the amplitude of the input alternating signal is high and an internal generation voltage is high.

The constant voltage circuit 806 generates a stable power supply voltage from an input potential and supplies it to each circuit. Note that the constant voltage circuit 806 may include a reset signal generation circuit. The reset signal generation circuit is a circuit which generates a reset signal of the logic circuit 809 by utilizing rise of the stable power supply voltage.

The demodulation circuit 807 demodulates the input alternating signal by envelope detection and generates the demodulated signal. Further, the modulation circuit 808 performs modulation in accordance with data to be output from the antenna 804.

The logic circuit 809 analyzes and processes the demodulated signal. The memory circuit 810 holds the input data and includes a row decoder, a column decoder, a memory region, and the like. Further, the ROM 811 stores an identification number (ID) or the like and outputs it in accordance with processing.

Note that the decision whether each circuit described above is provided or not can be made as appropriate as needed.

Here, the above-described memory device can be used as the memory circuit 810. Since the memory device of one embodiment of the present invention can retain data even when not powered, the memory device is suitable for an RFID tag. Further, the memory device of one embodiment of the present invention needs power (voltage) needed for data writing lower than that needed in a conventional nonvolatile memory; thus, it is possible to prevent a difference between the maximum communication range in data reading and that in data writing. Furthermore, it is possible to suppress malfunction or incorrect writing which is caused by power shortage in data writing.

Since the memory device of one embodiment of the present invention can be used as a nonvolatile memory, it can also be used as the ROM 811. In this case, it is preferable that a manufacturer separately prepare a command for writing data to the ROM 811 so that a user cannot rewrite data freely. Since the manufacturer gives identification numbers before shipment and then starts shipment of products, instead of putting identification numbers to all the manufactured RFID tags, it is possible to put identification numbers to only good products to be shipped. Thus, the identification numbers of the shipped products are in series and customer management corresponding to the shipped products is easily performed.

### <Application Examples of RFID Tag>

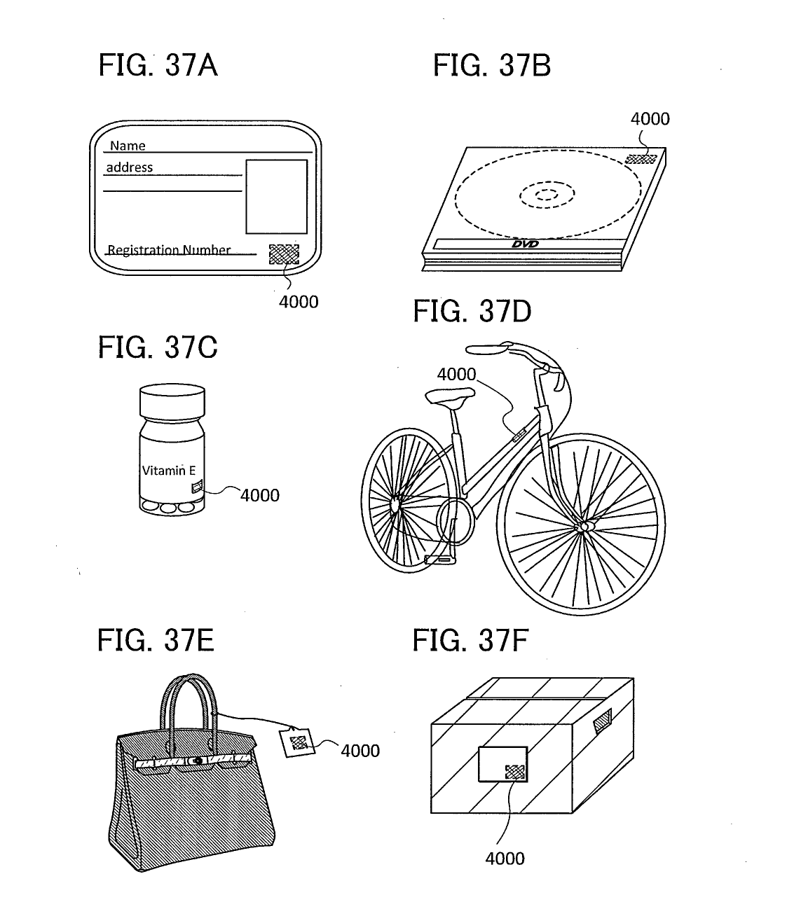

Application examples of the RFID tag of one embodiment of the present invention are shown below with reference to FIGS. 37A to 37F. The RFID tag is widely used and can be provided for, for example, products such as bills, coins, securities, bearer bonds, documents (e.g., driver's licenses or resident's cards, see FIG. 37A), packaging containers (e.g., wrapping paper or bottles, see FIG. 37C), recording media (e.g., DVD software or video tapes, see FIG. 37B), vehicles (e.g., bicycles, see FIG. 37D), personal belongings (e.g., bags or glasses), foods, plants, animals, human bodies, clothing, household goods, medical supplies such as medicine and chemicals, and electronic devices (e.g., liquid crystal display devices, EL display devices, television sets, or cellular phones), or tags on products (see FIGS. 37E and 37F).

An RFID tag 4000 of one embodiment of the present invention is fixed on products by, for example, being mounted on a printed board, being attached to a surface thereof, or being embedded therein. For example, the RFID tag 4000 is fixed to each product by being embedded in paper of a book, or embedded in an organic resin of a package. The RFID tag 4000 of one embodiment of the present invention is small, thin, and lightweight, so that the design of a product is not impaired even after the RFID tag 4000 of one embodiment of the present invention is fixed thereto. Further, bills, coins, securities, bearer bonds, documents, or the like can have identification functions by being provided with the RFID tag 4000 of one embodiment of the present invention, and the identification functions can be utilized to prevent counterfeits. Moreover, the efficiency of a system such as an inspection system can be improved by providing the RFID tag 4000 of one embodiment of the present invention for packaging containers, recording media, personal belongings, foods, clothing, household goods, electronic devices, or the like. Vehicles can also have higher security against theft or the like by being provided with the RFID tag 4000 of one embodiment of the present invention.

As described above, the RFID tag of one embodiment of the present invention can be used for the above-described purposes.

### <CPU>

A CPU including a semiconductor device such as any of the above-described transistors or the above-described memory device is described below.

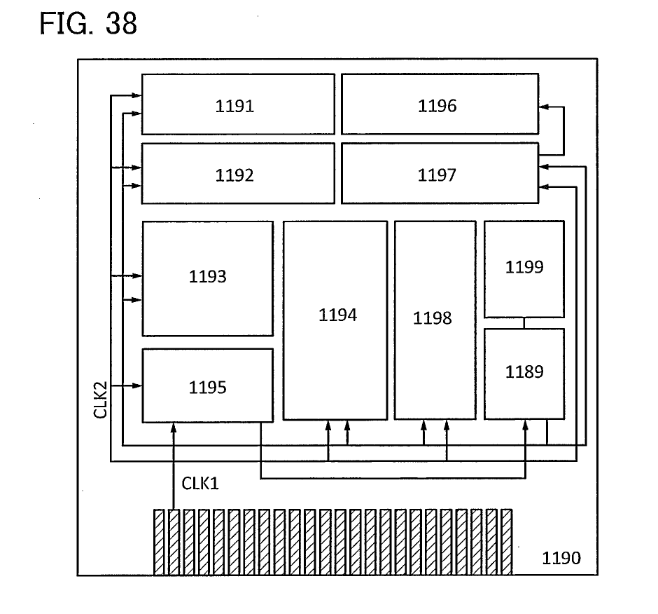

FIG. 38 is a block diagram illustrating a configuration example of a CPU including any of the above-described transistors as a component.

The CPU illustrated in FIG. 38 includes, over a substrate 1190, an arithmetic logic unit (ALU) 1191, an ALU controller 1192, an instruction decoder 1193, an interrupt controller 1194, a timing controller 1195, a register 1196, a register controller 1197, a bus interface 1198, a rewritable ROM 1199, and an ROM interface 1189. A semiconductor substrate, an SOI substrate, a glass substrate, or the like is used as the substrate 1190. The rewritable ROM 1199 and the ROM interface 1189 may be provided over a separate chip. Needless to say, the CPU in FIG. 38 is just an example in which the configuration has been simplified, and an actual CPU may have a variety of configurations depending on the application. For example, the CPU may have the following configuration: a structure including the CPU illustrated in FIG. 38 or an arithmetic circuit is considered as one core; a plurality of the cores are included; and the cores operate in parallel. The number of bits that the CPU can process in an internal arithmetic circuit or in a data bus can be 8, 16, 32, or 64, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device or a peripheral circuit on the basis of its priority or a mask state, and processes the request. The register controller 1197 generates an address of the register 1196, and reads/writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal CLK2 based on a reference clock signal CLK1, and supplies the internal clock signal CLK2 to the above circuits.

In the CPU illustrated in FIG. 38, a memory cell is provided in the register 1196. For the memory cell of the register 1196, any of the above-described transistors, the above-described memory device, or the like can be used.

In the CPU illustrated in FIG. 38, the register controller 1197 selects operation of retaining data in the register 1196 in accordance with an instruction from the ALU 1191. That is, the register controller 1197 selects whether data is retained by a flip-flop or by a capacitor in the memory cell included in the register 1196. When data retaining by the flip-flop is selected, a power supply voltage is supplied to the memory cell in the register 1196. When data retaining by the capacitor is selected, the data is rewritten in the capacitor, and supply of power supply voltage to the memory cell in the register 1196 can be stopped.

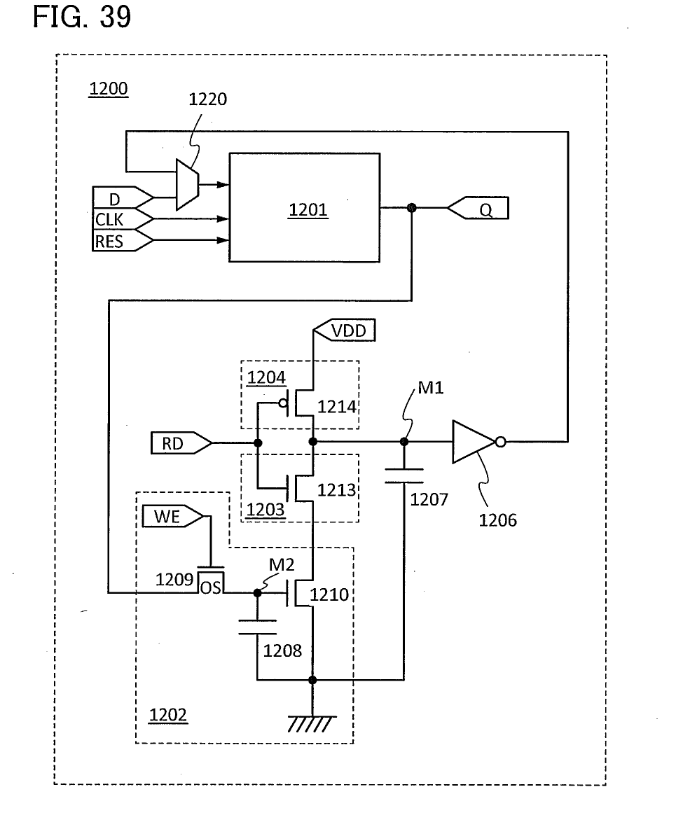

FIG. 39 is an example of a circuit diagram of a memory element that can be used as the register 1196. A memory element 1200 includes a circuit 1201 in which stored data is volatile when power supply is stopped, a circuit 1202 in which stored data is nonvolatile even when power supply is stopped, a switch 1203, a switch 1204, a logic element 1206, a capacitor 1207, and a circuit 1220 having a selecting function. The circuit 1202 includes a capacitor 1208, a transistor 1209, and a transistor 1210. Note that the memory element 1200 may further include another element such as a diode, a resistor, or an inductor, as needed.

Here, the above-described memory device can be used as the circuit 1202. When supply of a power supply voltage to the memory element 1200 is stopped, GND (0 V) or a potential at which the transistor 1209 in the circuit 1202 is turned off continues to be input to a gate of the transistor 1209. For example, the gate of the transistor 1209 is grounded through a load such as a resistor.

Shown here is an example in which the switch 1203 is a transistor 1213 having one conductivity type (e.g., an n-channel transistor) and the switch 1204 is a transistor 1214 having a conductivity type opposite to the one conductivity type (e.g., a p-channel transistor). A first terminal of the switch 1203 corresponds to one of a source and a drain of the transistor 1213, a second terminal of the switch 1203 corresponds to the other of the source and the drain of the transistor 1213, and conduction or non-conduction between the first terminal and the second terminal of the switch 1203 (i.e., the on/off state of the transistor 1213) is selected by a control signal RD input to a gate of the transistor 1213. A first terminal of the switch 1204 corresponds to one of a source and a drain of the transistor 1214, a second terminal of the switch 1204 corresponds to the other of the source and the drain of the transistor 1214, and conduction or non-conduction between the first terminal and the second terminal of the switch 1204 (i.e., the on/off state of the transistor 1214) is selected by the control signal RD input to a gate of the transistor 1214.

One of a source and a drain of the transistor 1209 is electrically connected to one of a pair of electrodes of the capacitor 1208 and a gate of the transistor 1210. Here, the connection portion is referred to as a node M2. One of a source and a drain of the transistor 1210 is electrically connected to a line which can supply a low power supply potential (e.g., a GND line), and the other thereof is electrically connected to the first terminal of the switch 1203 (the one of the source and the drain of the transistor 1213). The second terminal of the switch 1203 (the other of the source and the drain of the transistor 1213) is electrically connected to the first terminal of the switch 1204 (the one of the source and the drain of the transistor 1214). The second terminal of the switch 1204 (the other of the source and the drain of the transistor 1214) is electrically connected to a line which can supply a power supply potential VDD. The second terminal of the switch 1203 (the other of the source and the drain of the transistor 1213), the first terminal of the switch 1204 (the one of the source and the drain of the transistor 1214), an input terminal of the logic element 1206, and one of a pair of electrodes of the capacitor 1207 are electrically connected to each other. Here, the connection portion is referred to as a node M1. The other of the pair of electrodes of the capacitor 1207 can be supplied with a constant potential. For example, the other of the pair of electrodes of the capacitor 1207 can be supplied with a low power supply potential (e.g., GND) or a high power supply potential (e.g., VDD). The other of the pair of electrodes of the capacitor 1207 is electrically connected to the line which can supply a low power supply potential (e.g., a GND line). The other of the pair of electrodes of the capacitor 1208 can be supplied with a constant potential. For example, the other of the pair of electrodes of the capacitor 1208 can be supplied with the low power supply potential (e.g., GND) or the high power supply potential (e.g., VDD). The other of the pair of electrodes of the capacitor 1208 is electrically connected to the line which can supply a low power supply potential (e.g., a GND line).

The capacitor 1207 and the capacitor 1208 are not necessarily provided as long as the parasitic capacitance of the transistor, the wiring, or the like is actively utilized.

A control signal WE is input to the first gate (first gate electrode) of the transistor 1209. As for each of the switch 1203 and the switch 1204, a conduction state or a non-conduction state between the first terminal and the second terminal is selected by the control signal RD which is different from the control signal WE. When the first terminal and the second terminal of one of the switches are in the conduction state, the first terminal and the second terminal of the other of the switches are in the non-conduction state.

A signal corresponding to data retained in the circuit 1201 is input to the other of the source and the drain of the transistor 1209. FIG. 39 illustrates an example in which a signal output from the circuit 1201 is input to the other of the source and the drain of the transistor 1209. The logic value of a signal output from the second terminal of the switch 1203 (the other of the source and the drain of the transistor 1213) is inverted by the logic element 1206, and the inverted signal is input to the circuit 1201 through the circuit 1220.

In the example of FIG. 39, a signal output from the second terminal of the switch 1203 (the other of the source and the drain of the transistor 1213) is input to the circuit 1201 through the logic element 1206 and the circuit 1220; however, one embodiment of the present invention is not limited thereto. The signal output from the second terminal of the switch 1203 (the other of the source and the drain of the transistor 1213) may be input to the circuit 1201 without its logic value being inverted. For example, in the case where the circuit 1201 includes a node in which a signal obtained by inversion of the logic value of a signal input from the input terminal is retained, the signal output from the second terminal of the switch 1203 (the other of the source and the drain of the transistor 1213) can be input to the node.

In FIG. 39, the transistors included in the memory element 1200 except for the transistor 1209 can each be a transistor in which a channel is formed in a film formed using a semiconductor other than an oxide semiconductor or in the substrate 1190. For example, the transistor can be a transistor whose channel is formed in a silicon film or a silicon substrate. Alternatively, all the transistors in the memory element 1200 may be a transistor in which a channel is formed in an oxide semiconductor film. Further alternatively, in the memory element 1200, a transistor in which a channel is formed in an oxide semiconductor film can be included besides the transistor 1209, and a transistor in which a channel is formed in a layer or the substrate 1190 including a semiconductor other than an oxide semiconductor can be used for the rest of the transistors.

As the circuit 1201 in FIG. 39, for example, a flip-flop circuit can be used. As the logic element 1206, for example, an inverter or a clocked inverter can be used.

In a period during which the memory element 1200 is not supplied with the power supply voltage, the semiconductor device of one embodiment of the present invention can retain data stored in the circuit 1201 by the capacitor 1208 which is provided in the circuit 1202.

The off-state current of a transistor in which a channel is formed in an oxide semiconductor film is extremely low. For example, the off-state current of a transistor in which a channel is formed in an oxide semiconductor film is significantly lower than that of a transistor in which a channel is formed in silicon having crystallinity. Thus, when the transistor is used as the transistor 1209, a signal held in the capacitor 1208 is retained for a long time also in a period during which the power supply voltage is not supplied to the memory element 1200. The memory element 1200 can accordingly retain the stored content (data) also in a period during which the supply of the power supply voltage is stopped.

Since the above-described memory element performs pre-charge operation with the switch 1203 and the switch 1204, the time required for the circuit 1201 to retain original data again after the supply of the power supply voltage is restarted can be shortened.

In the circuit 1202, a signal retained by the capacitor 1208 is input to the gate of the transistor 1210. Therefore, after supply of the power supply voltage to the memory element 1200 is restarted, the signal retained by the capacitor 1208 can be converted into the one corresponding to the state (the on state or the off state) of the transistor 1210 to be read from the circuit 1202. Consequently, an original signal can be accurately read even when a potential corresponding to the signal retained by the capacitor 1208 varies to some degree.

By applying the above-described memory element 1200 to a memory device such as a register or a cache memory included in a processor, data in the memory device can be prevented from being lost owing to the stop of the supply of the power supply voltage. Furthermore, shortly after the supply of the power supply voltage is restarted, the memory device can be returned to the same state as that before the power supply is stopped. Therefore, the power supply can be stopped even for a short time in the processor or one or a plurality of logic circuits included in the processor, resulting in lower power consumption.

Although the memory element 1200 is used in a CPU, the memory element 1200 can also be used in an LSI such as a digital signal processor (DSP), a custom LSI, or a programmable logic device (PLD), and a radio frequency identification (RF-ID).

### <Display Device>

The following shows configuration examples of a display device of one embodiment of the present invention.

### Configuration Example

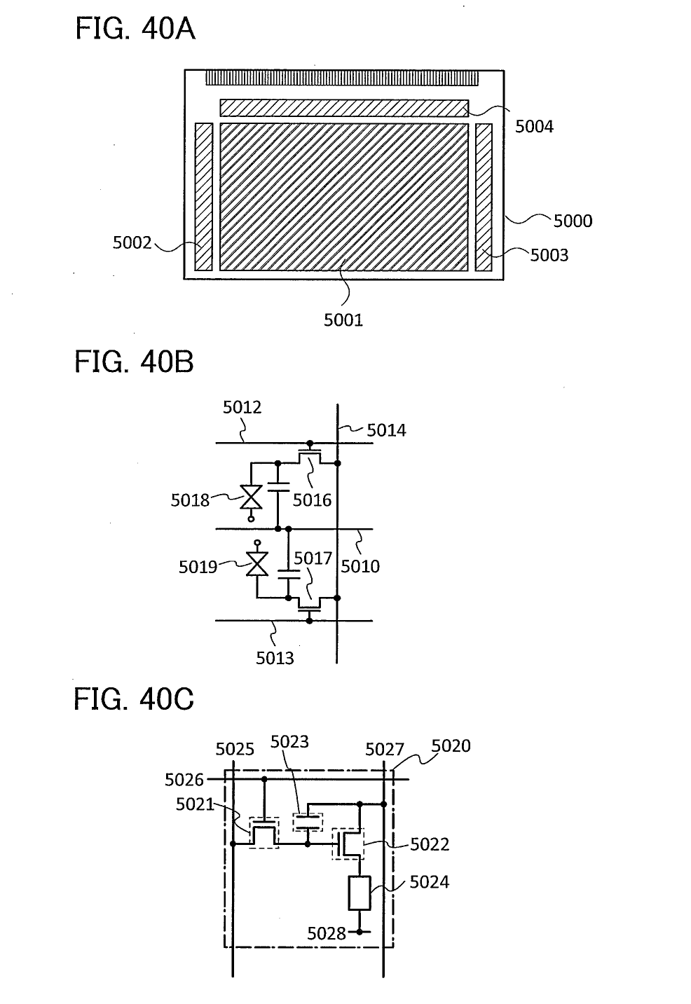

FIG. 40A is a top view of a display device of one embodiment of the present invention. FIG. 40B illustrates a pixel circuit where a liquid crystal element is used for a pixel of a display device of one embodiment of the present invention. FIG. 40C illustrates a pixel circuit where an organic EL element is used for a pixel of a display device of one embodiment of the present invention.

Any of the above-described transistors can be used as a transistor used for the pixel. Here, an example in which an n-channel transistor is used is shown. Note that a transistor manufactured through the same steps as the transistor used for the pixel may be used for a driver circuit. Thus, by using any of the above-described transistors for a pixel or a driver circuit, the display device can have high display quality and/or high reliability.

FIG. 40A illustrates an example of a top view of an active matrix display device. A pixel portion 5001, a first scan line driver circuit 5002, a second scan line driver circuit 5003, and a signal line driver circuit 5004 are provided over a substrate 5000 in the display device. The pixel portion 5001 is electrically connected to the signal line driver circuit 5004 through a plurality of signal lines and is electrically connected to the first scan line driver circuit 5002 and the second scan line driver circuit 5003 through a plurality of scan lines. Pixels including display elements are provided in respective regions divided by the scan lines and the signal lines. The substrate 5000 of the display device is electrically connected to a timing control circuit (also referred to as a controller or a control IC) through a connection portion such as a flexible printed circuit (FPC).

The first scan line driver circuit 5002, the second scan line driver circuit 5003, and the signal line driver circuit 5004 are formed over the substrate 5000 where the pixel portion 5001 is formed. Therefore, a display device can be manufactured at cost lower than that in the case where a driver circuit is separately formed. Further, in the case where a driver circuit is separately formed, the number of wiring connections is increased. By providing the driver circuit over the substrate 5000, the number of wiring connections can be reduced. Accordingly, the reliability and/or yield can be improved.

### [Liquid Crystal Display Device]

FIG. 40B illustrates an example of a circuit configuration of the pixel. Here, a pixel circuit which is applicable to a pixel of a VA liquid crystal display device, or the like is illustrated.

This pixel circuit can be applied to a structure in which one pixel includes a plurality of pixel electrodes. The pixel electrodes are connected to different transistors, and the transistors can be driven with different gate signals. Accordingly, signals applied to individual pixel electrodes in a multi-domain pixel can be controlled independently.

A gate wiring 5012 of a transistor 5016 and a gate wiring 5013 of a transistor 5017 are separated so that different gate signals can be supplied thereto. In contrast, a source or drain electrode 5014 functioning as a data line is shared by the transistors 5016 and 5017. Any of the above-described transistors can be used as appropriate as each of the transistors 5016 and 5017. Thus, the liquid crystal display device can have high display quality and/or high reliability.

The shapes of a first pixel electrode electrically connected to the transistor 5016 and a second pixel electrode electrically connected to the transistor 5017 are described. The first pixel electrode and the second pixel electrode are separated by a slit. The first pixel electrode has a V shape and the second pixel electrode is provided so as to surround the first pixel electrode.

A gate electrode of the transistor 5016 is electrically connected to the gate wiring 5012, and a gate electrode of the transistor 5017 is electrically connected to the gate wiring 5013. When different gate signals are supplied to the gate wiring 5012 and the gate wiring 5013, operation timings of the transistor 5016 and the transistor 5017 can be varied. As a result, alignment of liquid crystals can be controlled.

Further, a capacitor may be formed using a capacitor wiring 5010, a gate insulating film functioning as a dielectric, and a capacitor electrode electrically connected to the first pixel electrode or the second pixel electrode.

The multi-domain pixel includes a first liquid crystal element 5018 and a second liquid crystal element 5019. The first liquid crystal element 5018 includes the first pixel electrode, a counter electrode, and a liquid crystal layer therebetween. The second liquid crystal element 5019 includes the second pixel electrode, a counter electrode, and a liquid crystal layer therebetween.

Note that a pixel circuit in the display device of one embodiment of the present invention is not limited to that shown in FIG. 40B. For example, a switch, a resistor, a capacitor, a transistor, a sensor, a logic circuit, or the like may be added to the pixel circuit shown in FIG. 40B.

### [Organic EL Display Device]

FIG. 40C illustrates another example of a circuit configuration of the pixel. Here, a pixel structure of a display device using an organic EL element is shown.

In an organic EL element, by application of voltage to a light-emitting element, electrons are injected from one of a pair of electrodes included in the organic EL element and holes are injected from the other of the pair of electrodes, into a layer containing a light-emitting organic compound; thus, current flows. The electrons and holes are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

FIG. 40C illustrates an example of a pixel circuit. Here, one pixel includes two n-channel transistors. Note that any of the above-described transistors can be used as the n-channel transistors. Further, digital time grayscale driving can be employed for the pixel circuit.

The configuration of the applicable pixel circuit and operation of a pixel employing digital time grayscale driving will be described.

A pixel 5020 includes a switching transistor 5021, a driver transistor 5022, a light-emitting element 5024, and a capacitor 5023. A gate electrode of the switching transistor 5021 is connected to a scan line 5026, a first electrode (one of a source electrode and a drain electrode) of the switching transistor 5021 is connected to a signal line 5025, and a second electrode (the other of the source electrode and the drain electrode) of the switching transistor 5021 is connected to a gate electrode of the driver transistor 5022. The gate electrode of the driver transistor 5022 is connected to a power supply line 5027 through the capacitor 5023, a first electrode of the driver transistor 5022 is connected to the power supply line 5027, and a second electrode of the driver transistor 5022 is connected to a first electrode (a pixel electrode) of the light-emitting element 5024. A second electrode of the light-emitting element 5024 corresponds to a common electrode 5028. The common electrode 5028 is electrically connected to a common potential line provided over the same substrate.

As each of the switching transistor 5021 and the driver transistor 5022, any of the above-described transistors can be used as appropriate. In this manner, an organic EL display device having high display quality and/or high reliability can be provided.

The potential of the second electrode (the common electrode 5028) of the light-emitting element 5024 is set to be a low power supply potential. Note that the low power supply potential is lower than a high power supply potential supplied to the power supply line 5027. For example, the low power supply potential can be GND, 0 V, or the like. The high power supply potential and the low power supply potential are set to be higher than or equal to the forward threshold voltage of the light-emitting element 5024, and the difference between the potentials is applied to the light-emitting element 5024, whereby current is supplied to the light-emitting element 5024, leading to light emission. The forward voltage of the light-emitting element 5024 refers to a voltage at which a desired luminance is obtained, and includes at least forward threshold voltage.

Note that gate capacitance of the driver transistor 5022 may be used as a substitute for the capacitor 5023 in some cases, so that the capacitor 5023 can be omitted. The gate capacitance of the driver transistor 5022 may be formed between the channel formation region and the gate electrode.

Next, a signal input to the driver transistor 5022 is described. In the case of a voltage-input voltage driving method, a video signal for turning on or off the driver transistor 5022 is input to the driver transistor 5022. In order for the driver transistor 5022 to operate in a linear region, voltage higher than the voltage of the power supply line 5027 is applied to the gate electrode of the driver transistor 5022. Note that voltage higher than or equal to voltage which is the sum of power supply line voltage and the threshold voltage Vₜₕ of the driver transistor 5022 is applied to the signal line 5025.

In the case of performing analog grayscale driving, a voltage higher than or equal to a voltage which is the sum of the forward voltage of the light-emitting element 5024 and the threshold voltage Vₜₕ of the driver transistor 5022 is applied to the gate electrode of the driver transistor 5022. A video signal by which the driver transistor 5022 is operated in a saturation region is input, so that current is supplied to the light-emitting element 5024. In order for the driver transistor 5022 to operate in a saturation region, the potential of the power supply line 5027 is set higher than the gate potential of the driver transistor 5022. When an analog video signal is used, it is possible to supply current to the light-emitting element 5024 in accordance with the video signal and perform analog grayscale driving.

Note that in the display device of one embodiment of the present invention, a pixel configuration is not limited to that shown in FIG. 40C. For example, a switch, a resistor, a capacitor, a sensor, a transistor, a logic circuit, or the like may be added to the pixel circuit shown in FIG. 40C.

In the case where any of the above-described transistors is used for the circuit shown in FIGS. 40A to 40C, the source electrode (the first electrode) is electrically connected to the low potential side and the drain electrode (the second electrode) is electrically connected to the high potential side. Further, the potential of the first gate electrode may be controlled by a control circuit or the like and the potential described above as an example, e.g., a potential lower than the potential applied to the source electrode, may be input to the second gate electrode.

For example, in this specification and the like, a display element, a display device which is a device including a display element, a light-emitting element, and a light-emitting device which is a device including a light-emitting element can employ a variety of modes or can include a variety of elements. Examples of a display element, a display device, a light-emitting element, or a light-emitting device include an EL element (e.g., an EL element including organic and inorganic materials, an organic EL element, or an inorganic EL element), an LED (e.g., a white LED, a red LED, a green LED, or a blue LED), a transistor (a transistor which emits light depending on current), an electron emitter, a liquid crystal element, electronic ink, an electrophoretic element, a grating light valve (GLV), a plasma display panel (PDP), a micro electro mechanical system (MEMS), a digital micromirror device (DMD), a digital micro shutter (DMS), an interferometric modulator display (IMOD) element, an electrowetting element, a piezoelectric ceramic display, or a carbon nanotube, which are display media whose contrast, luminance, reflectivity, transmittance, or the like is changed by electromagnetic action. Note that examples of a display device having an EL element include an EL display. Examples of a display device having an electron emitter include a field emission display (FED) and an SED-type flat panel display (SED: surface-conduction electron-emitter display). Examples of a display device having a liquid crystal element include a liquid crystal display (e.g., a transmissive liquid crystal display, a transflective liquid crystal display, a reflective liquid crystal display, a direct-view liquid crystal display, or a projection liquid crystal display). Examples of a display device having electronic ink or an electrophoretic element include electronic paper.

A color layer (also referred to as a color filter) may be used in order to obtain a full-color display device in which white light (W) for a backlight (e.g., an organic EL element, an inorganic EL element, an LED, or a fluorescent lamp) is used. As the color layer, red (R), green (G), blue (B), yellow (Y), or the like may be combined as appropriate, for example. With the use of the color layer, higher color reproductivity can be obtained than in the case without the color layer. In this case, by providing a region with the color layer and a region without the color layer, white light in the region without the color layer may be directly utilized for display. By partly providing the region without the color layer, a decrease in luminance due to the color layer can be suppressed, and 20% to 30% of power consumption can be reduced in some cases when an image is displayed brightly. Note that in the case where full-color display is performed using a self-luminous element such as an organic EL element or an inorganic EL element, elements may emit light of their respective colors R, G, B, Y, and W. By using a self-luminous element, power consumption can be further reduced as compared to the case of using the color layer in some cases.

### <Module>

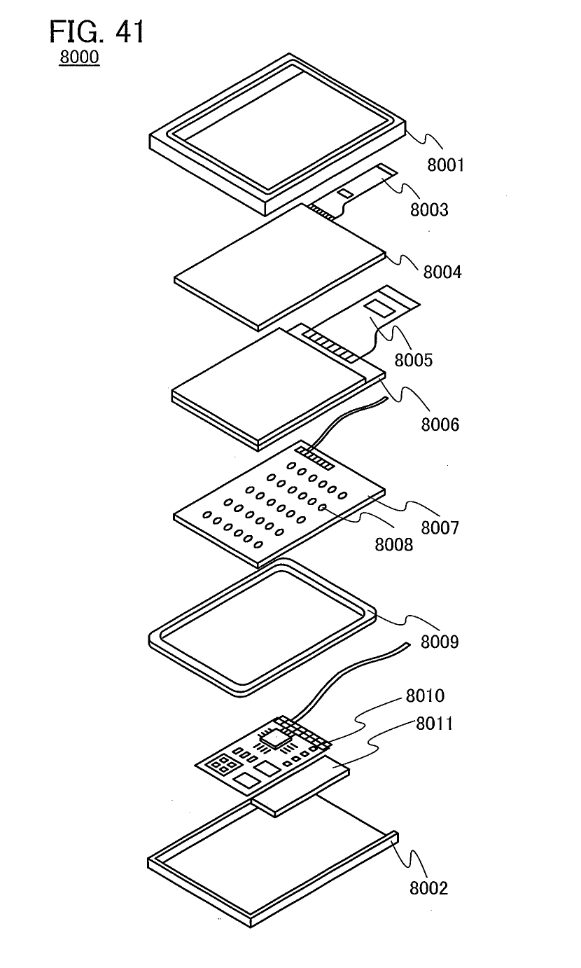

A display module using a semiconductor device of one embodiment of the present invention is described below with reference to FIG. 41.

In a display module 8000 in FIG. 41, a touch panel 8004 connected to an FPC 8003, a cell 8006 connected to an FPC 8005, a backlight unit 8007, a frame 8009, a printed board 8010, and a battery 8011 are provided between an upper cover 8001 and a lower cover 8002. Note that the backlight unit 8007, the battery 8011, the touch panel 8004, and the like are not provided in some cases.

The semiconductor device of one embodiment of the present invention can be used for the cell 8006, for example.

The shapes and sizes of the upper cover 8001 and the lower cover 8002 can be changed as appropriate in accordance with the sizes of the touch panel 8004 and the cell 8006.

The touch panel 8004 can be a resistive touch panel or a capacitive touch panel and may be formed to overlap with the cell 8006. A counter substrate (sealing substrate) of the cell 8006 can have a touch panel function. A photosensor may be provided in each pixel of the cell 8006 so that an optical touch panel is obtained. An electrode for a touch sensor may be provided in each pixel of the cell 8006 so that a capacitive touch panel is obtained.

The backlight unit 8007 includes a light source 8008. The light source 8008 may be provided at an end portion of the backlight unit 8007 and a light diffusing plate may be used.

The frame 8009 may protect the cell 8006 and also function as an electromagnetic shield for blocking electromagnetic waves generated by the operation of the printed board 8010. The frame 8009 may function as a radiator plate.

The printed board 8010 has a power supply circuit and a signal processing circuit for outputting a video signal and a clock signal. As a power source for supplying power to the power supply circuit, an external commercial power source or a power source using the battery 8011 provided separately may be used. The battery 8011 can be omitted in the case of using a commercial power source.

The display module 8000 can be additionally provided with a member such as a polarizing plate, a retardation plate, or a prism sheet

### <Electronic Device>

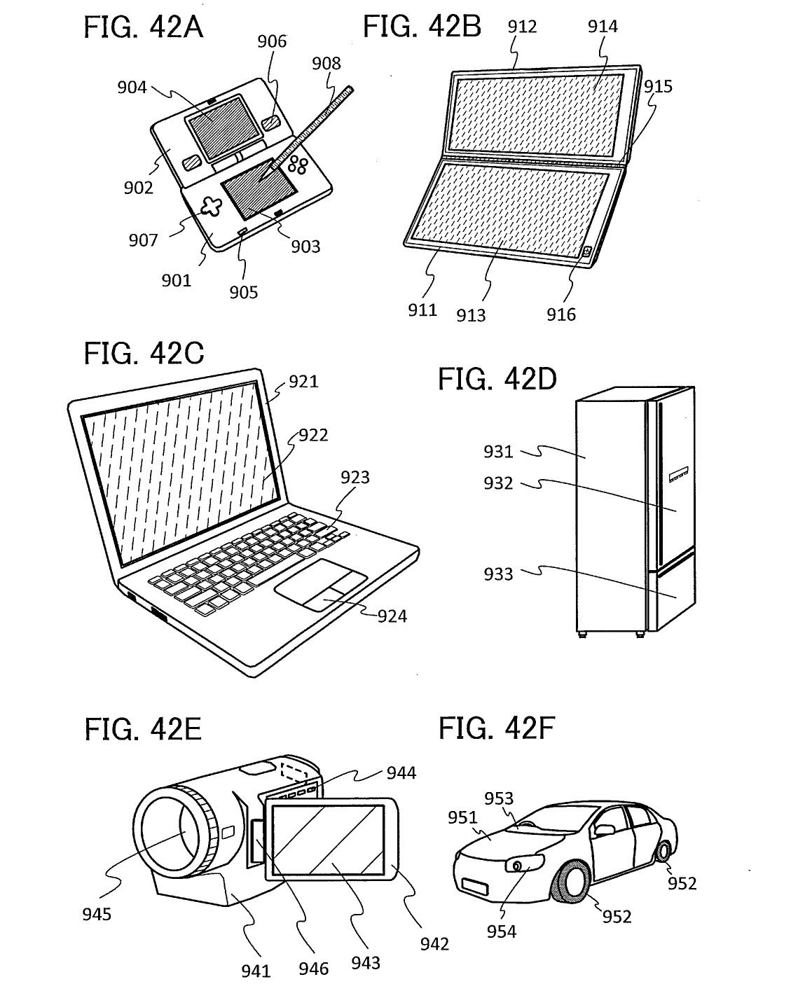

The semiconductor device of one embodiment of the present invention can be used for display devices, personal computers, or image reproducing devices provided with recording media (typically, devices which reproduce the content of recording media such as digital versatile discs (DVDs) and have displays for displaying the reproduced images). Other examples of electronic devices that can be equipped with the semiconductor device of one embodiment of the present invention are mobile phones, game machines including portable game consoles, portable data appliances, e-book readers, cameras such as video cameras and digital still cameras, goggle-type displays (head mounted displays), navigation systems, audio reproducing devices (e.g., car audio systems and digital audio players), copiers, facsimiles, printers, multifunction printers, automated teller machines (ATM), and vending machines. FIGS. 42A to 42F illustrate specific examples of these electronic devices.

FIG. 42A illustrates a portable game console including a housing 901, a housing 902, a display portion 903, a display portion 904, a microphone 905, a speaker 906, an operation key 907, a stylus 908, and the like. Although the portable game machine in FIG. 42A has the two display portions 903 and 904, the number of display portions included in a portable game machine is not limited to this.

FIG. 42B illustrates a portable data terminal including a first housing 911, a second housing 912, a first display portion 913, a second display portion 914, a joint 915, an operation key 916, and the like. The first display portion 913 is provided in the first housing 911, and the second display portion 914 is provided in the second housing 912. The first housing 911 and the second housing 912 are connected to each other with the joint 915, and the angle between the first housing 911 and the second housing 912 can be changed with the joint 915. An image on the first display portion 913 may be switched depending on the angle between the first housing 911 and the second housing 912 at the joint 915. A display device with a position input function may be used as at least one of the first display portion 913 and the second display portion 914. Note that the position input function can be added by providing a touch panel in a display device. Alternatively, the position input function can be added by provision of a photoelectric conversion element called a photosensor in a pixel portion of a display device.

FIG. 42C illustrates a laptop personal computer, which includes a housing 921, a display portion 922, a keyboard 923, a pointing device 924, and the like.

FIG. 42D illustrates the electric refrigerator-freezer including a housing 931, a door for a refrigerator 932, a door for a freezer 933, and the like.

FIG. 42E illustrates a video camera, which includes a first housing 941, a second housing 942, a display portion 943, operation keys 944, a lens 945, a joint 946, and the like. The operation keys 944 and the lens 945 are provided for the first housing 941, and the display portion 943 is provided for the second housing 942. The first housing 941 and the second housing 942 are connected to each other with the joint 946, and the angle between the first housing 941 and the second housing 942 can be changed with the joint 946. Images displayed on the display portion 943 may be switched in accordance with the angle at the joint 946 between the first housing 941 and the second housing 942.

FIG. 42F illustrates an ordinary vehicle including a car body 951, wheels 952, a dashboard 953, lights 954, and the like.

### EXPLANATION OF REFERENCE

100: pellet, 100a: pellet, 100b: pellet, 101: ion, 120: substrate, 130: target, 310: electron gun chamber, 312: optical system, 314: sample chamber, 316: optical system, 318: camera, 320: observation chamber, 322: film chamber, 324: electron, 328: substance, 332: fluorescent screen, 400: substrate, 402: insulating film, 404: conductive film, 406: semiconductor film, 406a: oxide semiconductor layer, 406b: oxide semiconductor layer, 406c: oxide semiconductor layer, 407: semiconductor film, 412: insulating film, 413: conductive film, 416a: conductive film, 416b: conductive film, 418: insulating film, 500: substrate, 502: insulating film, 504: conductive film, 506: semiconductor film, 512: insulating film, 513: conductive film, 516a: conductive film, 516b: conductive film, 518: insulating film, 524a: conductive film, 524b: conductive film, 600: substrate, 604: conductive film, 606: semiconductor film, 612: insulating film, 616a: conductive film, 616b: conductive film, 618: insulating film, 620: insulating film, 622: conductive film, 700: deposition apparatus, 701: atmosphere-side substrate supply chamber, 702: atmosphere-side substrate transfer chamber, 703a: load lock chamber, 703b: unload lock chamber, 704: transfer chamber, 705: substrate heating chamber, 706a: deposition chamber, 706b: deposition chamber, 706c: deposition chamber, 751: cryotrap, 752: stage, 761: cassette port, 762: alignment port, 763: transfer robot, 764: gate valve, 765: heating stage, 766: target, 767: attachment protection plate, 768: substrate stage, 769: substrate, 770: vacuum pump, 771: cryopump, 772: turbo molecular pump, 780: mass flow controller, 781: refiner, 782: gas heating system, 800: RFID tag, 801: communication device, 802: antenna, 803: radio signal, 804: antenna, 805: rectifier circuit, 806: constant voltage circuit, 807: demodulation circuit, 808: modulation circuit, 809: logic circuit, 810: memory circuit, 811: ROM, 901: housing, 902: housing, 903: display portion, 904: display portion, 905: microphone, 906: speaker, 907: operation key, 908: stylus, 911: housing, 912: housing, 913: display portion, 914: display portion, 915: joint, 916: operation key, 921: housing, 922: display portion, 923: keyboard, 924: pointing device, 931: housing, 932: door for refrigerator, 933: door for freezer, 941: housing, 942: housing, 943: display portion, 944: operation key, 945: lens, 946: joint, 951: car body, 952: wheel, 953: dashboard, 954: light, 1189: ROM interface, 1190: substrate, 1191: ALU, 1192: ALU controller, 1193: instruction decoder, 1194: interrupt controller, 1195: timing controller, 1196: register, 1197: register controller, 1198: bus interface, 1199: ROM, 1200: memory element, 1201: circuit, 1202: circuit, 1203: switch, 1204: switch, 1206: logic element, 1207: capacitor, 1208: capacitor, 1209: transistor, 1210: transistor, 1213: transistor, 1214: transistor, 1220: circuit, 2100: transistor, 2200: transistor, 2201: insulating film, 2202: conductive film, 2203: conductive film, 2204: insulating film, 2205: conductive film, 2206: conductive film, 2207: insulating film, 2211: semiconductor substrate, 2212: insulating layer, 2213: gate electrode, 2214: gate insulating film, 2215: source and drain region, 3001: wiring, 3002: wiring, 3003: wiring, 3004: wiring, 3005: wiring, 3200: transistor, 3300: transistor, 3400: capacitor, 4000: RFID tag, 5000: substrate, 5001: pixel portion, 5002: scan line driver circuit, 5003: scan line driver circuit, 5004: signal line driver circuit, 5010: capacitor wiring, 5012: gate wiring, 5013: gate wiring, 5014: source or drain electrode, 5016: transistor, 5017: transistor, 5018: liquid crystal element, 5019: liquid crystal element, 5020: pixel, 5021: switching transistor, 5022: driver transistor, 5023: capacitor, 5024: light-emitting element, 5025: signal line, 5026: scan line, 5027: power supply line, 5028: common electrode, 8000: display module, 8001: upper cover, 8002: lower cover, 8003: FPC, 8004: touch panel, 8005: FPC, 8006: cell, 8007: backlight unit, 8008: light source, 8009: frame, 8010: printed board, and 8011: battery.

This application is based on Japanese Patent Application serial no. 2013-218823 filed with Japan Patent Office on Oct. 22, 2013, the entire contents of which are hereby incorporated by reference.

1. A method for forming an oxide semiconductor film using a sputtering apparatus including a target containing a crystalline In—Ga—Zn oxide, a substrate, and a magnet, comprising the steps of:
generating plasma by applying a potential difference between the target and the substrate; and
separating a flat-plate-like In—Ga—Zn oxide from the target by making an ion generated in the plasma collide with the target, the flat-plate-like In—Ga—Zn oxide comprising a first layer, a second layer, and a third layer in this order,
wherein the flat-plate-like In—Ga—Zn oxide is negatively charged by passing through the plasma, gets close to a top surface of the substrate, moves over the top surface of the substrate due to a magnetic field of the magnet and current flowing from the substrate to the target, and then is deposited while keeping crystallinity,
wherein the first layer contains a gallium atom, a zinc atom, and an oxygen atom,
wherein the second layer contains an indium atom and an oxygen atom, and
wherein the third layer contains a gallium atom, a zinc atom, and an oxygen atom.

2. The method for forming an oxide semiconductor film, according to claim 1,
wherein an oxygen atom bonded to an indium atom, a gallium atom, or a zinc atom is negatively charged, and
wherein the oxygen atom is on a side surface of the flat-plate-like In—Ga—Zn oxide.

3. The method for forming an oxide semiconductor film, according to claim 2,
wherein a shape of the flat-plate-like In—Ga—Zn oxide is kept by making the oxygen atoms that are negatively charged repel each other.

4. The method for forming an oxide semiconductor film, according to claim 1,
wherein when moving over the top surface of the substrate, the side surface of the flat-plate-like In—Ga—Zn oxide is firmly bonded to the top surface of the substrate after being bonded to a side surface of an In—Ga—Zn oxide which has already been deposited.

5. The method for forming an oxide semiconductor film, according to claim 4,
wherein when the bonding is made, the oxygen atom bonded to the side surface of the flat-plate-like In—Ga—Zn oxide is released.

6. The method for forming an oxide semiconductor film, according to claim 5,
wherein an oxygen vacancy is filled with the oxygen atom that is released.

7. The method for forming an oxide semiconductor film, according to claim 1,
wherein when the flat-plate-like In—Ga—Zn oxide is deposited over the top surface of the substrate, an angle between a normal vector of the top surface of the substrate and a c-axis of the flat-plate-like In—Ga—Zn oxide is greater than or equal to −10° and less than or equal to 10°.

8. The method for forming an oxide semiconductor film, according to claim 1,
wherein a composition formula of the crystalline In—Ga—Zn oxide contained in the target is InGaZnO₄.

9. The method for forming an oxide semiconductor film, according to claim 1,
wherein the ion is an oxygen cation.

10. A method for forming an oxide semiconductor film using a sputtering apparatus including a target containing a crystalline In—Ga—Zn oxide, a substrate, and a magnet, comprising the steps of:
generating plasma by applying a potential difference between the target and the substrate; and
separating a flat-plate-like In—Ga—Zn oxide in which a first layer including a gallium atom, a zinc atom, and an oxygen atom, a second layer including an indium atom and an oxygen atom, and a third layer including a gallium atom, a zinc atom, and an oxygen atom are stacked in this order by making an ion generated in the plasma collide with the target,
wherein the flat-plate-like In—Ga—Zn oxide is negatively charged by passing through the plasma, gets close to a top surface of the substrate while keeping crystallinity, moves over the top surface of the substrate due to a magnetic field of the magnet and current flowing from the substrate to the target, and then is deposited.

11. The method for forming an oxide semiconductor film, according to claim 10,
wherein an oxygen atom bonded to an indium atom, a gallium atom, or a zinc atom is negatively charged, and
wherein the oxygen atom is on a side surface of the flat-plate-like In—Ga—Zn oxide.

12. The method for forming an oxide semiconductor film, according to claim 11,
wherein a shape of the flat-plate-like In—Ga—Zn oxide is kept by making the oxygen atoms that are negatively charged repel each other.

13. The method for forming an oxide semiconductor film, according to claim 10,
wherein when moving over the top surface of the substrate, the side surface of the flat-plate-like In—Ga—Zn oxide is firmly bonded to the top surface of the substrate after being bonded to a side surface of an In—Ga—Zn oxide which has already been deposited.

14. The method for forming an oxide semiconductor film, according to claim 13,
wherein when the bonding is made, the oxygen atom bonded to the side surface of the flat-plate-like In—Ga—Zn oxide is released.

15. The method for forming an oxide semiconductor film, according to claim 14,
wherein an oxygen vacancy is filled with the oxygen atom that is released.

16. The method for forming an oxide semiconductor film, according to claim 10,
wherein when the flat-plate-like In—Ga—Zn oxide is deposited over the top surface of the substrate, an angle between a normal vector of the top surface of the substrate and a c-axis of the flat-plate-like In—Ga—Zn oxide is greater than or equal to −10° and less than or equal to 10°.

17. The method for forming an oxide semiconductor film, according to claim 10,
wherein a composition formula of the crystalline In—Ga—Zn oxide contained in the target is InGaZnO₄.

18. The method for forming an oxide semiconductor film, according to claim 10,
wherein the ion is an oxygen cation.
